(19) United States
(12) Patent Application Publication
(10) Pub. No.: US 2026/0197004 A1
(43) Pub. Date: Jul. 9, 2026

(54) Sensor System Using Logic Gates Based on Ising Dynamics

(71) Applicant: Northeastern University, Boston, MA (US)

(72) Inventors: Cristian CASSELLA, Boston, MA (US); Nicolas CASILLI, Kendall Park, NJ (US); Hussein M.E. HUSSEIN, Boston, MA (US); Luca COLOMBO, Boston, MA (US)

(21) Appl. No.: 19/387,464

(22) Filed: Nov. 12, 2025

Related U.S. Application Data
(60) Provisional application No. 63/719,380, filed on Nov. 12, 2024.

(51) Int. Cl. H03K 19/195

(52) U.S. Cl. CPC H03K 19/195

(57) ABSTRACT

Provided herein are Ising logic-gates having at least four POs, each coupled to at least one other of the POs and configured to passively activate, responsive to a pump signal, a parametric oscillation, an output signal of the PO switchable between in-phase and out-of-phase, a plurality of coupling elements, each for coupling two of the at least four POs to form a plurality of blocks, each block having a mode corresponding to or interactive with a logical input, the mode passively activatable via the coupled POs to produce a corresponding block output, the plurality of block outputs tuned to selectively frustrate the plurality of block outputs to produce an output at negligible amplitude or constructively interfere with the plurality of block outputs to produce the output at detectable amplitude; and a power combiner for power-combining the plurality of block outputs to produce the output.

### CROSS REFERENCE TO RELATED APPLICATIONS

This application claims benefit under 35 U.S.C. § 119(e) of U.S. Provisional Application No. 63/719,380, filed on 12 Nov. 2024, entitled “Sensor System Using Logic Gates Based on Ising Dynamics,” the entirety of which is incorporated by reference herein.

### STATEMENT REGARDING FEDERALLY SPONSORED RESEARCH OR DEVELOPMENT

This invention was made with government support under Grant Number CCF-2103351 awarded by the National Science Foundation. The government has certain rights in the invention.

### BACKGROUND

The fusion of Artificial Intelligence (AI) with the Internet of Things (IoT) has been enabling decision-making processes based on data collected by widespread sensor deployments. This often requires intensive cloud computing resources, which can be impractical when rapid decision-making is needed, like in industrial automation, autonomous vehicles, and healthcare monitoring [1], [2]. Consequently, the IoT is shifting towards the adoption of new wireless sensors offering distributed computing capabilities not relying on cloud connectivity [3], [4]. A key requirement for these new wireless sensors is to perform “threshold sensing” [5]-[8], which involves identifying events where a parameter of interest (PoI) falls outside the range of acceptable values. Threshold sensing is also a key functionality in neural networks where devices emulating neurons “fire” only when their input signal surpasses a certain threshold [9]-[12]. Unfortunately, current wireless sensors suitable for threshold sensing are active sensors that rely on onboard batteries, making them expensive, bulky, environmentally unfriendly, and necessitating periodic battery replacements and maintenance. This constraint heavily limits their usability in widespread sensor deployments [13]. As a result, there has been increased attention into the adoption of passive wireless sensor devices, namely passive tags (or nodes), to implement threshold sensing [14]-[20].

Contrary to their active counterparts, passive tags are unable to independently recognize violations in their PoI because of their heavily limited signal processing capabilities. A passive tag typically acts as a linear electromagnetic scatterer. As a result, it responds to the interrogation signal produced by an interrogating device (i.e., a “reader”) by generating a backscattered signal with a modulated amplitude or phase dependent on the value of the targeted PoI. Then, it falls upon the reader to determine whether a violation in the targeted PoI at the tag's location has occurred or not, and the reader performs this operation by analyzing the portion of the tag's backscattered signal it receives.

Unfortunately, readers are typically unable to execute this task accurately for two reasons. The first reason, as shown in FIG. 1A, is the occurrence of multipath interference [14]-[17], wherein passive tags' backscattered signal interacts with the tags' surroundings, leading to distortions in both the amplitude and phase of readers' received signals. These distortions can be severe, especially in indoor or underground environments. The second reason, as shown in FIG. 1B, stems from co-site interference caused by other passive tags monitoring the same PoI at nearby locations. Passive tags, in fact, typically generate a backscattered signal irrespective of the value of the targeted PoI. As a result, they inherently pollute the electromagnetic spectrum by also generating their backscattered signal when no violation in their targeted PoI occurs. This behavior further compromises the readers' ability to successfully extract reliable information from their received signal as it incorporates portions of backscattered signals coming from all the passive tags reached by the interrogation signal. As a result, readers of passive tags currently face even bigger challenges in performing threshold sensing when a dense array of IoT tags is deployed within their interrogation range.

To overcome all these limitations, passive tags should be able to autonomously identify PoI-violations and generate a backscattered signal only when such violations occur, while staying “quiet” when no violation is detected. At the same time, passive tags for threshold sensing should also offer the ability to program their threshold, like their active counterparts. This is particularly important to ensure that the same passive tag can be used in applications that require monitoring a variety of heterogeneous items [21], [22].

Only recently, passive tags exploiting nonlinear processes have been proposed [18], to overcome the limited signal processing functionalities of linear passive tags and enable an autonomous implementation of threshold sensing. In these nonlinear tags, PoI violations activate an internal oscillation through a subcritical bifurcation, effectively triggering an alarm in the RF spectrum [18]. Different from their linear counterparts, these nonlinear tags can naturally exhibit different thresholds depending on the interrogation frequency. However, their reliance on subcritical bifurcations for implementing threshold sensing inevitably results in a large responsivity to fluctuations of their input power. Large fluctuations of these tags' input power can originate from multipath interference or from changes in the distance between these nonlinear passive tags and their reader [20]. The effect of these fluctuations can be very deleterious, making it challenging to use these tags in indoor or underground settings. Hence, a technological void in passive tags suitable for threshold sensing remains, and developing alternative passive tag technologies has become essential.

In a parallel field of research, the Ising model has been a subject of extensive research over the past 60 years [23], [24]. Originally devised to capture the phenomena driving phase transitions in ferromagnetic materials, this model has been applied to investigate the characteristics of superconductors and other condensed matter systems [25]. It has also been instrumental in understanding both equilibrium and nonequilibrium phenomena in statistical mechanics, as well as in tackling combinatorial optimization problems that defy traditional von Neumann computing architectures [26]. In the realm of optimization, the Ising model has been employed to describe the collective behavior of dissipatively coupled parametric oscillators (POs) [27]-[31]. Within this framework, studies have revealed that a network of resistively coupled electrical POs naturally converges towards a collective oscillation state that minimizes a Lyapunov function [32], [33]. This allows the network to evolve towards the ground state configuration of its Hamiltonian, enabling the use of networks of POs to solve combinatorial optimization problems [27], [29], [32]-[34]. While Ising systems formed by dissipatively coupled POs have been previously studied, only a few studies [28], have looked at the exploitation of the same dynamics exploited by these Ising systems in networks of POs coupled by dispersive frequency-dependent components, and these prior works are predominantly theoretical.

### SUMMARY

Described herein are Ising tags having coupled nonlinear parametric oscillators (POs) for threshold sensing of parameters of interest (PoIs). In some embodiments, such Ising tags can function as radio frequency (RF) passive tags (PTs) providing passive, robust, and reprogrammable threshold sensing insensitive to multi-path and reader self-interference. Furthermore, Ising tags having a plurality of coupled POs and sensor elements sensitive to various PoIs can advantageously provide multidimensional threshold sensing wherein the sensing threshold encompasses a locus of all combinations of values of the various PoIs for which the output signals of the POs constructively interfere to increase an output power of Ising tag.

In one aspect an Ising logic-gate is provided. The Ising logic-gate includes at least four parametric oscillators (POs), each coupled to and power-combined with at least one other of the at least four POs, each of the at least four POs configured to passively activate, responsive to a pump signal exceeding a threshold power of the PO, a parametric oscillation having an oscillation frequency equal to half an angular input frequency of the pump signal, wherein an output signal of the PO can be switched between an in-phase state and an out-of-phase state. The Ising logic-gate also includes a first coupling element for coupling first and second POs of the at least four POs to provide a first block having a first mode corresponding to a first logical input, wherein the first mode is passively activatable via passive activation of the first and/or second POs a first block output. The Ising logic-gate also includes a second coupling element for coupling third and fourth POs of the at least four POs to provide second block having a second mode corresponding to a second logical input, wherein the second mode is passively activatable via passive activation of the third and/or fourth POs to produce a second block output. The Ising logic-gate also includes a third coupling element for coupling two of the at least four POs to provide a third block having a third mode, the third mode passively activatable to produce a third block output tuned to selectively either frustrate the first block output and/or the second block output to produce a combined output signal having a negligible amplitude or constructively interfere with the first block output and/or the second block output to produce the combined output signal having a detectable amplitude; and a power combiner for power-combining the block outputs produced by the first, second, and third blocks and to produce the combined output signal indicating an in-phase or out-of-phase state of the Ising logic-gate.

In some embodiments, the third block is tuned to produce the combined output signal having the negligible amplitude only when the first mode and the second mode are both inactive. In some embodiments, the Ising logic-gate is an OR gate. In some embodiments, the third block is tuned to produce the combined output signal having the negligible amplitude when the first mode and the second mode are either both inactive or both active. In some embodiments, the Ising logic-gate is an XOR gate. In some embodiments, the Ising logic-gate also includes a fourth coupling element for coupling two of the at least four POs not coupled by the third coupling element to provide a fourth block having a fourth mode, the fourth mode passively activatable to produce a fourth block output tuned to selectively either frustrate the first, second, and/or third block output to produce the combined output signal having the negligible amplitude or constructively interfere with the first, second, and/or third block output to produce the combined output signal having the detectable amplitude. In some embodiments, the third and fourth blocks are tuned produce the combined output signal having the detectable amplitude only when the first mode and the second mode are both active. In some embodiments, the Ising logic-gate is an AND gate.

In some embodiments, the first coupling element is a first sensor element for sensing a first parameter of interest, wherein the first sensor element is configured to set the threshold power of the first and second POs to be exceeded by a power of the pump signal responsive to a value of the first parameter of interest exceeding a first parameter of interest threshold. In some embodiments, the second coupling element is a second sensor element for sensing a second parameter of interest, wherein the second sensor element is configured to set the threshold power of the third and fourth POs to be exceeded by a power of the pump signal responsive to a value of the second parameter of interest exceeding a second parameter of interest threshold. In some embodiments, a multidimensional sensing threshold of the Ising logic-gate is defined as a locus of all combinations of values of the first and second parameters of interest for which the block outputs constructively interfere to produce the combined output signal having the detectable amplitude. In some embodiments, the Ising logic-gate also includes at least one additional coupling element for coupling an additional PO of the at least four POs to one of the first, second, third, fourth, or another of the POs to provide a fourth block having a fourth mode, wherein the fourth mode is passively activatable via passive activation of the additional and/or the one of the first, second, third, fourth, or another of the POs to produce a fourth block output. In some embodiments, the first coupling element is a first sensor element for sensing a first parameter of interest, wherein the first sensor element is configured to set the threshold power of the first and second POs to be exceeded by a power of the pump signal responsive to a value of the first parameter of interest exceeding a first parameter of interest threshold. In some embodiments, the second coupling element is a second sensor element for sensing a second parameter of interest, wherein the second sensor element is configured to set the threshold power of the third and fourth POs to be exceeded by a power of the pump signal responsive to a value of the second parameter of interest exceeding a second parameter of interest threshold. In some embodiments, the at least one additional coupling element comprises at least one additional sensor element for sensing at least one additional parameter of interest, wherein the at least one additional sensor element is configured to set the threshold power of the additional and/or the one of the first, second, third, fourth, or another of the POs to be exceeded by a power of the pump signal responsive to a value of the at least one additional parameter of interest exceeding an at least one additional parameter of interest threshold. In some embodiments, a multidimensional sensing threshold of the Ising logic-gate is defined as a locus of all combinations of values of the first, second, and at least one additional parameters of interest for which the block outputs of the at least four POs constructively interfere to produce the combined output signal having the detectable amplitude. In some embodiments, the first, second, and at least one additional sensor elements have a same resonance frequency when the values of the respective first, second, and at least one additional parameters of interest do not exceed the respective first, second, and at least one additional parameter of interest parameter of interest thresholds. In some embodiments, first, second, and at least one additional sensor elements includes one or more resistive elements, inductive elements, capacitive elements, resonant elements, or combinations thereof. In some embodiments, each of the first, second, and at least one additional sensor elements produces a capacitive readout. In some embodiments, each of the first, second, and at least one additional sensor elements includes a combination of resistive elements, capacitive elements, and resonant elements. In some embodiments, each of the first, second, and at least one additional sensor elements includes one or more of a piezoelectric resonator, a MEMS resonator, a NEMS resonator, or a combination thereof.

In some embodiments, the power combiner is a Wilkinson power combiner. In some embodiments, each PO also includes a resonant input mesh driven by the pump signal. In some embodiments, each PO also includes a resonant output mesh coupled to the input mesh through a nonlinear component to form a parametric frequency divider. In some embodiments, the nonlinear component is configured to passively activate, responsive to the pump signal exceeding the threshold power of the PO, the parametric oscillation between the input and output meshes, the parametric oscillation having the oscillation frequency equal to half the angular input frequency of the pump signal, wherein the output signal of the PO can be switched between the in-phase state and the out-of-phase state. In some embodiments, a characteristic of the nonlinear component is modulated at the angular input frequency of the pump signal. In some embodiments, the nonlinear component has a nonlinear reactance. In some embodiments, the nonlinear component includes one or more of a diode, a varactor, or a combination thereof. In some embodiments, the nonlinear component includes a varactor and an inductor, wherein the input mesh and the output mesh are coupled through the varactor and the inductor. In some embodiments, the input mesh includes an input filter to constrain the pump signal within the input mesh to the angular input frequency of the pump signal. In some embodiments, the output mesh includes an output filter to constrain the output signal within the output mesh to half of the angular input frequency of the pump signal. In some embodiments, the output mesh is configured to series-resonate at half the angular input frequency of the pump signal. In some embodiments, each of the input mesh and the output mesh includes a resonator. In some embodiments, each resonator includes one or more of an electrical resonator, a piezoelectric resonator, a MEMS resonator, a NEMS resonator, an optical resonator, a non-Hermitian resonator, an electromagnetic resonator, or a combination thereof.

In another aspect, an Ising logic system having logic gates based on Ising dynamics is provided. The Ising logic system includes an Ising logic-gate. The Ising logic-gate includes an input antenna. The Ising logic-gate also includes an output antenna. The Ising logic-gate also includes at least four parametric oscillators (POs), each coupled to and power-combined with at least one other of the at least four POs, each of the at least four POs configured to passively activate, responsive to a pump signal exceeding a threshold power of the PO, a parametric oscillation having an oscillation frequency equal to half an angular input frequency of the pump signal, wherein an output signal of the PO can be switched between an in-phase state and an out-of-phase state. The Ising logic-gate also includes a first coupling element for coupling first and second POs of the at least four POs to provide a first block having a first mode corresponding to a first logical input, wherein the first mode is passively activatable via passive activation of the first and/or second POs a first block output. The Ising logic-gate also includes a second coupling element for coupling third and fourth POs of the at least four POs to provide second block having a second mode corresponding to a second logical input, wherein the second mode is passively activatable via passive activation of the third and/or fourth POs to produce a second block output. The Ising logic-gate also includes a third coupling element for coupling two of the at least four POs to provide a third block having a third mode, the third mode passively activatable to produce a third block output tuned to selectively either frustrate the first block output and/or the second block output to produce a combined output signal having a negligible amplitude or constructively interfere with the first block output and/or the second block output to produce the combined output signal having a detectable amplitude. The Ising logic-gate also includes a power combiner for power-combining the block outputs produced by the first, second, and third blocks and to produce the combined output signal indicating an in-phase or out-of-phase state of the Ising logic-gate. The Ising logic system also includes a reader configured to produce the pump signal and to read the combined output signal, wherein the reader is configured to detect an in-phase or out-of-phase state of the Ising logic-gate.

In some embodiments, the Ising logic-gate is at least one of an OR gate, an XOR gate, an AND gate, a NOR gate, or a NAND gate.

In a further aspect, an Ising logic-gate is provided. The Ising logic-gate includes at least four parametric oscillators (POs), each coupled to and power-combined with at least one other of the at least four POs, each of the at least four POs configured to passively activate, responsive to a pump signal exceeding a threshold power of the PO, a parametric oscillation having an oscillation frequency equal to half an angular input frequency of the pump signal, wherein an output signal of the PO can be switched between an in-phase state and an out-of-phase state. The Ising logic-gate also includes a plurality of coupling elements for coupling the at least four POs to form a plurality of blocks, each block comprising a coupled two of the at least four POs and having a mode corresponding to or interactive with a logical input, wherein the mode is passively activatable via passive activation of at least one of the coupled two of the at least four POs to produce a corresponding block output, the plurality of blocks producing a corresponding plurality of block outputs. The Ising logic-gate also includes wherein the plurality of block outputs are tuned to selectively either frustrate at least one other of the plurality of block outputs to produce a combined output signal having a negligible amplitude or constructively interfere with the at least one other of the plurality of block outputs to produce the combined output signal having a detectable amplitude. The Ising logic-gate also includes a power combiner for power-combining the plurality of block outputs and for producing the combined output signal indicating an in-phase or out-of-phase state of the Ising logic-gate.

In some embodiments, the Ising logic-gate is at least one of an OR gate, an XOR gate, an AND gate, a NOR gate, or a NAND gate. In some embodiments, the at least four POs and the plurality of coupling elements are coupled to form a NOR gate. In some embodiments, the NOR gate includes six POs, a first coupling element coupling a first PO and a second PO, a second coupling element coupling the second PO and a third PO, a third coupling element coupling the third PO and a fourth PO, a fourth coupling element coupling the fourth PO and a fifth PO, a fifth coupling element coupling the fifth PO and a sixth PO, a sixth coupling element coupling the first PO and the fifth PO, a seventh coupling element coupling the first PO and the sixth PO, and an eighth coupling element coupling the second PO and the fourth PO. In some embodiments, the at least four POs and the plurality of coupling elements are coupled to form a NAND gate. In some embodiments, the NAND gate includes six POs, a first coupling element coupling a first PO and a second PO, a second coupling element coupling the first PO and a third PO, a third coupling element coupling the first PO and a fourth PO, a fourth coupling element coupling the first PO and a fifth PO, and a fifth coupling element coupling the first PO and a sixth PO. In some embodiments, the at least four POs and the plurality of coupling elements are coupled in a Mobius Ladder topology.

Additional features and aspects of the technology include the following:
1. An Ising logic-gate comprising:
   at least four parametric oscillators (POs), each coupled to and power-combined with at least one other of the at least four POs, each of the at least four POs configured to passively activate, responsive to a pump signal exceeding a threshold power of the PO, a parametric oscillation having an oscillation frequency equal to half an angular input frequency of the pump signal, wherein an output signal of the PO can be switched between an in-phase state and an out-of-phase state;
   a first coupling element for coupling first and second POs of the at least four POs to provide a first block having a first mode corresponding to a first logical input, wherein the first mode is passively activatable via passive activation of the first and/or second POs a first block output;
   a second coupling element for coupling third and fourth POs of the at least four POs to provide second block having a second mode corresponding to a second logical input, wherein the second mode is passively activatable via passive activation of the third and/or fourth POs to produce a second block output;
   a third coupling element for coupling two of the at least four POs to provide a third block having a third mode, the third mode passively activatable to produce a third block output tuned to selectively either frustrate the first block output and/or the second block output to produce a combined output signal having a negligible amplitude or constructively interfere with the first block output and/or the second block output to produce the combined output signal having a detectable amplitude; and
   a power combiner for power-combining the block outputs produced by the first, second, and third blocks and to produce the combined output signal indicating an in-phase or out-of-phase state of the Ising logic-gate.
2. The Ising logic-gate of feature 1, wherein the third block is tuned to produce the combined output signal having the negligible amplitude only when the first mode and the second mode are both inactive.
3 The Ising logic-gate of feature 2, wherein the Ising logic-gate is an OR gate.
4. The Ising logic-gate of any of features 1-2, wherein the third block is tuned to produce the combined output signal having the negligible amplitude when the first mode and the second mode are either both inactive or both active.
5. The Ising logic-gate of feature 4, wherein the Ising logic-gate is an XOR gate.
6. The Ising logic-gate of any of features 1-5, further comprising:
   a fourth coupling element for coupling two of the at least four POs not coupled by the third coupling element to provide a fourth block having a fourth mode, the fourth mode passively activatable to produce a fourth block output tuned to selectively either frustrate the first, second, and/or third block output to produce the combined output signal having the negligible amplitude or constructively interfere with the first, second, and/or third block output to produce the combined output signal having the detectable amplitude.
7. The Ising logic-gate of any of features 1-6, wherein the third and fourth blocks are tuned produce the combined output signal having the detectable amplitude only when the first mode and the second mode are both active.
8. The Ising logic-gate of feature 7, wherein the Ising logic-gate is an AND gate.
9. The Ising logic-gate of any of features 1-8, wherein:
   the first coupling element is a first sensor element for sensing a first parameter of interest, wherein the first sensor element is configured to set the threshold power of the first and second POs to be exceeded by a power of the pump signal responsive to a value of the first parameter of interest exceeding a first parameter of interest threshold; and
   the second coupling element is a second sensor element for sensing a second parameter of interest, wherein the second sensor element is configured to set the threshold power of the third and fourth POs to be exceeded by a power of the pump signal responsive to a value of the second parameter of interest exceeding a second parameter of interest threshold.
10. The Ising logic-gate of any of features 1-9, wherein:
   a multidimensional sensing threshold of the Ising logic-gate is defined as a locus of all combinations of values of the first and second parameters of interest for which the block outputs constructively interfere to produce the combined output signal having the detectable amplitude.
11. The Ising logic-gate of any of features 1-10, further comprising:
   at least one additional coupling element for coupling an additional PO of the at least four POs to one of the first, second, third, fourth, or another of the POs to provide a fourth block having a fourth mode, wherein the fourth mode is passively activatable via passive activation of the additional and/or the one of the first, second, third, fourth, or another of the POs to produce a fourth block output.
12. The Ising logic-gate of feature 11, wherein:
   the first coupling element is a first sensor element for sensing a first parameter of interest, wherein the first sensor element is configured to set the threshold power of the first and second POs to be exceeded by a power of the pump signal responsive to a value of the first parameter of interest exceeding a first parameter of interest threshold;
   the second coupling element is a second sensor element for sensing a second parameter of interest, wherein the second sensor element is configured to set the threshold power of the third and fourth POs to be exceeded by a power of the pump signal responsive to a value of the second parameter of interest exceeding a second parameter of interest threshold; and
   the at least one additional coupling element comprises at least one additional sensor element for sensing at least one additional parameter of interest, wherein the at least one additional sensor element is configured to set the threshold power of the additional and/or the one of the first, second, third, fourth, or another of the POs to be exceeded by a power of the pump signal responsive to a value of the at least one additional parameter of interest exceeding an at least one additional parameter of interest threshold.
13. The Ising logic-gate of feature 12, wherein:
   a multidimensional sensing threshold of the Ising logic-gate is defined as a locus of all combinations of values of the first, second, and at least one additional parameters of interest for which the block outputs of the at least four POs constructively interfere to produce the combined output signal having the detectable amplitude.
14. The Ising logic-gate of feature 12, wherein the first, second, and at least one additional sensor elements have a same resonance frequency when the values of the respective first, second, and at least one additional parameters of interest do not exceed the respective first, second, and at least one additional parameter of interest parameter of interest thresholds.
15. The Ising logic-gate of feature 12, wherein first, second, and at least one additional sensor elements includes one or more resistive elements, inductive elements, capacitive elements, resonant elements, or combinations thereof.
16. The Ising logic-gate of feature 15, wherein each of the first, second, and at least one additional sensor elements produces a capacitive readout.
17. The Ising logic-gate of feature 15, wherein each of the first, second, and at least one additional sensor elements includes a combination of resistive elements, capacitive elements, and resonant elements.
18. The Ising logic-gate of feature 15, wherein each of the first, second, and at least one additional sensor elements includes one or more of a piezoelectric resonator, a MEMS resonator, a NEMS resonator, or a combination thereof.
19. The Ising logic-gate of any of features 1-18, wherein the power combiner is a Wilkinson power combiner.
20. The Ising logic-gate of any of features 1-19, wherein each PO further comprises:
   a resonant input mesh driven by the pump signal;
   a resonant output mesh coupled to the input mesh through a nonlinear component to form a parametric frequency divider; and
   the nonlinear component configured to passively activate, responsive to the pump signal exceeding the threshold power of the PO, the parametric oscillation between the input and output meshes, the parametric oscillation having the oscillation frequency equal to half the angular input frequency of the pump signal,
   wherein the output signal of the PO can be switched between the in-phase state and the out-of-phase state.
21. The Ising logic-gate of feature 20, wherein a characteristic of the nonlinear component is modulated at the angular input frequency of the pump signal.
22. The Ising logic-gate of feature 20, wherein the nonlinear component has a nonlinear reactance.
23. The Ising logic-gate of feature 22, wherein the nonlinear component includes one or more of a diode, a varactor, or a combination thereof.
24. The Ising logic-gate of feature 23, wherein the nonlinear component includes a varactor and an inductor, wherein the input mesh and the output mesh are coupled through the varactor and the inductor.
25. The Ising logic-gate of any of features 20-24, wherein:
   the input mesh includes an input filter to constrain the pump signal within the input mesh to the angular input frequency of the pump signal; and
   the output mesh includes an output filter to constrain the output signal within the output mesh to half of the angular input frequency of the pump signal.
26. The Ising logic-gate of any of features 20-25, wherein the output mesh is configured to series-resonate at half the angular input frequency of the pump signal.
27. The Ising logic-gate of any of features 20-26, wherein each of the input mesh and the output mesh includes a resonator.
28. The Ising logic-gate of feature 27, wherein each resonator includes one or more of an electrical resonator, a piezoelectric resonator, a MEMS resonator, a NEMS resonator, an optical resonator, a non-Hermitian resonator, an electromagnetic resonator, or a combination thereof.
29. A Ising logic system having logic gates based on Ising dynamics comprising:
   an Ising logic-gate including:
      an input antenna;
      an output antenna;
      at least four parametric oscillators (POs), each coupled to and power-combined with at least one other of the at least four POs, each of the at least four POs configured to passively activate, responsive to a pump signal exceeding a threshold power of the PO, a parametric oscillation having an oscillation frequency equal to half an angular input frequency of the pump signal, wherein an output signal of the PO can be switched between an in-phase state and an out-of-phase state;
      a first coupling element for coupling first and second POs of the at least four POs to provide a first block having a first mode corresponding to a first logical input, wherein the first mode is passively activatable via passive activation of the first and/or second POs a first block output;
      a second coupling element for coupling third and fourth POs of the at least four POs to provide second block having a second mode corresponding to a second logical input, wherein the second mode is passively activatable via passive activation of the third and/or fourth POs to produce a second block output;
      a third coupling element for coupling two of the at least four POs to provide a third block having a third mode, the third mode passively activatable to produce a third block output tuned to selectively either frustrate the first block output and/or the second block output to produce a combined output signal having a negligible amplitude or constructively interfere with the first block output and/or the second block output to produce the combined output signal having a detectable amplitude; and
      a power combiner for power-combining the block outputs produced by the first, second, and third blocks and to produce the combined output signal indicating an in-phase or out-of-phase state of the Ising logic-gate; and
   a reader configured to produce the pump signal and to read the combined output signal, wherein the reader is configured to detect an in-phase or out-of-phase state of the Ising logic-gate.
30. The Ising logic system of feature 29, wherein the Ising logic-gate is at least one of an OR gate, an XOR gate, an AND gate, a NOR gate, or a NAND gate.
31. An Ising logic-gate comprising:
   at least four parametric oscillators (POs), each coupled to and power-combined with at least one other of the at least four POs, each of the at least four POs configured to passively activate, responsive to a pump signal exceeding a threshold power of the PO, a parametric oscillation having an oscillation frequency equal to half an angular input frequency of the pump signal, wherein an output signal of the PO can be switched between an in-phase state and an out-of-phase state;
   a plurality of coupling elements for coupling the at least four POs to form a plurality of blocks, each block comprising a coupled two of the at least four POs and having a mode corresponding to or interactive with a logical input, wherein the mode is passively activatable via passive activation of at least one of the coupled two of the at least four POs to produce a corresponding block output, the plurality of blocks producing a corresponding plurality of block outputs;
   wherein the plurality of block outputs are tuned to selectively either frustrate at least one other of the plurality of block outputs to produce a combined output signal having a negligible amplitude or constructively interfere with the at least one other of the plurality of block outputs to produce the combined output signal having a detectable amplitude; and
   a power combiner for power-combining the plurality of block outputs and for producing the combined output signal indicating an in-phase or out-of-phase state of the Ising logic-gate.
32. The Ising logic-gate of feature 31, wherein the Ising logic-gate is at least one of an OR gate, an XOR gate, an AND gate, a NOR gate, or a NAND gate.
33. The Ising logic-gate of any of features 31-32, wherein the at least four POs and the plurality of coupling elements are coupled to form a NOR gate.
34. The Ising logic-gate of feature 33, wherein the NOR gate includes:
   six POs;
   a first coupling element coupling a first PO and a second PO;
   a second coupling element coupling the second PO and a third PO;
   a third coupling element coupling the third PO and a fourth PO;
   a fourth coupling element coupling the fourth PO and a fifth PO;
   a fifth coupling element coupling the fifth PO and a sixth PO;
   a sixth coupling element coupling the first PO and the fifth PO;
   a seventh coupling element coupling the first PO and the sixth PO; and
   an eighth coupling element coupling the second PO and the fourth PO.
35. The Ising logic-gate of any of features 31-32, wherein the at least four POs and the plurality of coupling elements are coupled to form a NAND gate.
36. The Ising logic-gate of feature 35, wherein the NAND gate includes:
   six POs;
   a first coupling element coupling a first PO and a second PO;
   a second coupling element coupling the first PO and a third PO;
   a third coupling element coupling the first PO and a fourth PO;
   a fourth coupling element coupling the first PO and a fifth PO; and
   a fifth coupling element coupling the first PO and a sixth PO.
37. The Ising logic-gate of any of features 31-36, wherein the at least four POs and the plurality of coupling elements are coupled in a Mobius Ladder topology.

### BRIEF DESCRIPTION OF THE DRAWINGS

FIG. 1A illustrates a symbolic schematic representation of multipath interference associated with prior art passive tags, which inevitably distorts the portion of the prior art passive tags' backscattered signal received by a reader.

FIG. 1B illustrates a symbolic schematic representation of co-site interference associated with prior art passive tags, wherein the same interrogation signal is received by many passive tags nearby, with each tag responding by generating its own separate return signal such that a plurality of similar return signals are simultaneously received by a reader.

FIG. 2A illustrates a symbolic schematic representation of an ideal non-interference scenario for threshold sensing using passive Ising tags as shown and described herein. Each of the passive Ising tags only produces a backscattered signal when a threshold violation of its PoI occurs. As a result, tags that do not detect any violations will not generate a return signal, even when those tags receive interrogation signals with comparable power levels.

FIG. 2B illustrates a simplified circuit schematic of an Ising tag having two parametric oscillators (POs) coupled by a coupling element and power combined at its output. The Ising tag is terminated using an input and output antenna operating at fₚ and fₚ/2, respectively.

FIG. 2C illustrates an example of the phase synchronization dynamics of the Ising tag of FIG. 2B by which it embeds its PoI threshold sensing functionality. As shown, exposure to or detection of a threshold PoI can change the preferred coupling state between the POs, wherein the tag produces either in-phase (ferromagnetic) or out-of-phase (anti-ferromagnetic) output signals.

FIG. 2D illustrates an output waveform of the Ising tag of FIG. 2B when the POs are either in an anti-ferromagnetic (out-of-phase) or ferromagnetic (in-phase) coupling state.

FIG. 3A illustrates a qualitative comparison between various state-of-the-art passive sensor technologies and the Synchronization technology described herein in accordance with various embodiments. It is noted that, with respect to “wireless reprogramming of sensing threshold,” unlike the present “synchronization” technology or the “subcritical bifurcations” technology, sensors using the “linear backscattering with continuous sensing” technology generally perform the wireless threshold reprogramming during post-processing of the sensed data, rather than during acquisition of the data. It is also noted that, with respect to “reversibility,” unlike the other technologies, sensors using the “linear backscattering with PoI-sensitive shape-transforming passive tags” technology may not always be reversible because not all shape transformation materials used in passive threshold sensing are strictly reversible.

FIGS. 3B-3E illustrate symbolic schematic representations of the sensor technologies compared in FIG. 3A wherein FIG. 3B illustrates continuous sensing linear backscattering, FIG. 3C illustrates shape transformation linear backscattering, FIG. 3D illustrates subcritical bifurcations, and FIG. 3E illustrates synchronization.

FIG. 4A illustrates a circuit schematic of an Ising tag in accordance with various embodiments. The tag includes two POs coupled together using a coupling element Z_{C} including a PoI sensitive element (e.g., a piezoelectric microacoustic resonator Zᵣₑₛ as shown) and a power combiner (e.g., a Wilkinson power combiner as shown).

FIG. 4B illustrates a Butterworth Van-Dyke (BVD) circuit model of the PoI sensitive piezoelectric resonator (Zᵣₑₛ) of the coupling element (Z_{C}) of FIG. 4A.

FIG. 4C illustrates a BVD circuit model of the power combiner of FIG. 4A. The power combiner's equivalent circuit includes two equal transmission lines with characteristic impedance equal to (Z_{TL}) connected to an isolation resistance (Rᵢₛₒ).

FIG. 4D illustrates a symbolic schematic of an Ising tag that is tailored for the application of the even and odd mode circuit technique. No input antenna is shown but the output antenna's input impedance (Z_{L}). To use the even and odd mode circuit decompositions, Z_{L} is shown as a parallel combination of two equal resistors with resistance 2Z_{L} while Zᵣₑₛ is shown as a series of two identical impedances equal to Zᵣₑₛ/2. An axis of symmetry is drawn to illustrate the basis for the even and odd mode circuit analysis.

FIG. 4E illustrates even mode decomposition of the Ising tag, wherein an equivalent impedance Z_{eq} connected to each PO is unaffected by Zᵣₑₛ, while being set strictly by Z_{W,E}.

FIG. 4F illustrates odd mode decomposition of the Ising tag, wherein the equivalent impedance Z_{eq} connected to each PO includes both Zᵣₑₛ/2 and Z_{W,O}.

FIG. 4G illustrates a circuit schematic showing the circuit design of a single electronic PO and delineating which components are part of the Z₁, Z₂, and Z₃ branches of the PO.

FIG. 4H illustrates 4 resonance conditions that enable minimization of an input power level required to start a subharmonic oscillation of the PO of FIG. 4G. It is noted that the P_{th,E} and P_{th,O} trends shown and described herein below were obtained by embedding the respective Z_{eq} into the output port of the Z₂ branch.

FIG. 5A illustrates a numerically extracted difference between P_{th,E} and P_{th,O} wherein the coupling impedance Z_{C} includes only a LiNbO₃ piezoelectric resonator and wherein a range of fₚ values corresponding to fₚ/2 values are close to the series resonance frequency of the LiNbO₃ piezoelectric resonator.

FIG. 5B illustrates a numerically extracted difference between P_{th,E} and P_{th,O} wherein Z_{C} includes both the LiNbO₃ piezoelectric resonator and a power combiner for the same range of fₚ used for FIG. 5A.

FIG. 5C illustrates numerically extracted trends of P_{th,E} and P_{th,O} with respect to different Tₐ values and an arbitrarily selected fₚ/2 value of 432 MHz.

FIG. 5D illustrates numerically extracted trends of P_{th,E} and P_{th,O} with respect to different Tₐ values and an arbitrarily selected fₚ/2 value of 438 MHz.

FIG. 6A illustrates an even and odd mode circuit analysis for a Wilkinson Power Combiner showing a circuit schematic of an ideal Wilkinson power combiner circuit, specifically illustrating its axis of symmetry.

FIG. 6B-C illustrate Even and odd mode equivalent circuits of the Wilkinson power combiner shown in FIG. 6A. Both circuits exhibit an equivalent impedance matched to Z_{L} when operating at one targeted design frequency. These circuits also have input impedances equal to Z_{W,E} and Z_{W,O}, respectively.

FIG. 7A illustrates a symbolic schematic of a network of two POs terminated to 50Ω loads, coupled by using an arbitrary impedance Z_{C}. Similar to FIG. 4D, Z_{C} is represented as the series of two identical impedances equal to Z_{C}/2.

FIG. 7B illustrates numerically extracted trends at a fixed Z_{C}/2 value (438 MHz) for P_{th,E} and P_{th,O} when considering Z_{C} to be purely resistive with a resistance ranging from 2Ω to 2 kΩ.

FIG. 7C illustrates numerically extracted trends at a fixed Z_{C}/2 value (438 MHz) for P_{th,E} and P_{th,O} when considering Z_{C} to be a purely inductive element with a reactance ranging from 2Ω to 2 kΩ.

FIG. 7D illustrates numerically extracted trends at a fixed Z_{C}/2 value (438 MHz) for P_{th,E} and P_{th,O} when considering Z_{C} to be a purely capacitive element with a reactance ranging from −2 kΩ to −2Ω.

FIG. 8A illustrates analytically extracted trends of P_{th,E} and P_{th,O} when considering a Tₐ for a fixed fₚ/2 of 438 MHz.

FIG. 8B illustrates analytically extracted trends of P_{th,E} and P_{th,O} when considering a Tₐ for a fixed fₚ/2 of 432 MHz.

FIG. 8C illustrates experimental results at room temperature demonstrating that fₗ does not exist in the SPIN prototype when the power combiner is removed from the coupling network.

FIG. 9 illustrates a coupled mode theory model schematic of a PO system of interest wherein a and b are both coupled to c. Intracavity modes a and b are described with a gain saturation coefficient r₁, a small-signal gain parameter r₂, and total loss rate κ_{a,b}. These modes are coupled via g to c, a mechanical mode with a mechanical loss rate represented by Γ_{c}.

FIG. 10A illustrates an even and odd mode threshold comparison using coupled mode theory showing a numerically extracted trend of |r_{2,E}^{cr}|−|r_{2,O}^{cr}| for fₚ/2 near fᵣₑₛ. As can be noted, there exists a transition point fₕ where the preferred solution changes between ferromagnetic and anti-ferromagnetic coupling states.

FIGS. 10B-E illustrate simulated waveforms of the coupled POs extracted by solving Eq. (S.4-S.6) taken when fₚ/2==437.5 MHz, 440 MHz, 441 MHz, and 442 MHz, corresponding to points B-E in FIG. 10A.

FIG. 10F illustrates a numerically extracted trend of |r_{2,E}^{cr}|−|r_{2,O}^{cr}| for fₚ/2 near fᵣₑₛ for Tₐ=25° C., 50° C., and 75° C., demonstrating a temperature-dependent change in the position of fₕ.

FIGS. 11A-E illustrate plots showing simulated P_{th,E} and P_{th,O} at Tₐ=25° C. and for fₚ/2=428 MHz (FIG. 11A), 431 MHz (FIG. 11B), 435 MHz (FIG. 11C), 438 MHz (FIG. 11D), and 442 MHz (FIG. 11E). The plots of FIGS. 11A-E show a narrow range of Pᵢₙ surrounding P_{th,E} and P_{th,O}.

FIGS. 11F-J illustrate plots showing simulated P_{th,E} and P_{th,O} at Tₐ=75° C. and for fₚ/2=428 MHz (FIG. 11F), 431 MHz (FIG. 11G), 435 MHz (FIG. 11H), 438 MHz (FIG. 11I), and 442 MHz (FIG. 11J). The plots of FIGS. 11F-J show a narrow range of Pᵢₙ surrounding P_{th,E} and P_{th,O}.

FIGS. 12A-E illustrate plots showing numerically extracted voltage waveforms (PO₁ and PO₂) at Tₐ=25° C. and for fₚ/2=428 MHz (FIG. 12A), 431 MHz (FIG. 12B), 435 MHz (FIG. 12C), 438 MHz (FIG. 12D), and 442 MHz (FIG. 12E).

FIGS. 12F-J illustrate plots showing numerically extracted voltage waveforms (PO₁ and PO₂) at Tₐ=75° C. and for fₚ/2=428 MHz (FIG. 12F), 431 MHz (FIG. 12G), 435 MHz (FIG. 12H), 438 MHz (FIG. 12I), and 442 MHz (FIG. 12J).

FIGS. 13A-E illustrate plots showing numerically extracted Pₒᵤₜ for fₚ/2=428 MHz (FIG. 13A), 431 MHz (FIG. 13B), 435 MHz (FIG. 13C), 438 MHz (FIG. 13D), and 442 MHz (FIG. 13E) at Tₐ=75° C. and at Tₐ=75° C.

FIGS. 14A-D illustrate a method used for fabricating a lithium niobate (LiNbO₃) resonator used in a prototype Ising tag, wherein FIG. 14A illustrates a 1 μm thin film of LiNbO3 bonded onto a 4-inch Si wafer by implementing surface activation bonding, chemical mechanical polishing, and ion trimming, FIG. 14B illustrates sputtering and patterning of 200 nm AlSiCu electrodes to form the interdigitated structure of a microacoustic device, FIG. 14C illustrates a 72° substrate angle ion mill etching of the LiNbO3, and FIG. 14D illustrates release of the interdigitated structure using 18 cycles of XeF₂.

FIGS. 14E-F illustrate a stress mode shape in the propagation direction of the fabricated S₀ mode LVR taken from a cross-sectional view cutting through all electrodes (FIG. 14E) and a top-down view (FIG. 14F)

FIG. 14G illustrates an SEM image of the LiNbO3 SAW device manufactured for the prototype Ising tag by the method shown in FIGS. 14A-D.

FIG. 15A illustrates a plot showing measured and fitted admittance of the fabricated LiNbO3 resonator extracted by directly probing the device.

FIG. 15B illustrates a partial detail view of the measured admittance of FIG. 15A showing a narrow frequency range surrounding fᵣₑₛ for various Tₐ of the fabricated LiNbO3 resonator when wirebonded onto the PCB hosting the Ising tag.

FIG. 15C illustrates a measured trend of fᵣₑₛ with respect to Tₐ, which was used to extract a first order approximation of the Ising tag's TCF.

FIG. 15D illustrates a circuit schematic of the BVD model used in the circuit simulations mapping the Ising tag's behavior.

FIG. 16A illustrates numerically extracted trends of P_{th,E}−P_{th,O} against

$${k}_{t}^{2}$$

centered around fᵣₑₛ. As shown, the swept parameters do not disrupt execution of mode competition between the coupled POs.

FIG. 16B illustrates numerically extracted trends of P_{th,E}−P_{th,O} against Q_{S} centered around fᵣₑₛ. As shown, the swept parameters do not disrupt execution of mode competition between the coupled POs.

FIG. 17A illustrates a schematic of an experimental setup used for a wired experiment used to extract Pₜₕ of an Ising tag, wherein a signal generator is connected directly to the input of the Ising tag and the output signal is connected to a spectrum analyzer.

FIG. 17B illustrates an image of the prototype Ising tag manufactured for the wired experimental setup of FIG. 17A.

FIG. 18A illustrates a schematic of an experimental setup used for a wireless experiment wherein a signal generator connected to a power amplifier and a directive antenna interrogates the Ising tag situated atop a heated chuck. The backscattered signal is captured via an antenna through a spectrum analyzer and the fₚ/2 signal power received at the spectrum analyzer (P_{R}) is measured for each value of fₚ and Tₐ.

FIG. 18B illustrates measured P_{R} of the experimental Ising tag over a range of fₚ/2 values, including fₗ and fₕ, when considering different Tₐ values.

FIG. 18C illustrates measured P_{R} for various Tₐ and fₚ values (as shown fₚ is indicated in terms of fₚ/2), demonstrating the ability to reprogram the Ising tag's temperature threshold. The fₚ values were selected to correspond to the selected Tₜₕ values of 30° C., 40° C., 50° C., and 60° C.

FIG. 18D illustrates measured and numerically predicted trends of fₗ and fₕ with respect to Tₐ.

FIG. 18E illustrates measured Δφ values at Tₐ=25° C. for Pᵢₙ varying between −5 dBm and 5 dBm, when considering two different fₚ values (corresponding to fₚ/2 values equal to 440 MHz and 441 MHz)

FIG. 19A illustrates a schematic of an Ising tag for multidimensional threshold sensing (e.g., based on three different PoIs as shown).

FIG. 19B illustrates the connectivity and coupling scheme used by the Ising tag of FIG. 19A.

FIG. 19C illustrates a locus containing all combinations of the values of R₁₂, R₂₃, and R₃₄ for which the 4 POs in the Ising tag of FIG. 19A constructively interfere to yield a strong Pₒᵤₜ, wherein R₁₃ is assumed to be 120Ω.

FIG. 19D illustrates a deployed system having multiple multidimensional Ising tags to aid in solving optimization problems through remote sensing data acquired by a set of multidimensional Ising tags at various locations.

FIG. 20A illustrates a circuit schematic of a higher order SPIN behavior-mapped to an OR logic gate. In such a SPIN, the logical inputs A and B correspond to the detuning of the y_{1,2} and y_{3,4} mechanical resonant modes and the output is represented by the summation of the power generated at fₚ/2 by all POs.

FIGS. 20B-E illustrate maximum-cut solutions and numerically extracted summations of the POs' output waveforms for all the possible combinations of A and B. As shown, the system outputs a strong signal when either A or B is equal to 1 as well as when A=B=1. As also shown, the system produces a negligible output when A=B=0.

FIG. 21A illustrates a circuit schematic of a higher order SPIN behavior-mapped to a XOR logic gate. In such a SPIN, the logical inputs A and B correspond to the detuning of the y_{1,2} and y_{3,4} mechanical resonant modes and the output is represented by the summation of the power generated at fₚ/2 by all POs.

FIGS. 21B-E illustrate maximum-cut solutions and numerically extracted summations of the POs' output waveforms for all the possible combinations of A and B. As shown, the system outputs a strong signal when either A or B is equal to 1. As also shown, the system produces a negligible output for any condition where A=B.

FIG. 22A illustrates a circuit schematic of a higher order SPIN behavior-mapped to an AND logic gate. In such a SPIN, the logical inputs A and B correspond to the detuning of the y_{1,2} and y_{1,3} mechanical resonant modes and the output is represented by the strength of the summation of the bistable subharmonic waveforms generated by each PO.

FIGS. 22B-E illustrate maximum-cut solutions and numerically extracted summations of the POs' output waveforms for all the possible combinations of A and B. As shown, the system outputs a strong signal whenever A=B=1. As also shown, the system produces a negligible output for any other condition (either A or B is equal to 1 or A=B=0).

FIG. 23A illustrates a circuit schematic of a higher order SPIN behavior-mapped to a NOR logic gate. In such a SPIN, the logical inputs A and B correspond to the detuning of the y_{1,2} and y_{4,5} mechanical resonant modes and the output is represented by the summation of the power generated at fₚ/2 by all POs.

FIGS. 23B-E illustrate maximum-cut solutions and numerically extracted summations of the POs' output waveforms for all the possible combinations of A and B. As shown, the system outputs a strong signal when A=B=0. As also shown, the system produces a negligible output for any other condition (either A or B is equal to 1 or A=B=1).

FIG. 24A illustrates a circuit schematic of a higher order SPIN behavior-mapped to an NAND logic gate. In such a SPIN, the logical inputs A and B correspond to the detuning of the y_{1,2} and y_{1,6} mechanical resonant modes and the output is represented by the strength of the summation of the bistable subharmonic waveforms generated by each PO.

FIGS. 24B-E illustrate maximum-cut solutions and numerically extracted summations of the POs' output waveforms for all the possible combinations of A and B. As shown, the system outputs a strong signal when either A or B is equal to 1 as well as when A=B=0. As also shown, the system produces a negligible output when A=B=1.

FIG. 25A illustrates numerically extracted trends depicting the difference in Tₜₕ between a perfectly symmetric SPIN and a SPIN with a 2% detuning on a single PO when operating near fₗ.

FIG. 25B illustrates numerically extracted trends depicting the difference in Tₜₕ between a perfectly symmetric SPIN and a SPIN with a 2% detuning on a single PO when operating near fₕ.

FIG. 26A illustrates a schematic of a sample 6-PO SPIN coupled in a Mobius Ladder topology.

FIG. 26B illustrates numerically extracted trends of P_{GS} against N for a variety of different ηᵥ.

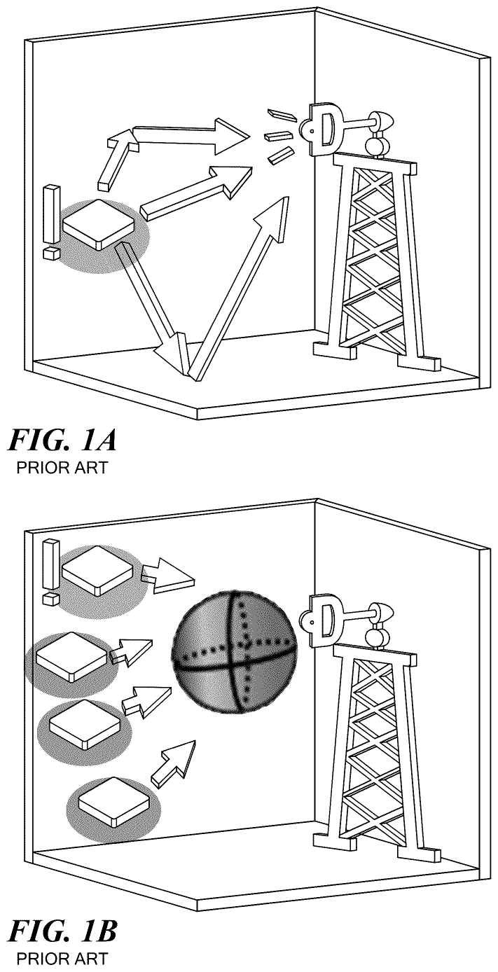

### DETAILED DESCRIPTION

The present technology provides the incorporation of Ising dynamics into radio frequency (RF) wireless technologies and offers the enhancement of modern wireless sensing capabilities. The present disclosure demonstrates a passive wireless sensor exploiting Ising dynamics, and its use to accurately implement threshold sensing. Implementations referred to herein as Sensing Parametric Ising Nodes (SPINs) or “Ising tags” correlate the occurrence of violations in a sensed parameter with transitions in the coupling state of two parametric oscillators (POs) acting as Ising spins. This feature renders the SPIN's accuracy unaffected by distortions in its input and output signals caused by multipath interference and also permits the reduction of co-site interference. An embodiment which is exemplified hereinbelow is that of temperature threshold sensing. Also demonstrated herein is that by coupling SPIN's two POs with a PoI-sensitive sensor element (e.g., a microelectromechanical resonant sensor such as a piezoelectric microacoustic LiNbO₃ resonator as shown herein), the PoI threshold of the SPIN can be wirelessly reprogrammed. As such, the present technology, advantageously and for the first time, provides wireless sensing by presenting the core unit of a novel passive computing system that can facilitate decision-making well beyond what is possible with existing passive technologies.

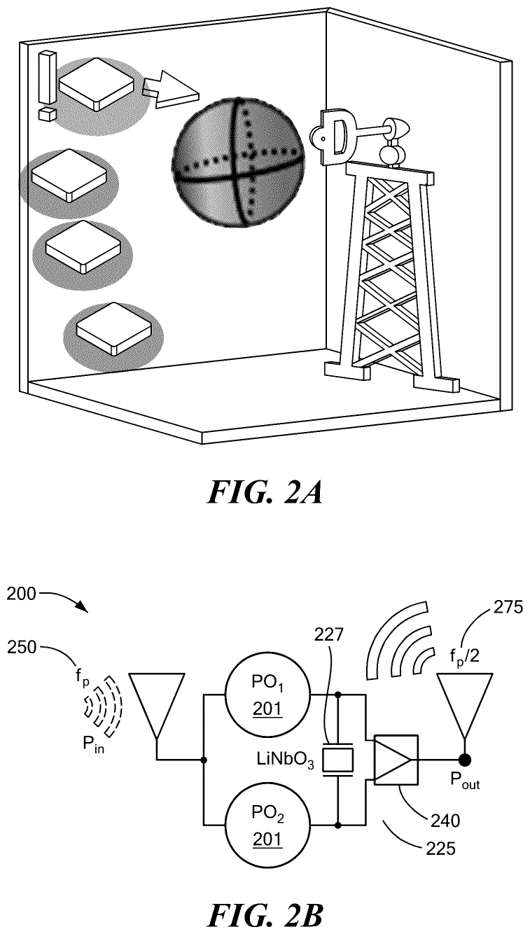

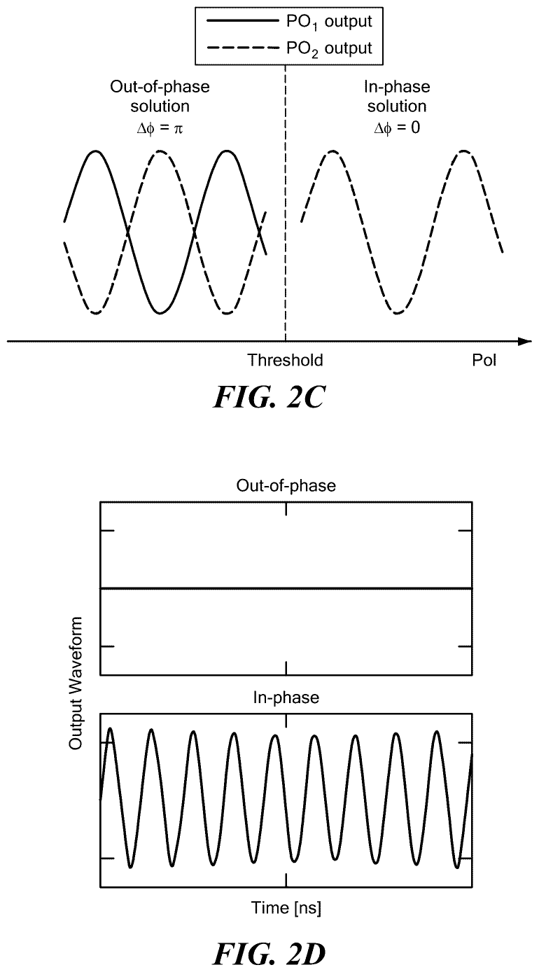

Referring now to FIG. 2B, in some embodiments, the Ising tag 200 relies on two POs 201 (PO₁ and PO₂) coupled to a dispersive impedance element 225 that, as shown, includes a resonant microelectromechanical system (MEMS) enabled sensor 227 responsive to a targeted PoI. As explained hereinbelow, such Ising tags 200 can autonomously implement threshold sensing. In particular, when driven by a continuous-wave interrogation signal, received at an input antenna 250 of the Ising tag 200 with frequency fₚ and power Pᵢₙ, the Ising tag's 200 POs 201 enter a collective oscillation state [35]. In this state, as shown in FIGS. 2C and 2D, the POs 201 generate equal-magnitude subharmonic signals with frequency fₚ/2 and phase-difference (Δφ) equal to 0 or π depending on the value of the sensed PoI [31], [32]. By summing the POs' 201 output signals with a power combiner 240, the output signal, whose power Pₒᵤₜ is radiated by the Ising tag's 200 output antenna 275, can either be negligible (for Δφ=π) or strong (for Δφ=0) due to respective destructive interference or constructive interference between the POs' 201 output signals.

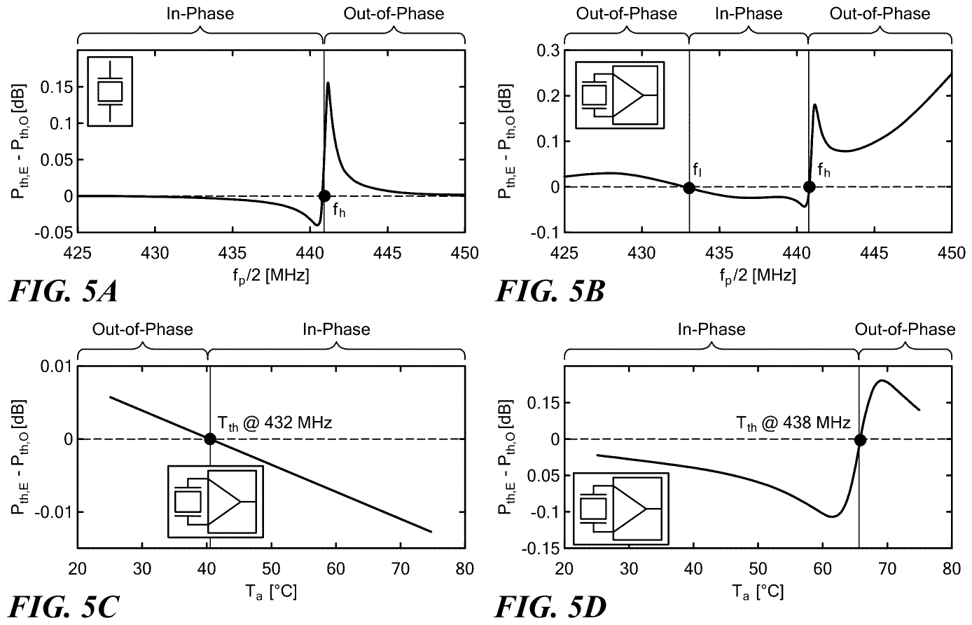

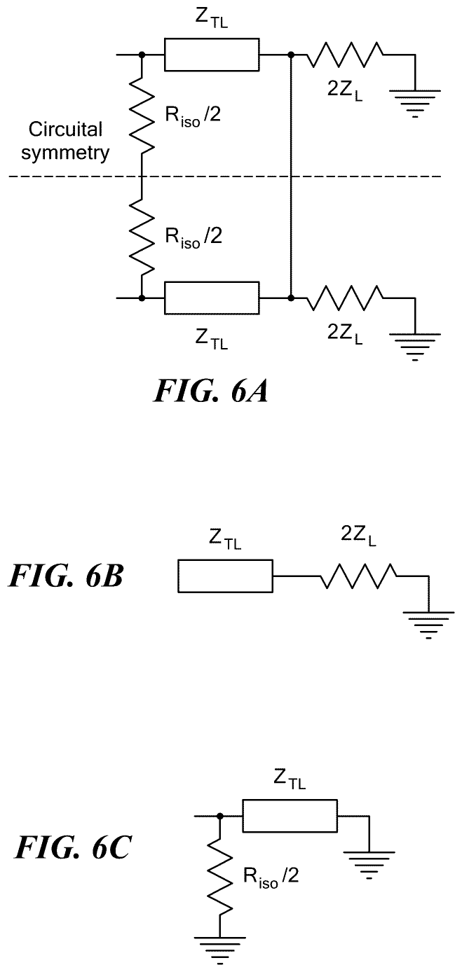

Changes in Δφ from π to 0 or vice versa occur when the targeted PoI surpasses or becomes lower than a certain threshold value. This provides the means to generate a trigger signal when a threshold violation in the PoI occurs. Because the occurrence of a PoI violation is encoded into the generation and radiation of a strong subharmonic signal and not into specific amplitude or phase values of the Ising tag's output signal, the reader accuracy is not affected by multipath interference distorting the Ising tag's output signal. In addition, as shown, for example, in FIG. 2A, the Ising tag's readers also experience minimal impact from co-site interference generated by other Ising tags placed nearby because the output signal of any Ising tag remains negligible when no violation is detected. Another advantage of the present technology, as described in further detail below with reference, for example, to FIGS. 5B-5D and 6C, is that the Ising tags can be wirelessly programmed to exhibit different sensing thresholds by varying the input (pump) frequency fₚ.

Yet another advantage is that the generation of the Ising tag's strong output signal stems from the synchronization of its two POs and not from the triggering of a bifurcation, thus making Δφ independent of Pᵢₙ [32], [36]. This represents a significant advancement compared to previous nonlinear passive tags, as it makes the detection of PoI violations immune to fluctuations in Pᵢₙ, despite the Ising tag's inherent nonlinear behavior. In turn, Pᵢₙ must remain larger than the minimum threshold power required (Pₜₕ) to start the POs' subharmonic oscillations, independent of the surrounding conditions.

### Comparison to Existing Passive Threshold Sensors

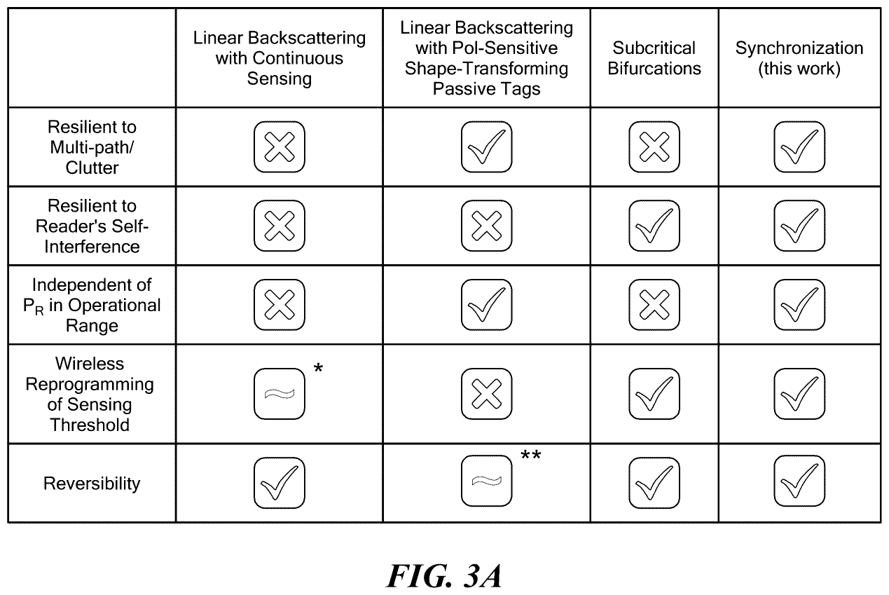

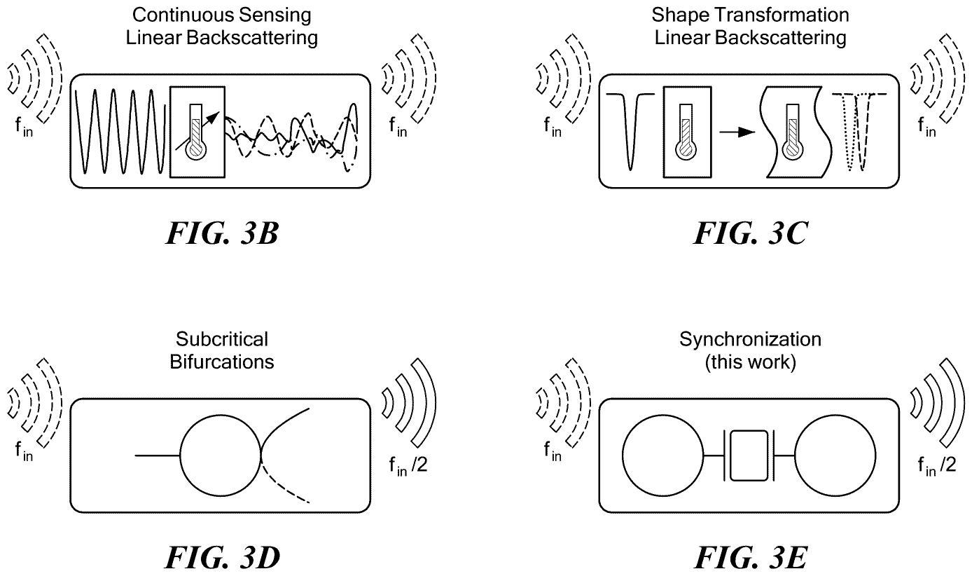

Nearly all the available passive tags behave as linear scatterers implementing continuous sensing functionalities. They do so by translating real-time changes in the strength of a sensed PoI into variations of their backscattered signal's magnitude or phase. This sensing approach faces challenges in achieving sufficient accuracy when targeting threshold sensing. A significant challenge is primarily due to distortion caused by multipath and clutter [45], [46], [47], [48]. To this end, linear passive tags incorporating nonlinear functional materials that undergo irreversible changes when a sensed parameter exceeds a certain value have been explored to implement threshold sensing [49], [50], [51]. Such changes permanently modify the amplitude and the phase of these tags' backscattered signal when a threshold event occurs, ensuring a detection more resilient to distortion caused by multipath and clutter. Unfortunately, most of these tags suffer from single use lifespans [49], [50], and their sensing threshold is fixed and set by design. As a result, multiple tags are needed to detect violations at different thresholds [52], [53], [54], which prevents their practical use in applications wherein a variety of heterogeneous items must be monitored. Only recently, passive tags exploiting subcritical bifurcations have been explored for temperature threshold sensing [55], [56]. In these tags, PoI violations activate an internal oscillation through a subcritical bifurcation, effectively triggering an alarm operating in the RF spectrum. Differently from their linear counterparts, these nonlinear tags can naturally exhibit different thresholds depending on the interrogation frequency. However, their reliance on subcritical bifurcations for implementing threshold sensing inevitably results in high sensitivity to random fluctuations in their input power, making them not usable reliably in uncontrolled electromagnetic environments. SPINs' modality for threshold sensing is different from any other one reported to date. SPINs utilize the synchronization of two POs coupled with a PoI-sensitive resonant sensor to implement threshold sensing. In this regard, SPINs encode their sensed information into the presence (or absence) of a backscattered signal which, owing to its origin as a function of the preferred synchronization state of two coupled POs, exhibits additional robustness to fluctuations of Pᵢₙ. Nonetheless, SPINs' input power must still be higher than Pₜₕ for SPINs to be able to functiona feature that sets SPINs' maximum interrogation range. It is important to note that SPINs' readers are prone to inaccurate readings because of co-site interference at fₚ/2 like the readers of any other passive tag developed to date. However, SPINs' ability to transmit their threshold sensing information at half of their interrogation frequency provides SPINs' readers with immunity from multipath, clutter and their own self-interference-a feature that the other available passive tags are unable to harness. A comparison graphic is shown in FIG. 3A that depicts the relative strengths and weaknesses of the different passive wireless threshold sensors available today, including SPINs. FIG. 3B-3E provide graphical representations of the operational characteristics of each discussed class of passive threshold sensing tag.

### Design and Modelling of SPINS

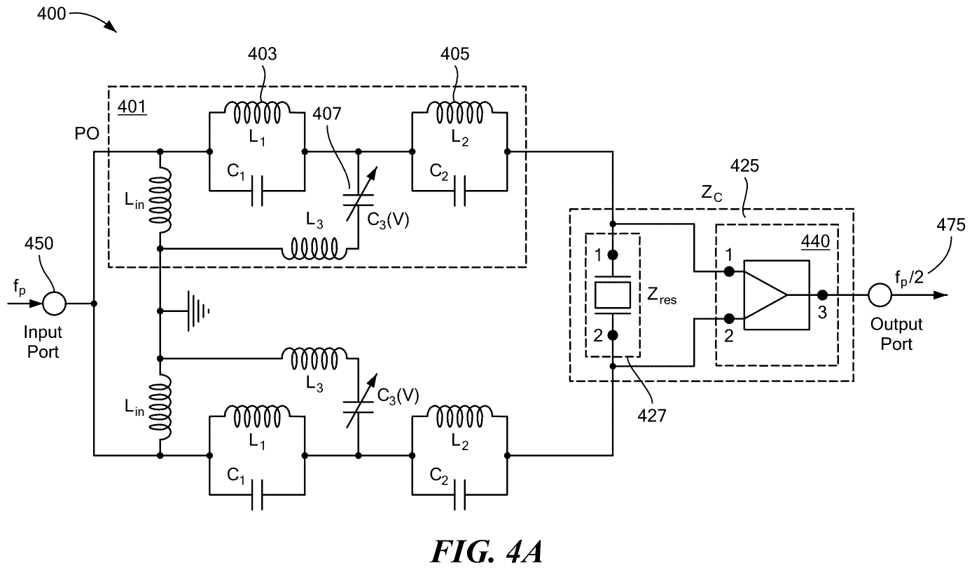

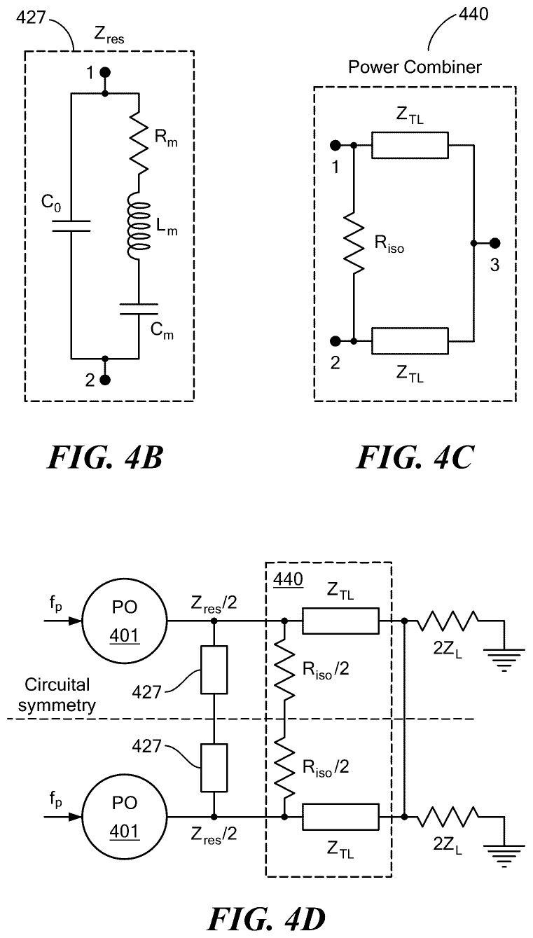

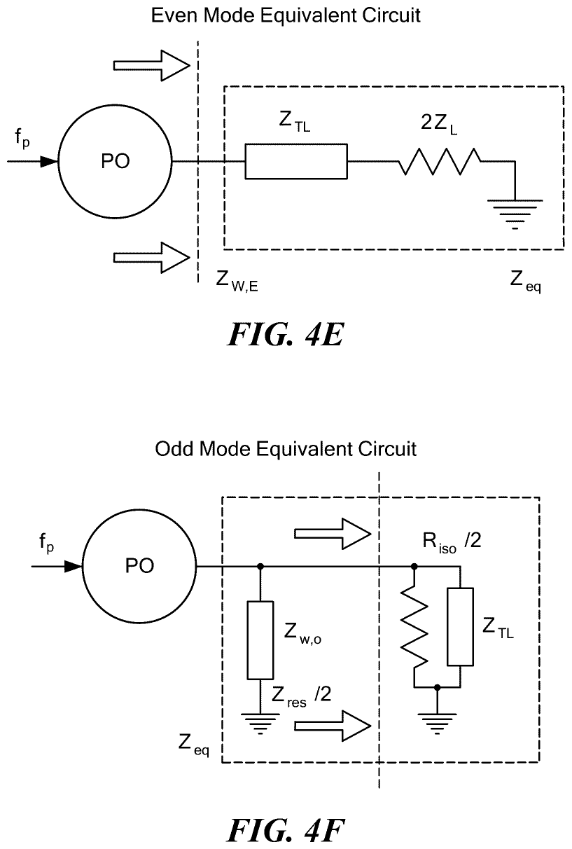

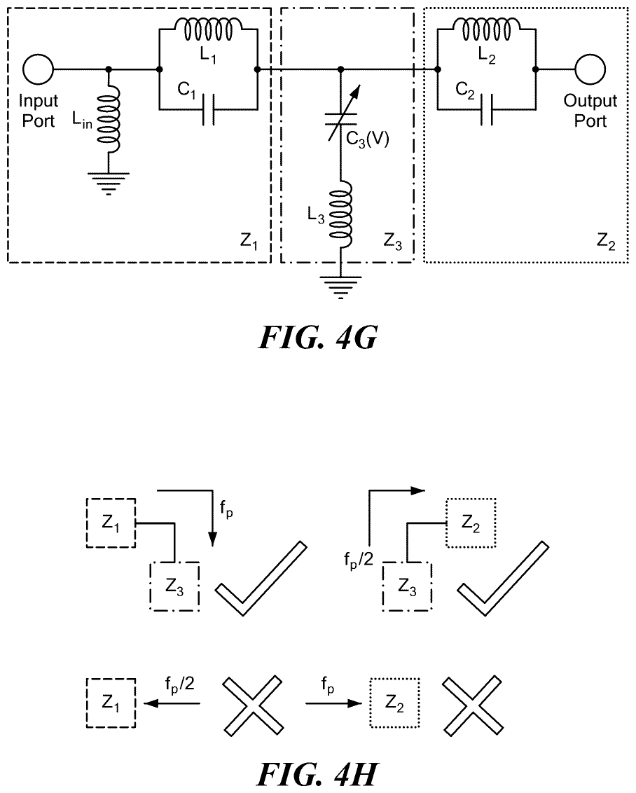

The design, principle of operation, and experimental characterization of an Ising tag prototype specifically tailored for temperature threshold sensing are described below with reference, for example, at least to FIGS. 4A-4F, 5A-5D, 17A-17B, and 18A-18E. This prototype relies on a microfabricated lithium niobate (LiNbO₃) MEMS resonant device serving as a temperature sensor, in conjunction with two POs constructed from off-the-shelf lumped components. However, it will be apparent in view of this disclosure that any number of PoI sensitive devices, resonators, off-the-shelf, and/or custom components can be used in various combinations to provide threshold sensing and/or multidimensional threshold sensing Ising tags having desired characteristics and/or their constituent components such as POs, sensor elements, resonators, antennas, transceivers, ports, etc. in accordance with various embodiments.

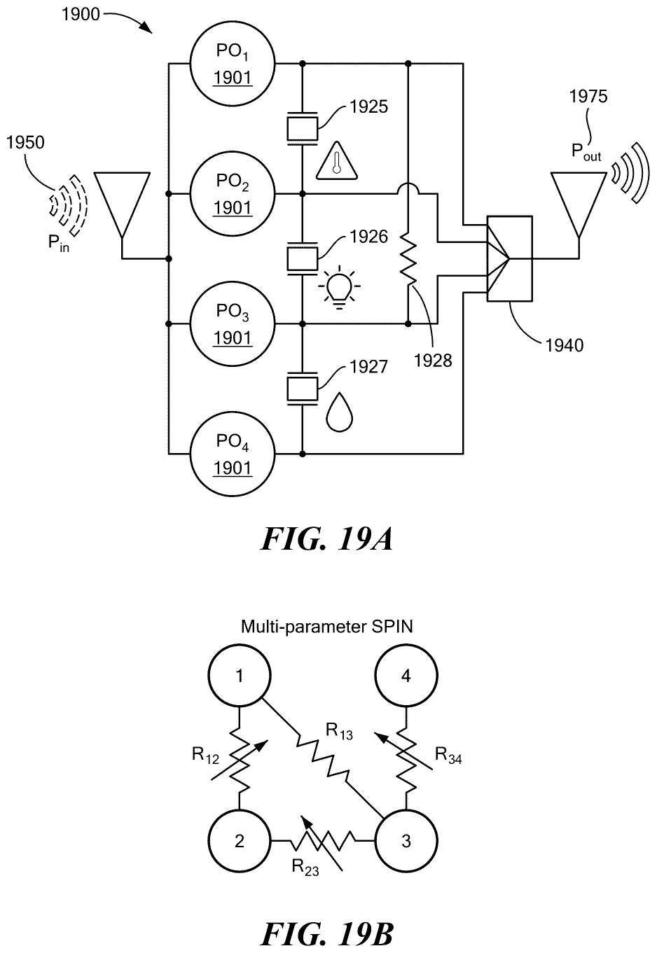

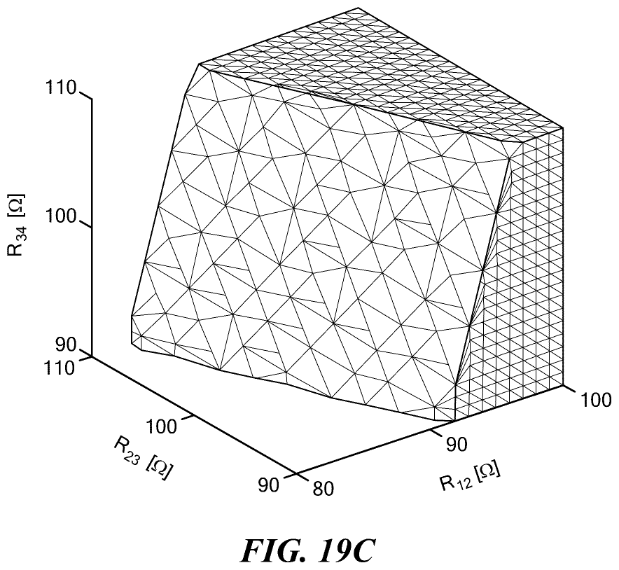

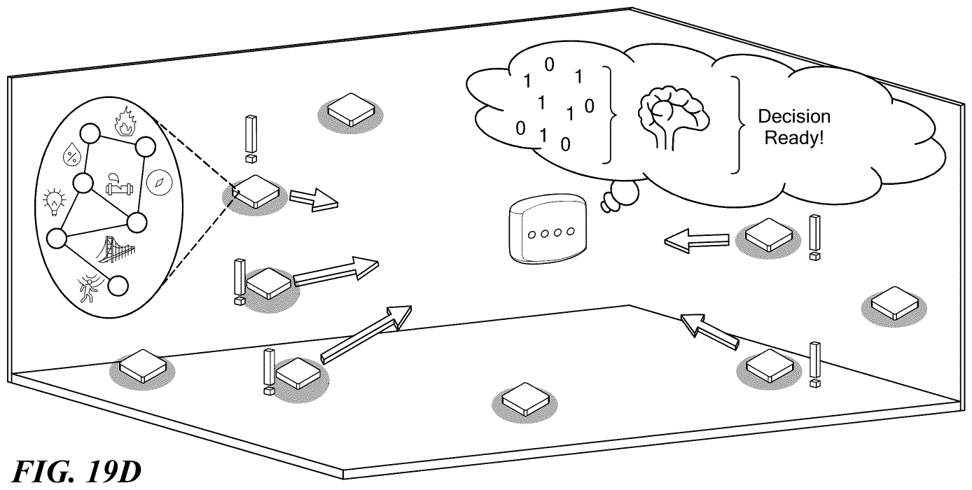

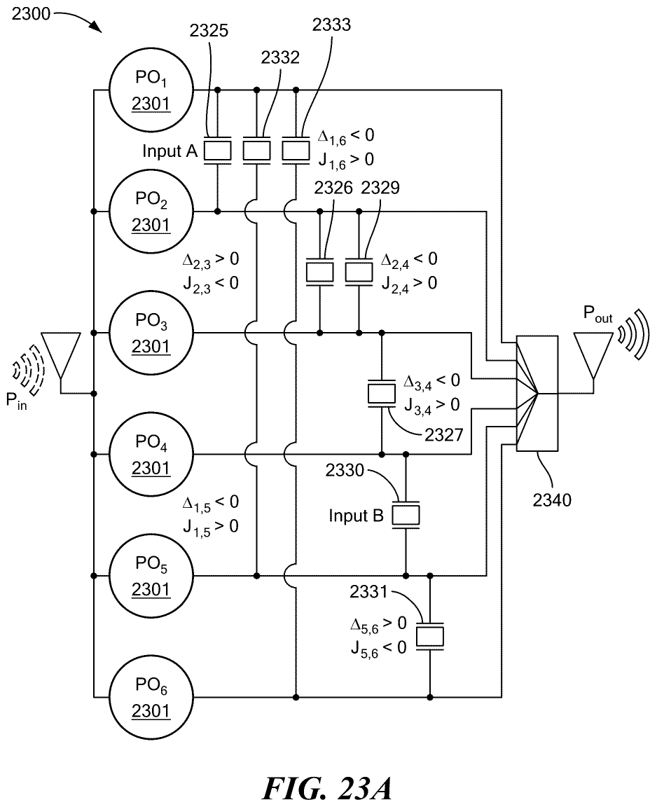

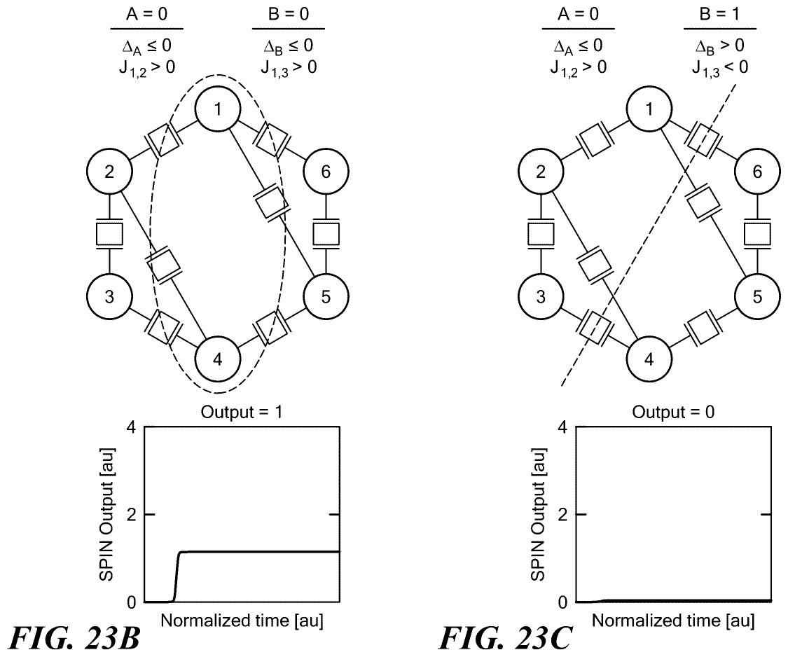

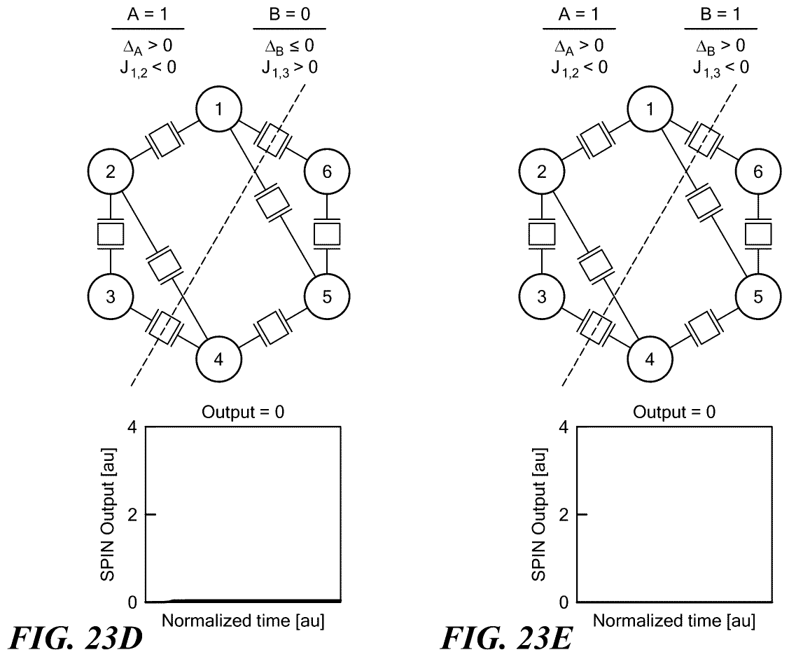

Referring now to FIGS. 4A-4F, an Ising tag 400 exploits the synchronization dynamics of two POs 401 coupled by a coupling element 425 providing a dispersive electrical load (e.g., the combination of a piezoelectric microacoustic resonant sensor 427 and a power combiner 440) to generate strong or weak output signals depending on the value of a sensed PoI. In general, the smallest or most basic hardware realization of the Ising model comprises a system of two coupled POs. However, it will be apparent in view of this disclosure that such hardware realizations can be extended to systems having any number of coupled POs including, for example, three (3) POs, four (4) POs (e.g., as shown in FIG. 19A), six (6) POs (e.g., as shown in FIGS. 23A-E, 24A-E, and 26A), as well as larger systems including tens of POs, hundreds of POs, thousands of POs, or more.

Referring now to FIGS. 4A-4C, each PO 401 in the exemplified Ising tag 400 includes a passive circuit formed by two resonant meshes (input mesh 403, output mesh 405) (e.g., LC tanks as shown). Each PO 401 also includes a nonlinear component 407 (e.g., a varactor as shown) responsible for parametric gain. Selection of the lumped electrical components in the POs 401 should be tailored to satisfy four resonant conditions [37]. Specifically, the selected components forming the input mesh 403, the output mesh 405, and the nonlinear component 407 need to simultaneously series resonate (or parallel resonate) the input and output meshes 403, 405 of each PO 401 at fₚ (or fₚ/2) and fₚ/2 (or fₚ), respectively. This allows maximization of both the voltage at fₚ produced by the interrogation signal across each PO's 401 varactor 407 and the parametric gain, which is important to minimize Pₜₕ.

The process delineated in [57] was followed to design the POs, aiming primarily at minimizing Pₜₕ and confine the input signal and the output signal in two separate meshes as shown in FIG. 4G. Addressing these goals requires a proper synthesis of the branch impedances (Z₁, Z₂, and Z₃) forming each PO in SPINs' circuit (see FIG. 4H). Z₁, Z₂, and Z₃ were synthesized to satisfy four resonant conditions [57] (see FIG. 4H):
1. The mesh including the series of Z₁ and Z₃ should series resonate at fₚ.
2. Z₂ should act as a notch filter for fₚ.
3. The mesh including the series of Z₂ and Z₃ should series resonate at fₚ/2.
4. Z₁ should act as a notch filter for fₚ/2.

The satisfaction of these four resonant conditions permits to maximize the voltage modulation at fₚ across the varactor hosted in Z₃ while ensuring that the PO's generated subharmonic output signals are directed towards its output port (i.e., one of the power-combiner's input ports). Each PO's optimum circuit components can be found for any desired fₚ value by using Harmonic Balance (HB) [58] and a simulation technique known as the “power auxiliary generator (pAG) technique” [59], as demonstrated in [57], [60], [61]. The pAG technique is also useful to identify Pₜₕ, whose analytical expression is available in [57] for the generalized single-varactor T-network architecture used by PO₁ and PO₂. The analytical expression of Pₜₕ available in was used to compute the P_{th, E} and P_{th, O} trends reported in the main manuscript. The optimization process for the design of SPINs' POs was conducted in conjunction with electromagnetic simulations capturing the behavior of SPINs' printed circuit board (PCB). This allowed us to account for any parasitic reactance arising from PCB traces and connectors. An fₚ value equal to 876 MHz was targeted during the design of the reported SPIN's POs, which is about twice the resonant frequency of the LiNbO₃ resonant sensor. The selected components and component values are listed in Table 1.

TABLE 1
Components list of the fabricated SPIN:

| | | |
|---|---|---|
| Component | Nominal Value | Model Number |

| | | | |
|---|---|---|---|
| L₁ | 8.2 | nH | 0402HP-8N2 |
| L₂ | 47 | nH | 0402HP-47N |
| L₃ | 16 | nH | 0402HP-16N |
| Lᵢₙ | 2 | nH | 0402HP-2N0 |
| C₁ | 5.3 | pF | GRM1555C1H5R3WA01 |
| C₂ | 2.0 | pF | GRM1555C1E2R0CA01 |
| C₃ | 1.2 | pF | SMV1430 |

### Analysis of PO Systems Via Coupled Mode Theory

### Phase Bistability of a Single PO

The POs 401 exhibit inherent bistability when operating in their period-doubling regime [30], [31], [36]. As a result, they express two possible solutions for input power levels higher than Pₜₕ: one stable and one unstable. These solutions are phase-shifted by π with respect to each other and, in the absence of noise, can be reached equiprobably. [32]

The following analysis investigates these highly nonlinear systems. The model of a single PO includes of two modes mediated by the second-order parametric process, analogous to the χ⁽²⁾ processes in nonlinear optics, and it can be effectively described by a single mode [62]:

$$\dot{a} = - [ \frac{{κ}_{a}}{2} + i {Δ}_{a} + {r}_{1} {\vert a \vert}^{2} ] a - i {r}_{2} {a}^{*} \qquad ( S \text{.1} )$$

In this regard, a represents the amplitude of the resonant mode in a single PO with a loss rate described by κₐ and a detuning

$${Δ}_{a} = 2 π ( {f}_{a} - \frac{{f}_{p}}{2} ) .$$

In this analysis, fₐ represents the optimal frequency of operation for the resonant mode, equivalent to the value of fₚ/2 minimizing the Pₜₕ of the SPINs' POs. r₁ and r₂ map to the gain saturation coefficient and the small-signal gain parameter, respectively. A rotational frame of

$$a \to {a}^{- i \frac{π}{4}}$$

can then be applied to rewrite Eq. (S.1) as the following:

$$\dot{a} = - [ \frac{{κ}_{a}}{2} + i {Δ}_{a} + {r}_{1} {\vert a \vert}^{2} ] a + {r}_{2} {a}^{*} \qquad ( S . 2 )$$

Then, a=Ae^{-iθ} can be set and Eq. (S.2) expressed when constraining θ to 0 or π (to enforce the criteria required for phase bistability [60]) as the following:

$$0 = - [ \frac{{κ}_{a}}{2} + i {Δ}_{a} + {r}_{1} {A}^{2} - {r}_{2} ] A \qquad ( S . 3 )$$

The solution of Eq. (S.3) is obtained as

$${A}_{th} = \sqrt{\frac{{r}_{2} - \frac{κ}{2} - i {Δ}_{a}}{{r}_{1}}} ,$$

which is indeed the threshold for phase bistability, when

$${r}_{2} \geq \frac{{κ}_{a}}{2} + i {Δ}_{a} .$$

Such solution indicates that phase bistability is achieved when driving the PO with a sufficiently large r₂ due to the emergence of a period-doubling regime through a nonlinear bifurcation [63], [64], [65].

When two POs are coupled by an impedance Z_{C} as shown in FIG. 4A, they converge to a state where their output signals are either in-phase (the “ferromagnetic coupling state”) or out-of-phase (the “anti-ferromagnetic coupling state”) depending on Z_{C}, emulating two spins of an Ising system with different coupling weights [28], [33]. For the experimental Ising tag 400, Z_{C} 425 is a combination of the dispersive impedances of the resonant sensor 427 and the power combiner 440, as also shown in FIG. 4A. A Wilkinson power combiner 440 terminated to a load impedance (Z_{L}) of 50Ω is considered here, as in the experiments [38] described herein.

To understand what drives the convergence of the POs 401 toward a ferromagnetic or anti-ferromagnetic coupling state, it is useful to employ an “even and odd mode” circuit analysis [39] to analyze the stability of the non-dividing solution (the “trivial” solution) for two POs 401 coupled by Z_{C} 425. This technique, as shown in FIGS. 4D-4F, allows decomposition of the Ising tag's 400 circuit into two separate circuits, namely the “even” FIG. 4E and “odd” FIG. 4F equivalent circuits, by leveraging circuit symmetry. Both the even and the odd circuits are effectively formed by only one PO 401 loaded with a generally complex equivalent impedance Z_{eq}. In FIGS. 4E-4F, Z_{eq} is different for the two circuit modes. In the even mode of FIG. 4E, Z_{eq} does not depend on the resonant sensor but only on the input impedance (Z_{W,E}) of the even mode decomposition of the power combiner 440 [38]. In the odd mode of FIG. 4F, the value of Z_{eq} for the odd mode depends on both the resonant sensor's 427 impedance (Zᵣₑₛ) and the input impedance (Z_{W,O}) of the odd mode decomposition of the power combiner 440 as explained in more detail below [38].

It is important to note a fundamental distinction in the interpretation of even and odd mode equivalent circuits of a network of two POs 401 compared to their typical interpretation in linear circuits. While in linear and symmetric circuits any voltage, current, or power can be determined by superimposing the voltages, currents, and powers obtained from the even and odd mode equivalent circuits individually, this is not true for a network of two coupled POs 401 [38], [39]. In such a nonlinear network, only one equivalent circuit accurately depicts the network's behavior when the input power received at input port 450 exceeds the threshold (i.e., when Pᵢₙ≥Pₜₕ) because the POs' output signals, transmitted from output port 475, are constrained to be either in-phase or out-of-phase. Specifically, the even circuit captures the network's behavior when the two POs are in a ferromagnetic coupling state (when the two POs' output signals are in-phase, meaning that the Ising interaction term is positive [40]) whereas the odd circuit captures the network's behavior when the two POs are in an anti-ferromagnetic coupling state (when the two POs' output signals are out-of-phase and the Ising interaction is therefore negative [40]). The even and odd modes of a network of two POs then compete against each other to determine the final state.

To understand which PO's coupling state wins this competition, it is necessary to identify which coupling state is activated first when the POs' driving power is increased from zero to any value above Pₜₕ [29], [33]. In this regard, the power threshold of any varactor-based electrical PO is directly related to the impedance seen by its varactor [37] at both fₚ and fₚ/2. Consequently, the even and odd circuits shown in FIGS. 4E-4F exhibit different Pₜₕ values, “P_{th,E}” and “P_{th,O}”, respectively. Hence, the preferred coupling state for Pᵢₙ≥Pₜₕ can be determined by identifying which equivalent circuit between the even and odd mode circuits exhibits the lowest Pₜₕ, which depends on Z_{eq} (see FIGS. 4E-4F) [29], [33].

### Even and Odd Mode Behavior

### Modelling of the Power Combiner

The ideal Wilkinson power combiner includes two quarter-wave transmission lines with a characteristic impedance Z_{TL} equal to Z_{L}\sqrt{2}, where Z_{L} represents the termination impedance equal to 50Ω. These transmission lines are connected using a shunt isolation resistor, Rᵢₛₒ, equal to 2Z_{L} (FIG. 6A) [66], [67]. Both the even and odd mode equivalent circuits of the ideal Wilkinson power combiner exhibit an equivalent resistance equal to Z_{L} at the optimal design frequency [66], [67]. In FIG. 6B, the quarter-wave transmission line transforms the 2Z_{L} termination impedance to only Z_{L} while in FIG. 6C, the short circuit termination is transformed into an open circuit, making the equivalent termination resistance equal to Rᵢₛₒ/2, or Z_{L}. Therefore, an ideal Wilkinson power combiner operating at its targeted frequency does not impact SPINs' mode competition [57], [67]. However, when operating at frequencies detuned from the nominal one, the transmission lines stop having an electrical length equal to a quarter wavelength. Consequently, Wilkinson power combiners typically exhibit dispersive properties innate to their physical realizations.

### SPIN Dynamics Excluding the Power Combiner

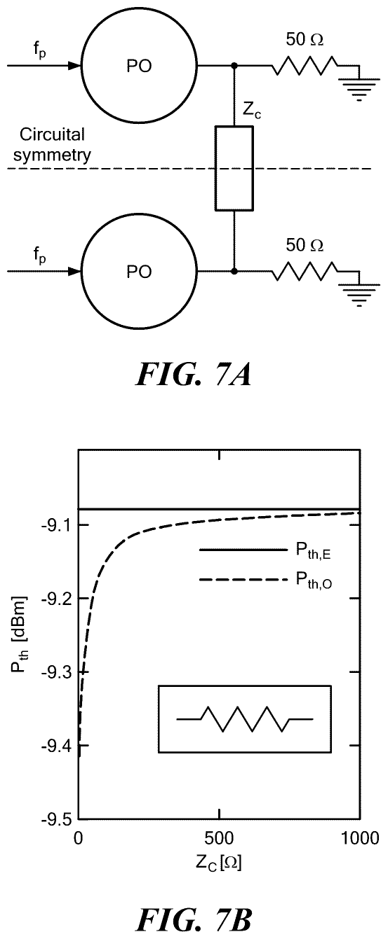

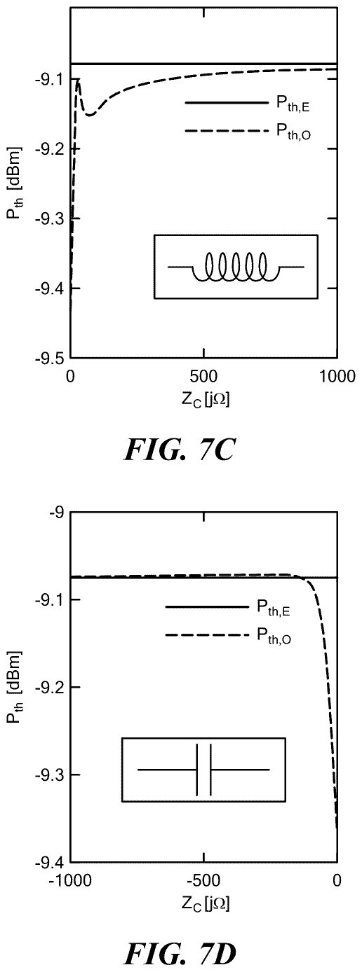

To better understand the dynamics of the assembled SPIN prototype without the power combiner, it is informative to look at the different behaviors that two electrical POs, terminated to separate 50Ω loads, exhibit (see FIG. 7A) when coupled by different types of impedance while being driven at the specific frequency that minimizes Pₜₕ. the coupling impedance between the two electrical POs can still be referred to as Z_{C}, as with SPINs' coupling impedance. In this case study, P_{th,E} is independent of Z_{C}. This is because the voltage difference across Z_{C} must be zero when the POs are in a ferromagnetic coupling state (i.e., the two POs' output signals have the same magnitude and the same phase). P_{th,O}, on the other hand, can vary substantially, reaching the lowest value when Z_{C} behaves as a short circuit at fₚ/2. Yet, P_{th,O} can also be higher than P_{th,E} when the reactance of Z_{C} significantly detunes both POs' output meshes. The effect of this detuning on P_{th,O} is analogous to changing the resonance frequency of a Mathieu resonator without changing its pump frequency [60], [68].

The numerical trends of P_{th,E} and P_{th,O} for a system of two POs formed by the same lumped components used in the demonstrated SPIN prototype were also studied. Initially, the two POs were terminated to separate 50Ω loads and operating at a fixed fₚ value (876 MHz, corresponding to fₚ/2=438 MHz (see FIG. 7A). These trends were extracted when considering that the POs were coupled using: i) a resistor with resistance changing between 2Ω and 2 kΩ (see FIG. 7B), ii) an inductor with reactance changing from 2Ω to 2 kΩ (see FIG. 7C), iii) a capacitor with reactance changing from −2 kΩ to −2Ω (see FIG. 7D). As shown in FIGS. 7B-C, when coupling the POs with either a resistor or an inductor, P_{th,O} yields a smaller value than P_{th,E} for all the investigated cases. This indicates that the anti-ferromagnetic coupling state is always preferred. On the other hand, when sweeping the reactance of a purely capacitive Z_{C} value, a transition in the preferred coupling state can occur. Specifically, for large capacitance values (i.e., for low reactance values) P_{th,O} is lower than P_{th, E}, making the antiferromagnetic coupling state preferred. However, a change in the preferred coupling state occurs for low capacitance values (i.e., for large reactance values). In this scenario, the detuning of the POs originating from the capacitive coupler causes an increase of P_{th,O} that ultimately makes the ferromagnetic coupling state the one that is preferred.

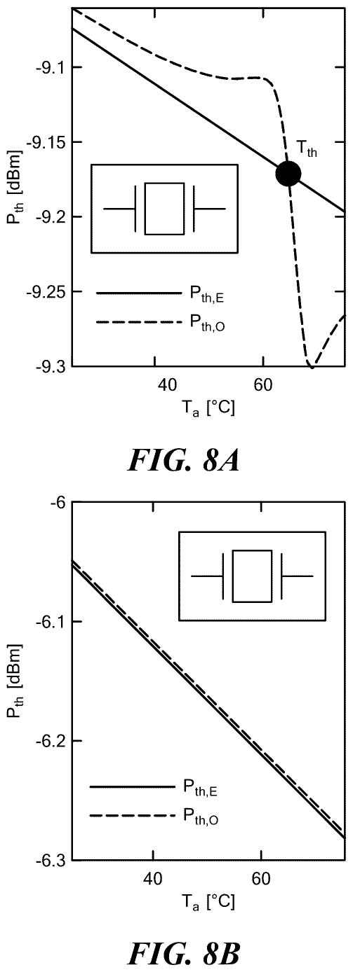

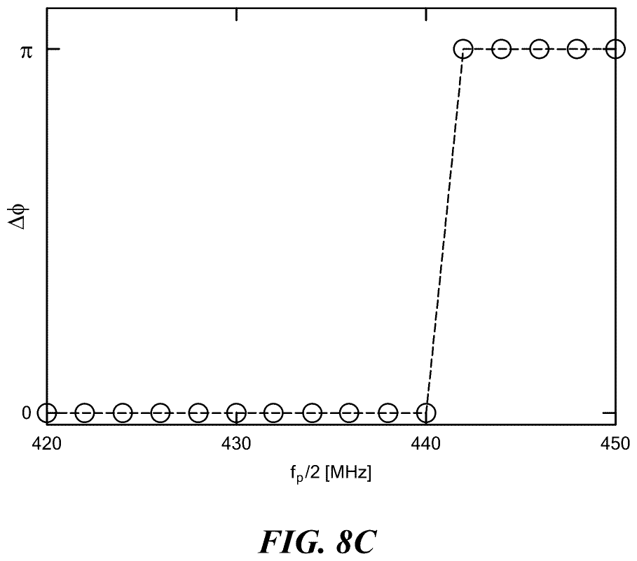

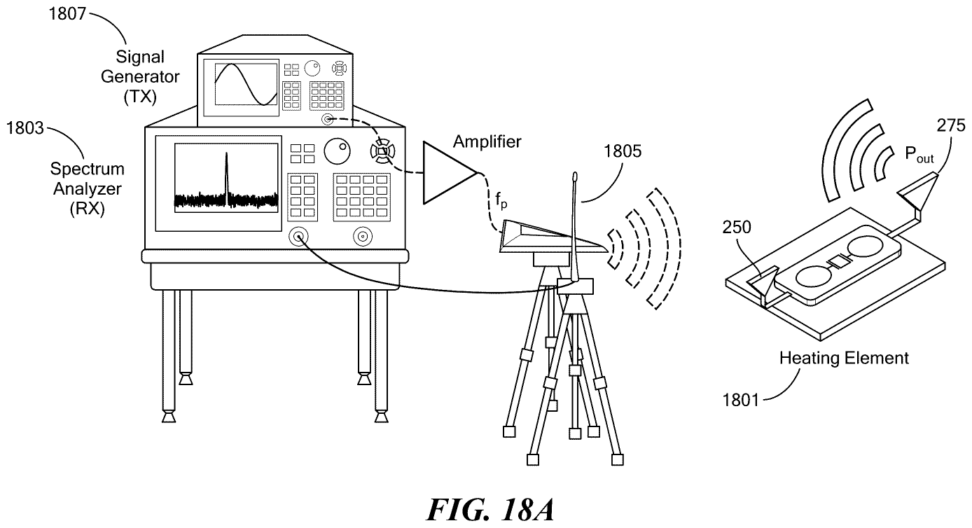

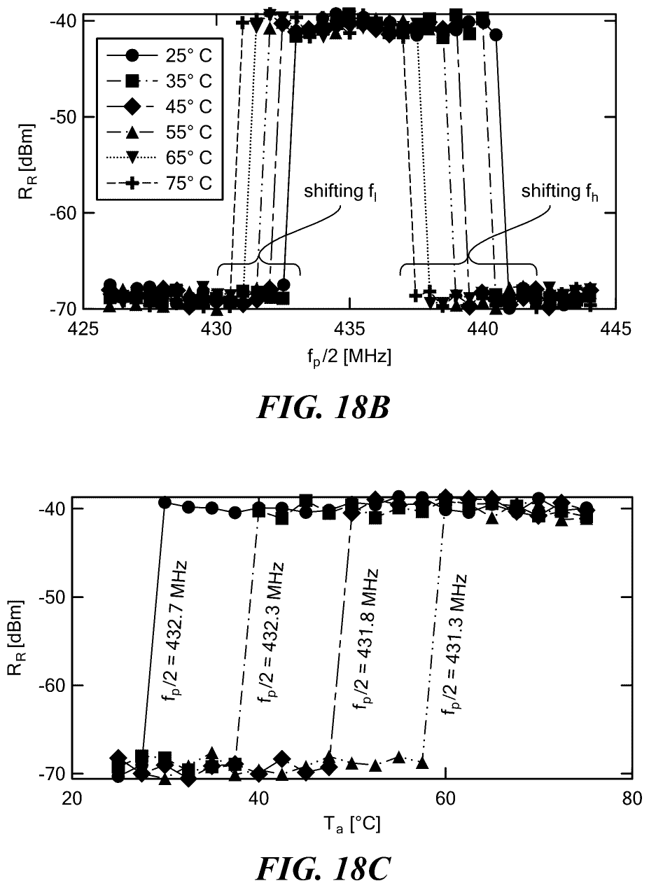

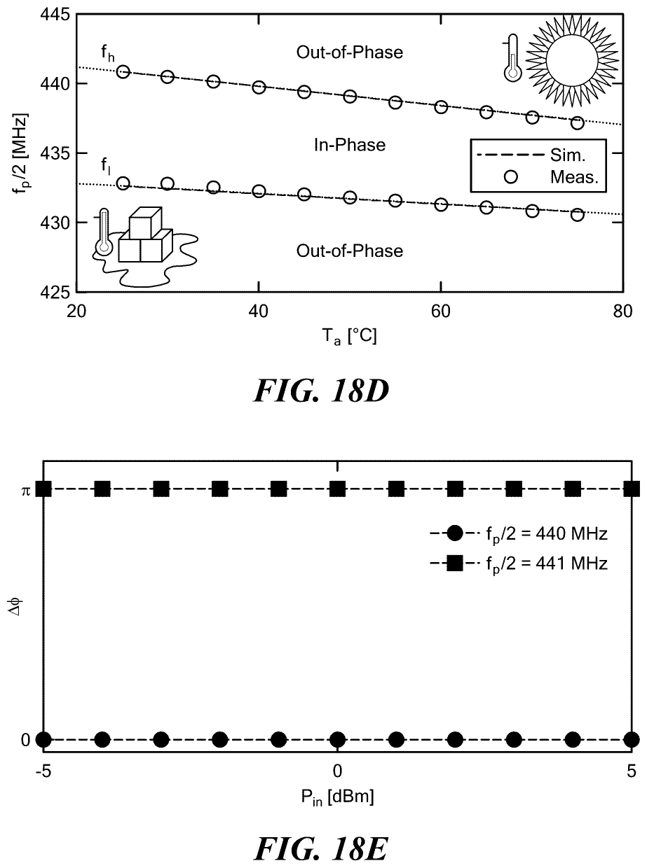

Then, the case study conducted in FIG. 18C-D, described below, was repeated. However, this time each PO terminated to a 50Ω load rather than to an input port of the power combiner, similar to FIG. 7A. As seen in FIG. 8A-B, it was found that removing the power combiner did not significantly change fₕ with respect to FIG. 4F; however, the second transition at fₗ was not found. To validate this, the output waveforms of each PO in the assembled SPIN prototype were experimentally measured using an oscilloscope with 50Ω terminations, as done in FIG. 18E. During this experiment, Tₐ was considered fixed to room temperature and a wired connection to a signal generator was used to pump the POs with Pᵢₙ=0 dBm for fₚ/2 ranging from 420 MHz to 450 MHz. Δφ was then calculated from the measured waveforms of the POs for each explored fₚ/2 value and found, indeed, that fₗ does not exist without the power combiner (see FIG. 8C).

### Further Analysis of PO Systems Via Coupled Mode Theory

### Even and Odd Mode Thresholds for Coupled POs

The first findings with respect to phase bistability were confirmed by using coupled mode theory. Particularly, the working principle of the mode competition occurring in such highly nonlinear systems was analytically investigated, demonstrating good agreement with results from the circuit model.

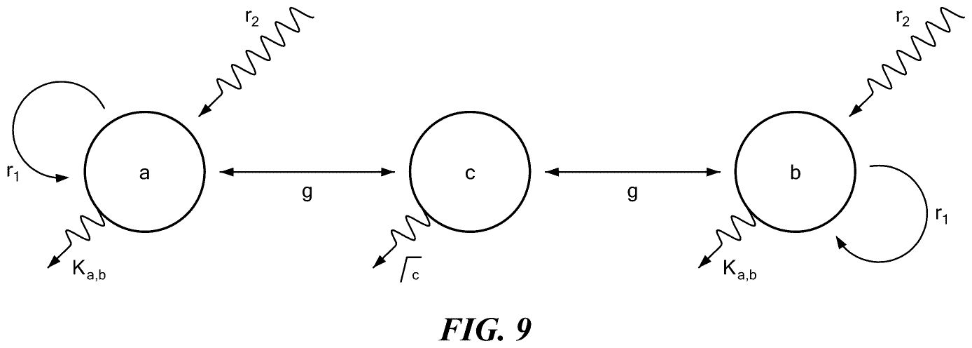

In the following, a model describing the behavior of the circuit introduced in the main text is presented. FIG. 9 illustrates the schematic of the system under investigation, including two parametric oscillators mediated by the χ⁽²⁾ nonlinearity and coupled with a mechanical resonant cavity. Given the effective Hamiltonian of the system, Hᵢₙₜ=ℏg(a*c+b*c+h·c), its equations of motion can be described by temporal coupled-mode theory via the Heisenberg picture:

$$\dot{a} = - [ \frac{{κ}_{a ,}}{2} + i {Δ}_{a , b} + {r}_{1} {\vert a \vert}^{2} ] a - i {r}_{2} {a}^{*} - igc , \qquad ( S . 4 )$$

$$\dot{b} = - [ \frac{{κ}_{a ,}}{2} + i {Δ}_{a , b} + {r}_{1} {\vert b \vert}^{2} ] b - i {r}_{2} {b}^{*} - igc , \qquad ( S . 5 )$$

$$\dot{c} = - [ \frac{{Γ}_{c}}{2} + i {Δ}_{c} ] c - ig ( a + b ) \qquad ( S . 6 )$$

Here, a and b represent the amplitudes of the intracavity fields of the two modes representing the POs in the SPIN circuit while κ_{ab} represents the total loss rates for both modes. In this analysis, these modes are treated as identical. Similarly, c represents the mechanical mode in the LiNbO₃ resonator and Γ_{c} maps its mechanical loss rate. The detuning term, Δ_{a,b} corresponds to the difference between the frequency of the modes (f_{a,b}) and the subharmonic frequency, given as fₚ/2 in the main text, and takes the form:

$${Δ}_{a , b} = 2 π ( {f}_{a , b} - \frac{{f}_{p}}{2} ) . {Δ}_{c}$$

maps to the detuning of fᵣₑₛ with respect to fₚ/2 and is given as

$$2 n ( {f}_{res} - \frac{{f}_{p}}{2} ) .$$

### Additionally,

$${r}_{1} \approx \frac{2 {\vert g \vert}^{2}}{κ}$$

is the gain saturation coefficient, r₂ is the small-signal gain parameter, and g≈4Γ_{c} is the nonlinear coupling rate, indicating that the modes are strongly coupled [62].

When considering the system to operate in its steady state, Eq. (S.4) and Eq. (S.5) can be rewritten as the following:

$$0 = - [ \frac{{κ}_{a , b}}{2} + i {Δ}_{a , b} + {r}_{1} {\vert a \vert}^{2} ] a - i {r}_{2} {a}^{*} - \frac{{g}^{2} b}{\frac{{Γ}_{c}}{2} + i {Δ}_{c}} \qquad ( S . 7 )$$

$$0 = - [ \frac{{κ}_{a , b}}{2} + i {Δ}_{a , b} + {r}_{1} {\vert b \vert}^{2} ] b - i {r}_{2} {b}^{*} - \frac{{g}^{2} a}{\frac{{Γ}_{c}}{2} + i {Δ}_{c}} \qquad ( S . 8 )$$

Now, by defining the effective coupling as

$$G = \frac{{g}^{2}}{\frac{{Γ}_{c}}{2} + i {Δ}_{c}} ,$$

the effective loss rate as

$$\overline{κ} = {κ}_{a , b} + \frac{{g}^{2} {Γ}_{c}}{{( \frac{{Γ}_{c}}{2} )}^{2} + {Δ}_{c}^{2}} ,$$

and the effective detuning as

$$\overline{Δ} = {Δ}_{a , b} + \frac{{g}^{2} {Δ}_{c}}{{( \frac{{Γ}_{c}}{2} )}^{2} + {Δ}_{c}^{2}} ,$$

Eq. (S.7) and Eq. (S.8) can be rewritten into the following form:

$$0 = - [ \frac{\overline{κ}}{2} + i \overline{Δ} + {r}_{1} {A}^{2} ] A + {r}_{2} A {e}^{i 2 {θ}_{a}} - GB {e}^{i Δ ϕ} , \qquad ( S . 9 )$$

$$0 = - [ \frac{\overline{κ}}{2} + i \overline{Δ} + {r}_{1} {B}^{2} ] B + {r}_{2} B {e}^{i 2 {θ}_{a}} - BA {e}^{- i Δ ϕ} , \qquad ( S . 10 )$$

where a=Ae^{iθ}^{ₐ} and b=Be^{iθ}^{_{b}}. In Eq. (S.9) and Eq. (S.10), it is useful to recall from the previous subsection that θₐ and θ_{b} are constrained to 0 or π, meaning that the relative phase difference Δφ=θₐ−θ_{b} is also constrained to these values. When enforcing these conditions and then subtracting Eq. (S.10) from Eq. (S.9), the system can be modeled with a single equation, and when setting equal mode amplitudes (A=B) it takes the form:

$$0 = - ( \frac{\overline{κ}}{2} + i \overline{Δ} ) - {r}_{1} ( 3 {A}^{2} ) + {r}_{2} ∓ G \qquad ( S . 11 )$$

From Eq. (S.11), there are two possible amplitude solutions (A_{th,E} and A_{th,O}), corresponding to whether Δφ equals 0 or π, respectively, as given below:

$${A}_{th , E} = \sqrt{\frac{{r}_{2} - \frac{{κ}_{a , b}}{2} - i {Δ}_{a , b} - 2 G}{3 {r}_{1}}} \qquad ( S . 12 )$$

$${A}_{th , O} = \sqrt{\frac{{r}_{2} - \frac{{κ}_{a , b}}{2} - i {Δ}_{a , b}}{3 {r}_{1}}} \qquad ( S . 13 )$$

Here, the nonzero solutions of Eq. (S.12) and Eq. (S.13) are obtained when the gain parameter is larger than its critical value, e.g.,

$${r}_{2 , E} \geq {r}_{2 , E}^{cr} = \frac{{κ}_{a , b}}{2} + i {Δ}_{a , b} + 2 G or {r}_{2 , O} \geq {r}_{2 , O}^{cr} = \frac{{κ}_{a , b}}{2} + i {Δ}_{a , b} .$$

In this case, r_{2,E} and r_{2,O} refer to the small-signal gain parameters corresponding to each solution while r_{2,E}^{cr} and r_{2,O}^{cr} denote the minimum value of r_{2,E} and r_{2,O} required to excite the in-phase or out-of-phase solutions, respectively. Clearly, r_{2,E}^{cr} and r_{2,O}^{cr} exhibit differing values based on the effective coupling G and the manifested solution (in-phase or out-of-phase) arises depending on which small-signal gain parameter requires the least amount of power to sustain. It is important to note that this analytical treatment most accurately models the region of fₚ/2 near f_{ab} and fᵣₑₛ, as the impact of the static capacitance (C₀) of the LiNbO₃ MEMS device is not embedded in the analysis.

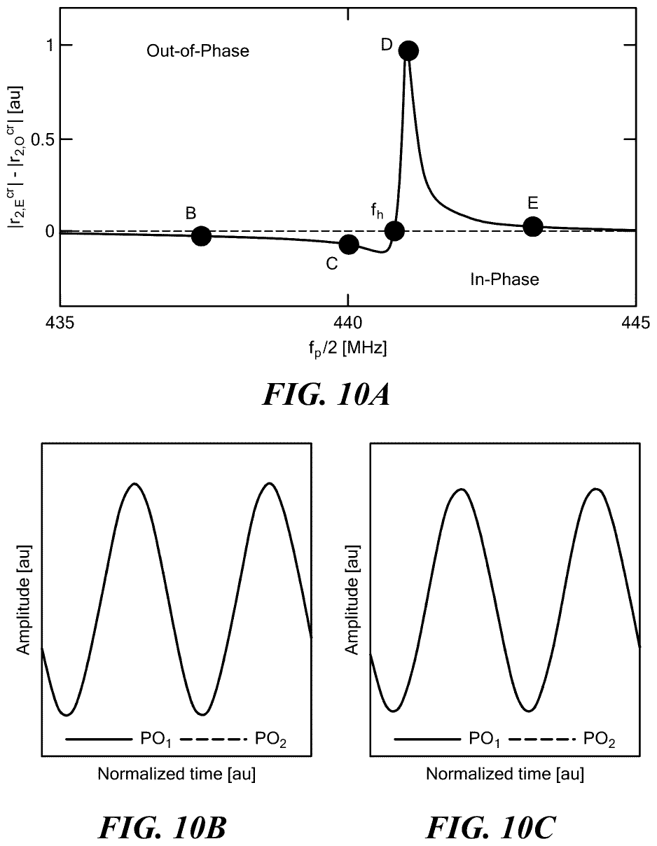

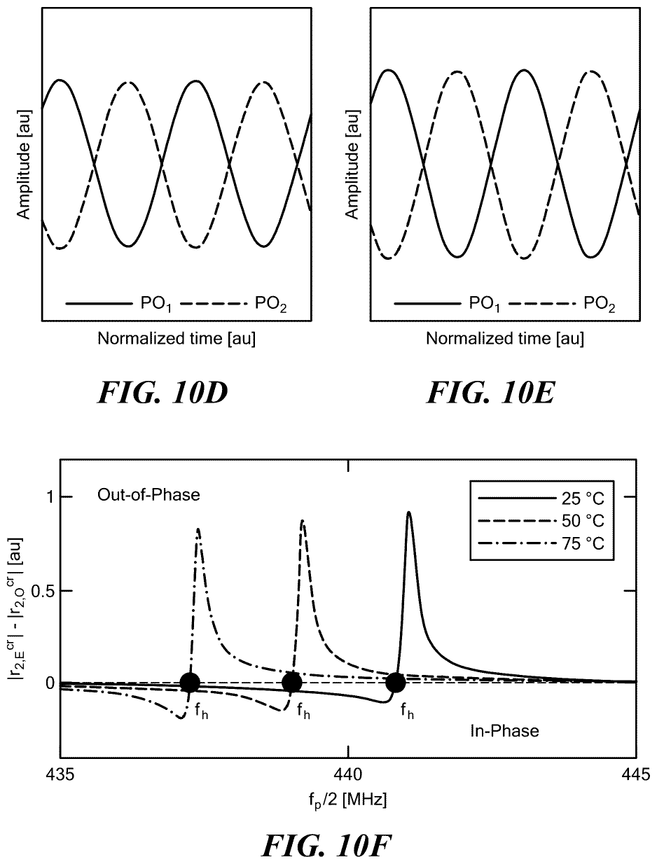

To characterize the mode competition, the difference between |r_{2,E}^{cr}| and |r_{2,O}^{cr}| across a range of fₚ/2 values is plotted in FIG. 10A. In the immediate region near fᵣₑₛ, the value of |r_{2,O}^{cr} is less than the value of |r_{2,E}^{cr}|, indicating a preference for an out-of-phase solution. In such a scenario, the coupling can be assumed as dissipative since Γ_{c}»Δ_{c}.

Nonetheless, a value of fₕ near fᵣₑₛ is observable where |r_{2,E}^{cr}| becomes less than |r_{2,0}^{cr} and the system prefers an in-phase solution. To validate this modelling, Eq. (S.4), Eq. (S.5), and Eq. (S.6) are numerically solved for fₚ/2 values above and below fₕ and the steady state oscillations of the a and b modes are plotted in FIG. 10B-E. For the selected fₚ/2 values below fₕ (437.5 MHz and 440 MHz, shown in FIG. 10B-C), the system preferred an in-phase solution while the opposite (an out-of-phase solution) was obtained when selecting fₚ/2 above fₕ (441 MHz and 442.5 MHz, shown in FIG. 10D-E). Even more, to validate the relationship between fₕ and Tₐ, the measured TCF of the fabricated LiNbO₃ MEMS resonator was embedded into the model of the mechanical mode and then plotted |r_{2,E}^{cr}|−|r_{2,O}^{cr}| with respect to fₚ/2 for various Tₐ values, equal to 25° C., 50° C., and 75° C. (see FIG. 10F). As can be observed, the temperature-driven changes in fᵣₑₛ cause sufficient shifts in Δ_{C} (and therefore G and |r_{2,E}^{cr}) to alter the respective position of fₕ, ultimately changing the system's preference between even and odd modes for certain values of fₚ/2. Note that the key element of the mode competition in this system is Δ_{c}, which embeds the difference between fᵣₑₛ and fₚ/2. Thus, as long as a resonant sensor has a sensitivity of its fᵣₑₛ to some PoI (not necessarily temperature), then this PoI can induce changes in the manifested synchronization regime and SPIN can be used to flag violations of the same PoI.

Referring now to FIGS. 4A-4D, the trends of P_{th,E} and P_{th,O} with respect to fₚ were modeled. In FIG. 5A, the POs were coupled with a piezoelectric resonator matching the one used in the Ising tag prototype 400 described herein but, as an initial baseline, no power combiner was used, and SPIN's POs were assumed to be terminated on separate 50Ω resistors. Additionally, it was assumed that the entire system is operating at room temperature (i.e., 25° C.). The piezoelectric resonator, a LiNbO₃ device like the one used in this work, was modelled through its equivalent temperature-dependent Butterworth Van-Dyke (BVD) model [41], which makes it possible to capture the resonator's mechanical behavior in the electrical domain. More information with respect to the various components forming the equivalent circuit of the modelled LiNbO3 resonator is provided below.

When Z_{C} is just comprised of the resonant sensor, the dispersion of Zᵣₑₛ makes SPIN's preferred coupling state dependent on fₚ. In this scenario, there exists one fₚ value, corresponding to a fₚ/2 value labeled as fₕ in FIG. 5A, marking the transition between ranges of fₚ favoring either ferromagnetic or anti-ferromagnetic coupling states. Specifically, P_{th,O} is lower than P_{th,E} when fₚ/2 is higher than fₕ, (so the system prefers an anti-ferromagnetic coupling state), while the opposite is true when fₚ/2 is lower than fₕ. Further, fₕ matches closely the resonance frequency (fᵣₑₛ) of the LiNbO₃ device.

Next, as shown in FIG. 5B, P_{th,E} and P_{th,O} were extracted while considering the POs coupled by both the piezoelectric resonant sensor and the power combiner used for the Ising tag prototype 400. As shown in FIG. 5B, it was found that the dispersive impedance of the power combiner creates a second transition point in the preferred coupling state. This transition occurs at a fₚ value corresponding to a fₚ/2 value labeled as fₗ in FIG. 5B. Specifically, when fₚ/2 is lower than fₗ, P_{th,O} is lower than P_{th,E} (i.e., the anti-ferromagnetic coupling state is preferred). In contrast, when fₚ/2 lies between fₗ and fₕ, the system exhibits a P_{th,O} value higher than P_{th,E}, and a ferromagnetic coupling configuration is favored.

Piezoelectric resonators, like the resonant sensors described herein, inherently exhibit sensitivity to ambient temperature (Tₐ) owing to the temperature coefficient of the Young's modulus of their constituent layers [41]. As a result, their resonance frequencies are detuned by any change (ΔTₐ) in Tₐ. Thus, when a piezoelectric resonator is used to couple two POs driven at fₚ, together with a power combiner, the POs' preferred coupling state becomes dependent on the ambient temperature following the resonator's Temperature Coefficient of Frequency (TCF, equal to −165 ppm/° C.) [41], [42]. As a result, while the POs may prefer a particular coupling state at a certain Tₐ, there exists a temperature threshold value (Tₜₕ) for any possible fₚ value at which the preferred coupling state changes. As shown in FIGS. 5C and 5D, this behavior was numerically confirmed by extracting P_{th,E} and P_{th,O} when considering the same piezoelectric resonant temperature sensor and power combiner considered in FIG. 5B while assuming a Tₐ value varying between room temperature and 75° C. During this numerical investigation, SPIN's behavior was studied vs. Tₐ for two distinct fₚ values, corresponding to fₚ/2 values of 438 MHz (near fₕ, see FIG. 5C) and 432 MHz (near fₗ, see FIG. 5D). In FIG. 5D it is shown that P_{th,E} was found to be lower than P_{th,O} for Tₐ<66° C., indicating that the system prefers a ferromagnetic coupling state. Once Tₐ exceeds 66° C., P_{th,E} becomes higher than P_{th,O} and the system starts favoring an anti-ferromagnetic coupling state. Thus, in this scenario, Tₜₕ is equal to 66° C. The opposite behavior was observed, as shown in FIG. 5D, for fₚ/2=432 MHz because the system reacts to a Tₐ value exceeding 40° C. by making P_{th,E} lower than P_{th,O}. This rich behavioral profile was corroborated by Harmonic Balance simulations [43], [44], discussed below, which indicates that SPIN can be used to implement the detection of violations in both directions of a set threshold through the proper selection of fₚ.

Although shown and described above and otherwise herein with respect to a PoI being temperature, it will be apparent in view of this disclosure that the operation of SPIN is agnostic to any specific PoI being sensed and can thus be applicable to any suitable PoI.

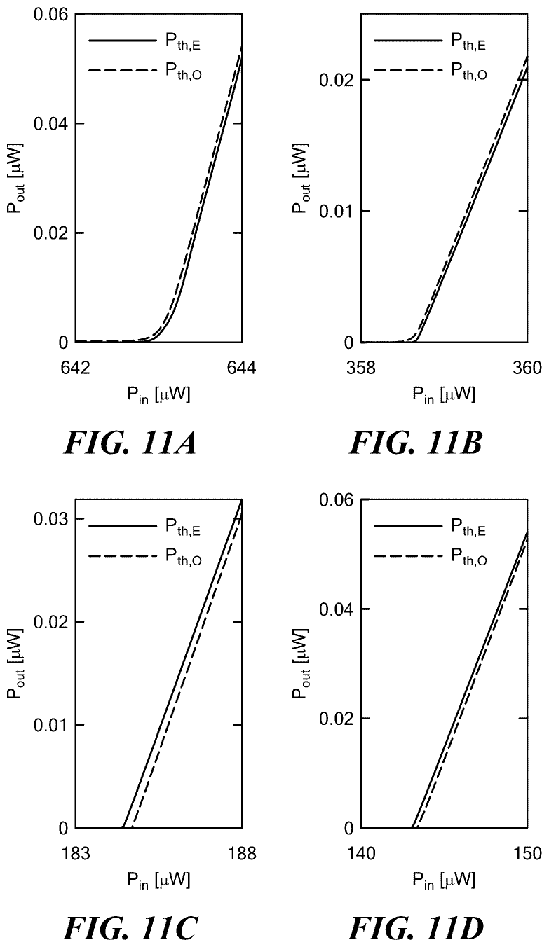

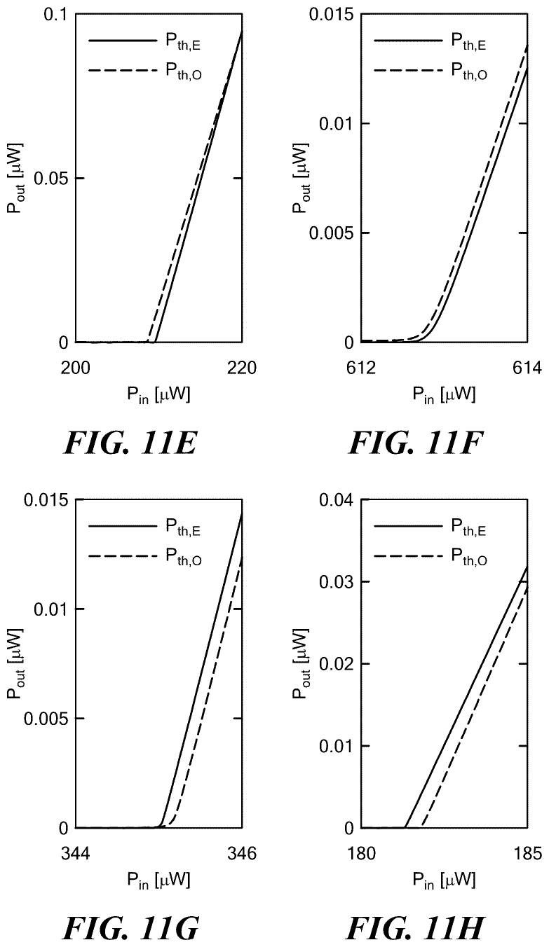

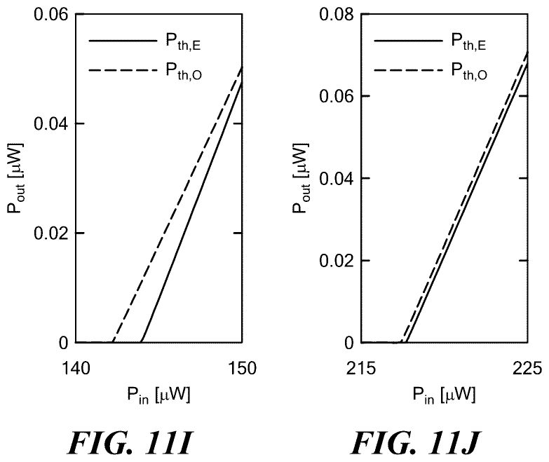

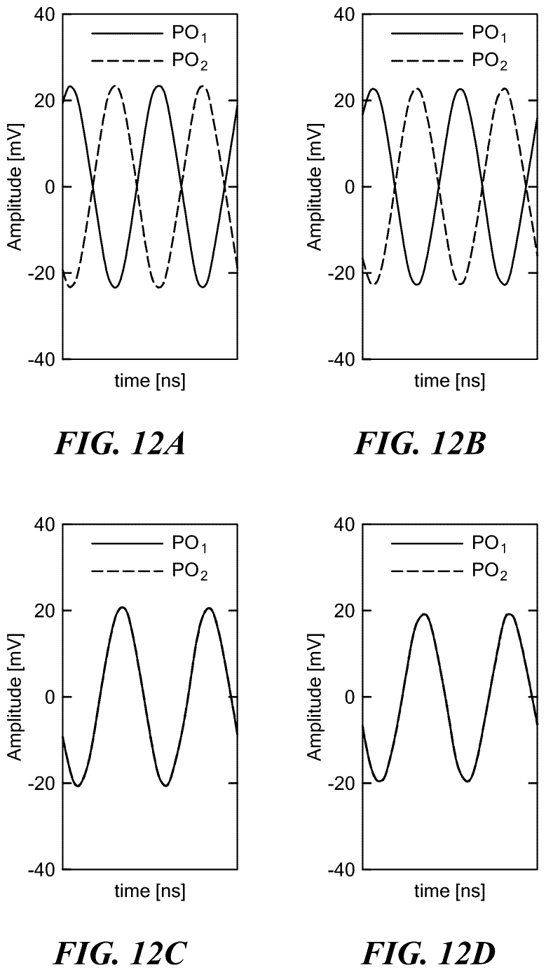

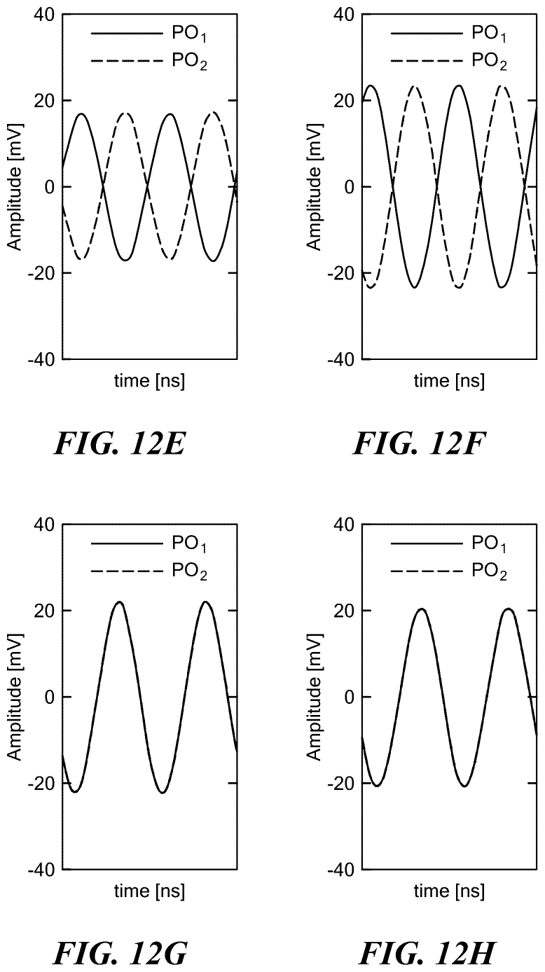

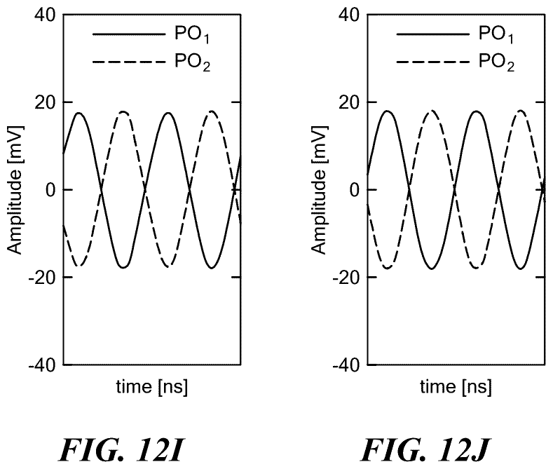

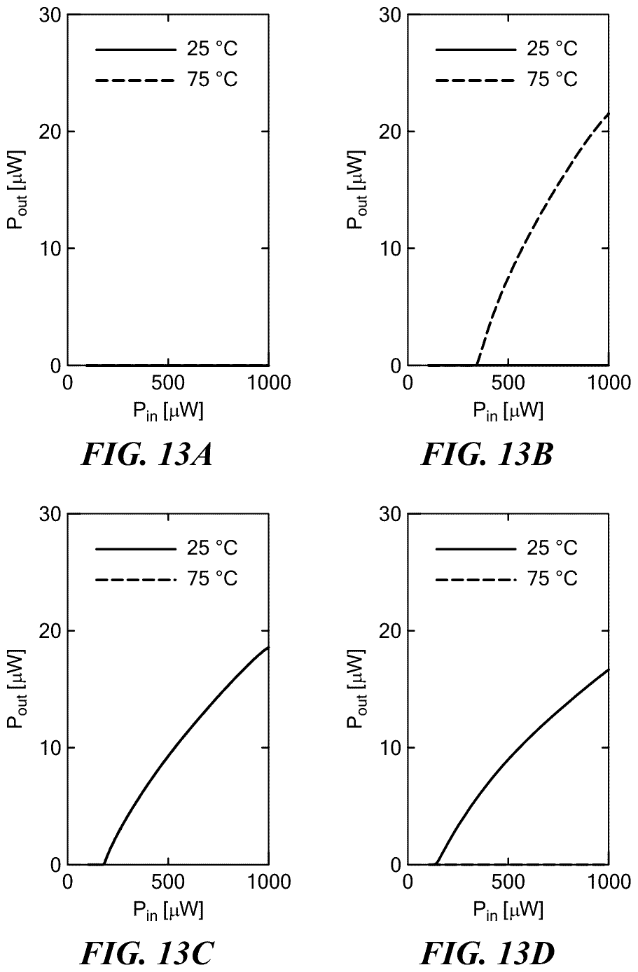

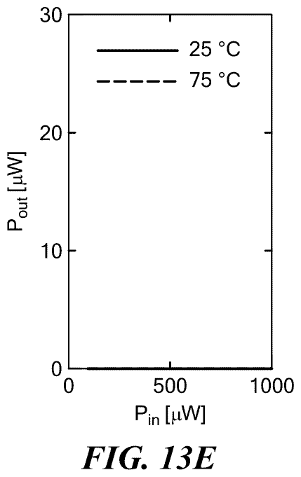

Even and Odd Mode Modelling of SPINS To further characterize the behavior of SPINs and their even and odd mode equivalent circuits shown in FIGS. 4A and 4C-4D, additional simulations were conducted leveraging the pAG technique [57], [59], [60]. These simulations were performed for a series of fₚ (corresponding to fₚ/2 values of 428 MHz, 431 MHz, 435 MHz, 438 MHz, and 442 MHz) at both Tₐ=25° C. and 75° C. Firstly, separate HB simulations were performed on SPINs' even and odd mode equivalent circuits, as shown in FIGS. 4C-4D. Pᵢₙ was swept from 100μ W to 1000μ W and continuously monitored Pₒᵤₜ at the output of each equivalent circuit for each combination of fₚ and Tₐ. In FIGS. 11A-J, the extracted trends of the even and odd mode equivalent circuits' output power at fₚ/2 vs. Pᵢₙ are shown. Because these simulations were performed on the even and odd mode equivalent circuits of the SPIN, P_{th,E} and P_{th,O} can be determined directly from each circuit's extracted Pₒᵤₜ. Unsurprisingly, these simulations confirm that the even and odd equivalent circuits exhibit different Pₜₕ values due to differences in their loading terminations (Z_{eq}). Even more, the difference between the P_{th,E} and P_{th,O} values extracted using HB simulations aligned with those found analytically as shown in FIGS. 5F-5H. After this characterization of P_{th,E} and P_{th,O}, time domain simulations were conducted for the entire SPIN circuit of FIG. 4A. In these simulations (plotted in FIGS. 12A-J), Pᵢₙ was swept from 100μ W to 1000μ W for the same combinations of fₚ and Tₐ. After reaching Pᵢₙ=1000μ W, the voltage waveforms of each PO were measured immediately before entering the power combiner's inputs. The waveforms depicted in FIG. 12A-E correspond to when Tₐ=25° C., while those shown in FIG. 12F-J correspond to Tₐ=75° C. Upon inspection, the only investigated fₚ/2 values producing a ferromagnetic coupling state at 25° C. are 435 MHz and 438 MHz, in accordance with the measurements of FIG. 18B and analytical modelling shown in FIG. 5F. At 75° C., a ferromagnetic coupling state is preferred only when fₚ/2 equals 431 MHz or 435 MHz, affirming that ΔTₐ-driven shifts of both fₗ and fₕ lead to changes in the Δφ across the investigated range of fₚ/2. A final set of HB simulations considering the aforementioned fₚ/2 and Tₐ conditions was performed to extract the power of the full SPIN circuit at its output (Pₒᵤₜ). In these simulations, Pᵢₙ was again swept from 100μ W to 1000μ W and continuously probed the output termination of the SPIN circuit for Pₒᵤₜ. FIGS. 13A-E depict Pₒᵤₜ for both investigated Tₐ values and for the same set of fₚ/2. The simulations shown in FIG. 13 illustrate that antiferromagnetic coupling states (when the voltage waveforms are out-of-phase with each other) result in a complete annihilation of Pₒᵤₜ while ferromagnetic coupling states (when the voltage waveforms are in-phase with each other) lead to strong values of Pₒᵤₜ. Since the preferred coupling state of the SPINs' POs maps directly to which equivalent circuit requires the least amount of energy to activate its subharmonic oscillations, the emergence of a strong or weak Pₒᵤₜ is directly linked to the mode competition between the even and odd equivalent circuits.

### Fabrication and Characterization of LiNbO₃ Resonator

### Fabrication Process

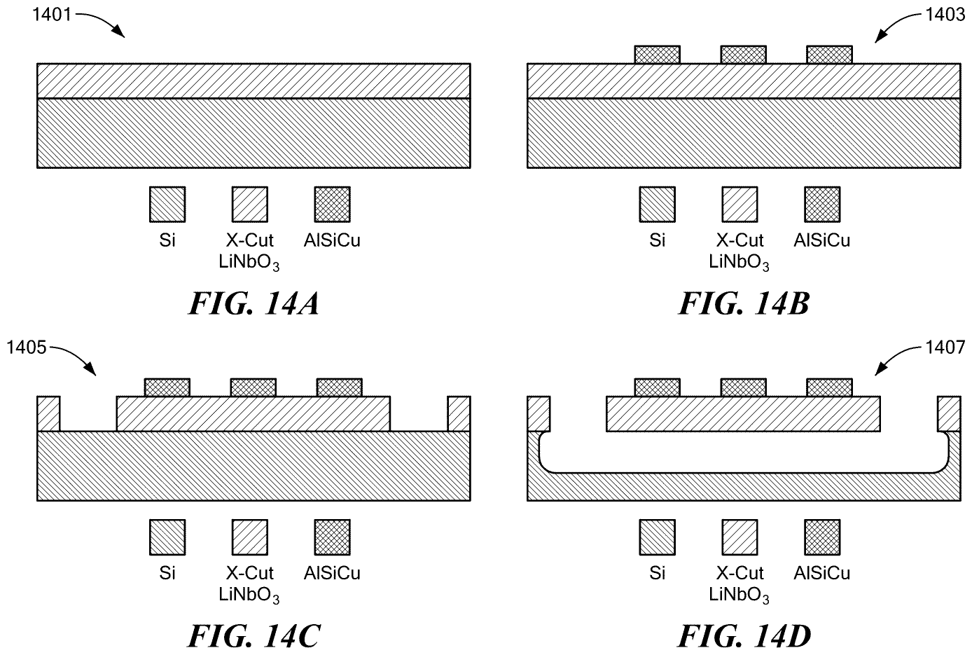

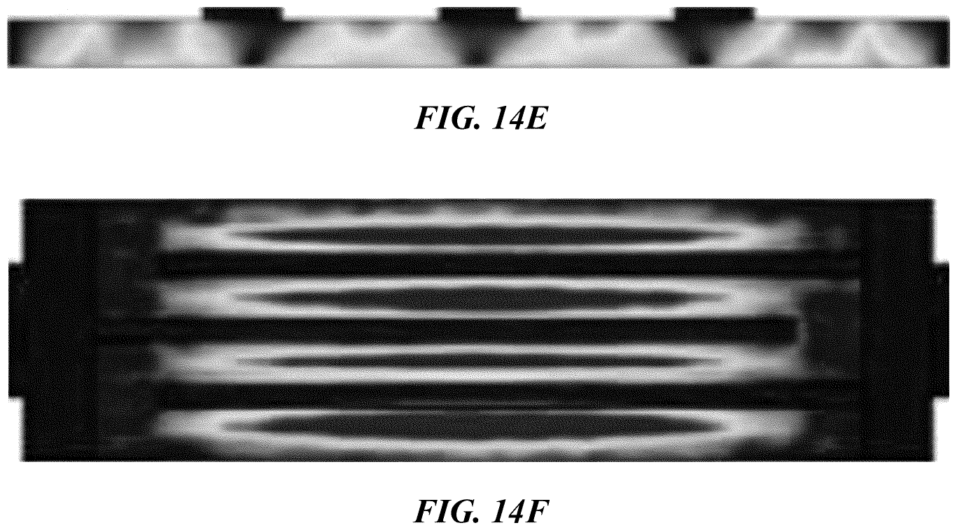

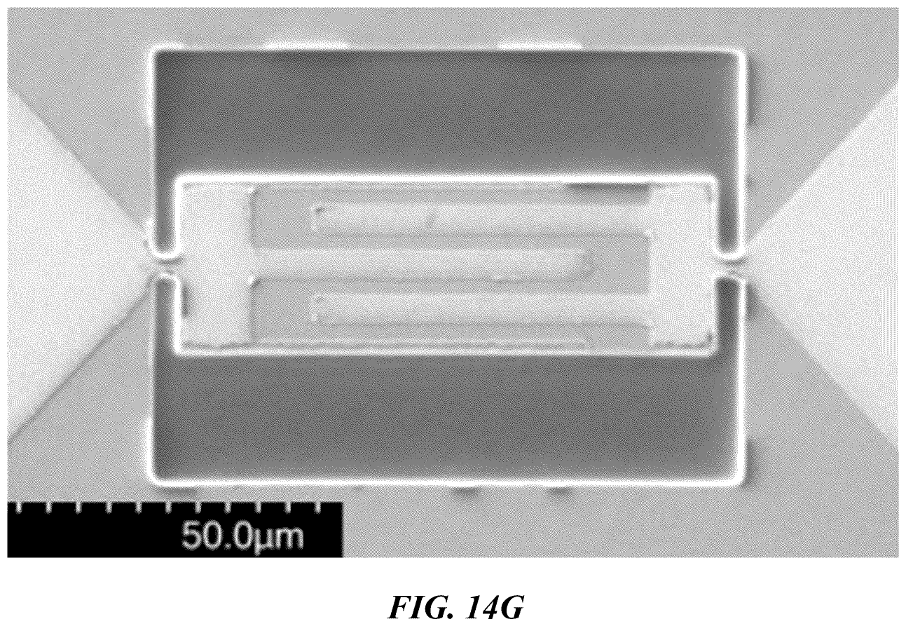

With regard to the X-Cut YZ30° lithium niobate (LiNbO₃) resonator used in the assembled SPIN prototype, it was designed as a Laterally Vibrating Resonator (LVR) operating in the S₀ mode with a resonance frequency of approximately 438.46 MHz in laboratory conditions [69]. Such a resonator was fabricated using the following process. In a first step 1401, a bulk lithium niobate wafer was bonded onto a high-resistivity silicon wafer through surface activation bonding by NGK, Ltd. Then, using chemical mechanical polishing and ion trimming, the layer of LiNbO 3 was thinned to a desired thickness of 1 μm (FIG. 14A). After this, in a second step 1403, a 200 nm layer of aluminum-silicon-copper (AlSiCu) was sputtered and patterned using chlorine-based reactive ion etching to form the resonator's interdigitated electrodes (FIG. 14B). Then, in a third step 1405, the resonator plate was patterned using an anisotropic ion milling physical etch with a 72° substrate angle (FIG. 14C). Finally, in a fourth step 1407, the device was released from the silicon substrate using 18 cycles of xenon difluoride (XeF₂) isotropic etching (FIG. 14D). The cross-sectional and top view stress mode shape at resonance of such a device, simulated using COMSOL® Multiphysics can be seen in FIG. 14E along with an SEM image of the fabricated device in FIG. 14F.

### Temperature Coefficient of Frequency (TCF)

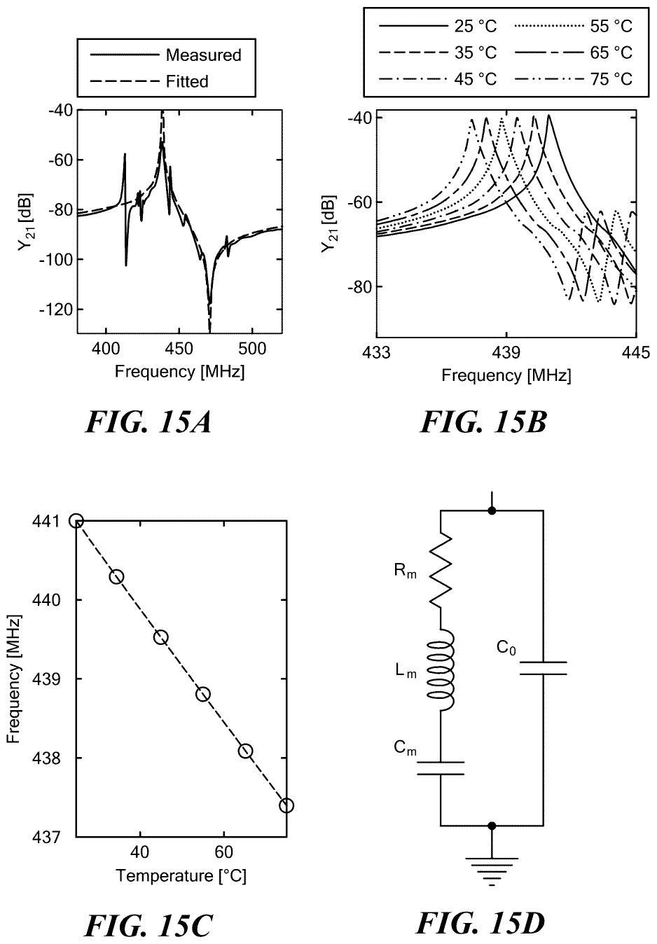

The S-parameters of the fabricated resonator were characterized in laboratory conditions via direct wafer probing with GSG probes. Its admittance was extracted analytically, and the device's electrical performance was fitted to the Butterworth Van-Dyke (BVD) model. When measured, the device exhibited a resonant frequency (fᵣₑₛ) of 438.46 MHz, an electromechanical coupling [symbol] of 16.9%, and a quality factor at resonance (Qₛ) of 2214. These parameters yielded an equivalent motional resistance (Rₘ), motional inductance (Lₘ), and motional capacitance (Cₘ) of 75.69Ω, 44.55 μH, and 2.96 fF respectively when modeled in the electrical domain. The static capacitance (C₀), indicating the intrinsic capacitance of the interdigitated structure at rest, was fitted as 19.47 fF (see FIG. 15A). After these measurements, the device was wire-bonded onto the SPIN's PCB. The device's admittance was re-extracted from the two output ports of the assembled SPIN prototype, showing a ~3 MHz shift in fᵣₑₛ due to electrical loading caused by the traces of the PCB and by the wirebonds. Then, the TCF of the LiNbO₃ device was extracted [69], [70]. This was done by raising Tₐ from room temperature (25° C.) to 75° C. in steps of 10° C. while measuring the resultant fᵣₑₛ of the device (see FIG. 15B). Subsequently, the device's TCF was determined by mathematically fitting a value for TCF to a first-order expression relating fᵣₑₛ, Tₐ, and TCF with respect to a baseline room temperature, as derived from [69]. This device's TCF was measured as −165 ppm/° C. (see FIG. 15C) [71], [72]. When modeling the assembled SPIN prototype in the circuital simulations, the extracted TCF was embedded within the BVD model to implement the measured shifts in fᵣₑₛ as a function of Tₐ (see FIG. 15D).

### Impact of Resonator Material Parameters on Mode Competition in SPINs

The following analysis describes an investigation of how varying the Qₛ and

$${k}_{t}^{2}$$

of the coupling element adopted in SPINs impacts the corresponding mode competition governing phase synchronization. In this regard, the trends of P_{th,E} and P_{th,O} were extracted for the system of two POs coupled with the lumped component model of the LiNbO₃ device used in experiments. The two POs were terminated to two separate 50Ω loads, and the computation of P_{th,E}−P_{th,O} was performed for a range of fₚ/2 between 438 MHz and 444 MHz while varying

$${k}_{t}^{2}$$

between 0.05 and 0.35, spanning most of the values of

$${k}_{t}^{2}$$

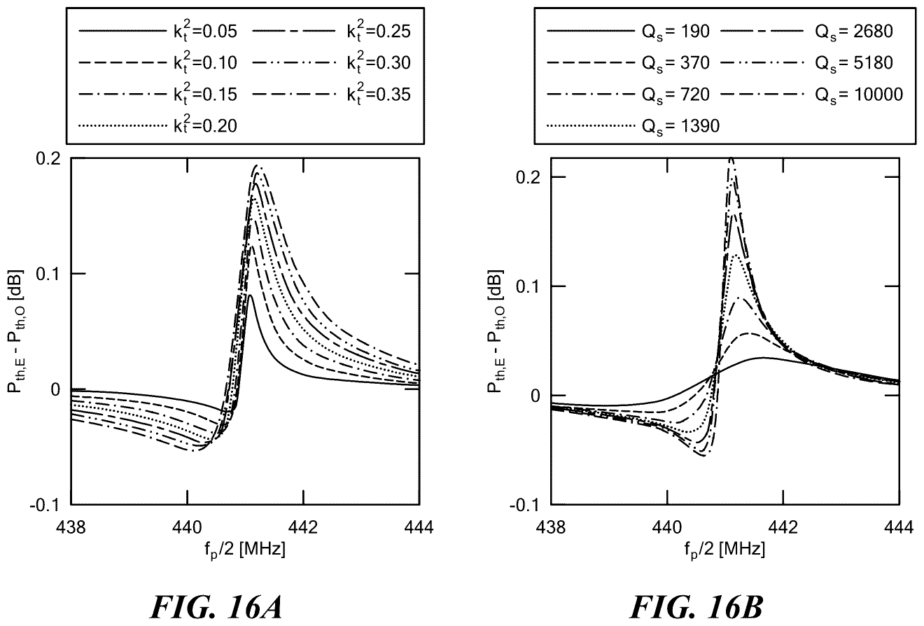

achievable with LiNbO₃ technology. As seen in FIG. 16A, reported findings indicate that the distance between fₕ and fᵣₑₛ increases monotonically by a small amount, but there is no phenomenological change to the dynamics of the mode competition. This same study was repeated, but this time logarithmically varying Qₛ between 190 and 10,000, as seen in FIG. 16B. In this regard, it was found that Qₛ affects the extent to which a certain phasesynchronization dominates the mode competition, particularly near fᵣₑₛ, observing progressively larger differences between P_{th,E} and P_{th,O} upon increasing Qₛ. It was also noted that Qₛ modifies the distance between fₕ and fᵣₑₛ.

In this work, a LiNbO₃ resonant sensor was built in-house for use in the demonstrated SPIN prototype because of its high TCF, which maps to a high responsivity to temperature variations. However, even other resonator technologies are available for use in SPIN and, more generally, in other RF systems. In this regard, a comparison table, Table 2, is reported listing Qₛ,

$${Q}_{s} , {k}_{t}^{2}$$

and TCF for RF MEMS resonant devices built on various piezoelectric substrates used for RF applications. As shown, LiNbO₃ resonators offer the highest TCF, as well as the highest achievable figure-of-merit (i.e., the highest Qₛ·

$${Q}_{s} \cdot {k}_{t}^{2}$$

product). Achieving a high figure-of-merit implies requiring a lower power to activate SPIN's subharmonic output signal, thus paving the way to longer interrogation ranges.

TABLE 2
$Comparison of TCF , {Q}_{s} , and {k}_{t}^{2} between different commonly used$
piezoelectric materials for fabricating LVR SAWs:

| Material | TCF | Qs | ${k}_{t}^{2}$ | FoM |
|---|---|---|---|---|
| X-Cut LiNbO₃ [73], [74] | −76 ppm/° C. | ~5000 | 43% | ~2150 |
| Y-Cut LiNbO₃ [73], [75] | −76 ppm/° C. | ~5000 | 43% | ~2150 |
| AlN [73], [76] | −26 ppm/° C. | ~5000 | 2% | ~100 |
| Al_{0.7}Sc_{0.3} N [77], [78] | −27 ppm/° C. | ~1500 | 9.7% | ~146 |
| Al_{0.8} Sc_{0.2} N [78], [79] | −25 ppm/° C. | ~1000 | 4.5% | ~45 |
| LiTaO_{3-on-quartz[80]} | −35 ppm/° C. | ~3000 | 10.3% | ~310 |

### Experimental Design and Results

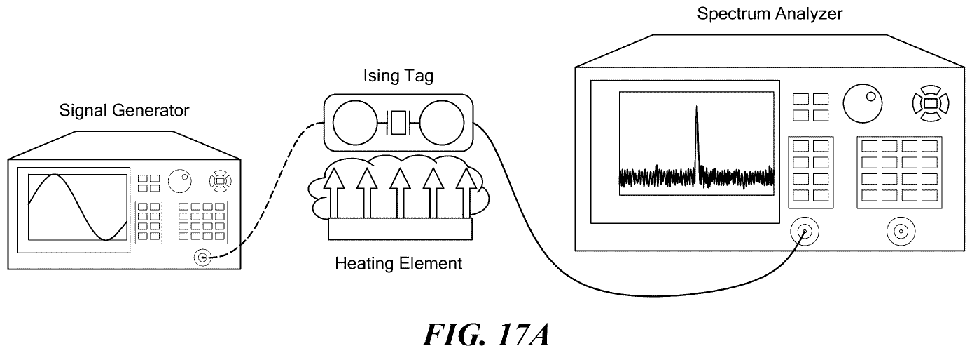

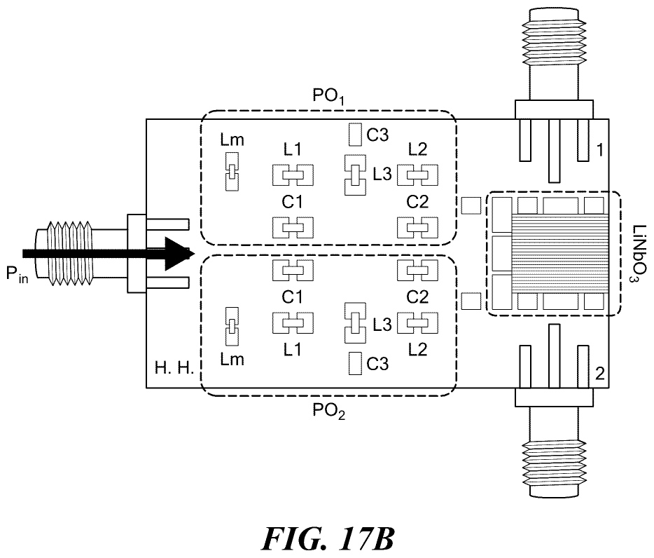

To experimentally demonstrate the operational principle of SPIN, a prototype Ising tag 400 as described above with reference to FIGS. 4A-4F was designed, built, and tested on a printed circuit board (PCB), shown in FIG. 17B, using off-the-shelf components and the same LiNbO₃ piezoelectric resonator 427 described above. The resonator was connected to the PCB using wirebonding. The assembled Ising tag comprises two identical POs 401 coupled by the LiNbO₃ device 427 and a Wilkinson power combiner 440 as shown in FIG. 4A. As shown in FIG. 18A, two off-the-shelf antennas (input antenna 250 and output antenna 275) operating around the targeted fₚ value (876 MHz, corresponding to fₚ/2=438 MHz) were connected at the POs' 401 input and output ports 450, 475 respectively, as schematically described in FIG. 2B. In the wireless experiment shown and described in connection with FIGS. 18A-18E these antennas 250, 275 were used to receive the interrogation signal and radiate the Ising tag's 400 output signal (the combined output signal resulting from the power-combined sum of the POs' 401 output signals).

The LiNbO₃ piezoelectric resonator 427 was fabricated using microfabrication processes. At ambient temperature, this device had a fᵣₑₛ value (~441 MHz) close to the targeted fₚ/2 value. Also, it showed a quality factor (Q) of 2214 and an electromechanical coupling coefficient [40]

$$( {k}_{t}^{2} )$$

of 16.9%.

Characterization of the prototype Ising tag 400 began by extracting the Pₜₕ value of its POs 401. This was done by performing a wired experiment, shown in FIGS. 17A-17B, in which the input and output ports of PO₁ were connected to a signal generator and a spectrum analyzer, respectively.

For the experimental setup used to characterize the performance of the prototype Ising tag 400, the input port of the assembled SPIN prototype was fed with a continuous wave (CW) signal generated from a signal generator (model no: Tektronix TSG 4104A) transmitting swept values of fₚ at various input power levels, Pᵢₙ.

The output of the SPIN prototype was connected to a spectrum analyzer (mode no: Agilent ESA-E Series E4402B) to monitor Pₒᵤₜ·Pᵢₙ was manually swept to determine the device's Pₜₕ across a range of different fₚ values.

More particularly, the signal generator was configured to produce a continuous-wave signal with frequency varying in finite steps from 428 MHz to 448 MHz. For each analyzed frequency value, the applied RF power was increased from −20 dBm until the prototype Ising tag 400 generated an output power at half of the input frequency (fₚ/2) that was measureable using the spectrum analyzer. Pₜₕ was found to vary between ~−5 dBm and −7 dBm across the spanned frequency range. Also, PO₁ and PO₂ were found to have nearly an identical power threshold despite inherent differences between the POs' 401 components caused by process variations and components' tolerance. The impact of such variations on the performance of SPINs is discussed in more detail below.

Additionally, a wired experiment was conducted in which the power combiner (model no: Pasternack PE2088) was removed from the SPIN prototype's circuit and connected at its output ports to the 50Ω ports of an oscilloscope (model no: Keysight InfiniiVision MSOX6004A) to measure the time domain waveforms of the generated subharmonic oscillations. For these experiments, fₚ and Pᵢₙ were swept to determine fₗ which is non-existent without the combiner, see FIG. 5A and fₕ, as well as to demonstrate the resiliency of the POs' synchronization to fluctuations in Pᵢₙ.

Next, the prototype Ising tag's 400 temperature characterization was started via the wireless experiment illustrated in FIGS. 18A-18E. The experiment intended to emulate a transceiver sending an interrogating signal to excite the SPIN prototype and reading its response over a range of fₚ and Tₐ values.

To this end, the antennas 250, 275 and power combiner were connected to the Ising tag 400 to produce a configuration as shown in FIG. 2B, and the assembled prototype Ising tag 400 was placed on top of a temperature-controlled heating chuck 1801. This allowed electronic control of the Ising tag's 400 temperature and, consequently, the fᵣₑₛ value of the LiNbO₃ device 427. The prototype Ising tag 400 was wirelessly interrogated at different frequencies from a one-meter distance. A spectrum analyzer 1803, connected to an off-the-shelf antenna 1805, was used to emulate the operation of the receiving module of a reader. Also, the spectrum analyzer 1803 was placed on top of a signal generator 1807 used to generate the interrogation signal, as shown in FIG. 18A. During this test, fₚ was varied between 852 MHz and 888 MHz, with 1 MHz steps. For each frequency value, a wirelessly transmitted power of 30 dBm was considered, which is enough to ensure that the Ising tag's 400 received power is above Pₜₕ. The Ising tag's 400 output power was measured for each explored frequency value. This was done by measuring the power at fₚ/2 received by the spectrum analyzer (P_{R}).

More particularly, the CW interrogating signal was transmitted through a wideband log-periodic antenna (model no: Aaronia HyperLOG 4025, with a gain of +4 dBi) after amplifying it with a power amplifier (model no: ZHL-1000-3 W+, with a power gain of +45 dB) to achieve an EIRP of +30 dBm [81]. The SPIN prototype's backscattered signal was received through an isotropic dipole antenna (model no: 712-ANT-433-CW-QW, with a gain of +3.3 dBi) connected to a spectrum analyzer to characterize P_{R}. The SPIN prototype was placed onto a temperature-controlled heating element positioned one meter away from the emulated transceiver's antennas and it was terminated at its input and output ports with two isotropic dipole antennas operating near fₚ (model no: AEACAC054010-S915, with a gain of +2 dBi) and fₚ/2 (model no: 712-ANT-433-CW-QW, with a gain of +3.3 dBi), respectively. For each combination of fₚ and Tₐ, the EIRP was swept from 0 dBm (representing a Pᵢₙ incident to the SPIN which is much lower than Pₜₕ) up to 30 dBm and then P_{R} was recorded.

As expected, the assembled prototype Ising tag 400 activated a ferromagnetic coupling state between its POs 401 within a limited range of fₚ/2 values, consistent with the modeling of FIG. 5B. Matching predictions, both the lowest and the highest frequencies of this frequency range (fₗ and fₕ) depend on Tₐ, as shown in FIG. 18B. When Ising tag 400 is interrogated at a frequency fₚ=fₓ lower than the room-temperature value for 2fₗ, there is a specific Tₐ value (i.e., Tₜₕ) above room temperature that renders fₗ equal to fₓ/2. As a result, for Tₐ≥Tₜₕ, the two POs 401 prefer a ferromagnetic coupling state, allowing the generation of a strong subharmonic output signal at fₓ/2. Similarly, when one interrogates the assembled SPIN prototype at a frequency fₚ=fₓ such that fₓ/2 is slightly higher than fₕ at room-temperature, there exists another Tₐ value (lower than room temperature) at which fₕ shifts up sufficiently to equate to fₓ/2. This inevitably triggers a change in the POs' preferred coupling state from anti-ferromagnetic to ferromagnetic and leads to the generation of a strong subharmonic output signal at fₓ/2. In other words, the Ising tag's Tₜₕ value is ultimately controllable by changing fₚ. When fₚ/2 is outside the range bounded by fₗ and fₕ for all considered Tₐ values, PO₁ and PO₂ always prefer an anti-ferromagnetic coupling state, which leads to a negligible output power level (ideally no power at all).

A second experiment was run, with results shown in FIG. 18C, to demonstrate the ability of Ising tags 400 to have their Tₜₕ value remotely programmed. In this experiment, four different fₚ values were selected (corresponding to fₚ/2 values of 432.7 MHz, 432.3 MHz, 431.8 MHz, and 431.3 MHz), all lower than the room-temperature value of fₗ. These selected fₚ values correspond to Tₜₕ values of 30° C., 40° C., 50° C., and 60° C., as shown in FIG. 18C.

Then, a 30 dBm continuous wave signal was transmitted at each one of these selected frequencies while sweeping the temperature of the heating chuck from 25° C. to 75° C., as shown in FIG. 18C. Meanwhile, P_{R} was recorded as shown in FIG. 18B. As expected, P_{R} becomes significant for Tₐ values higher than a Tₜₕ value that depends on the selected fₚ value. Through the same experimental set-up, distributions of fₗ vs. Tₐ and fₕ vs. Tₐ were also extracted, as reported in FIG. 18D. These two curves effectively map the correlation between Tₜₕ and fₚ for both threshold sensing modalities that the Ising tags can exploit. Both trends in FIG. 18D closely match the simulated trends found through circuit analysis.

Finally, the resilience of the preferred coupling state to fluctuations in the input power that may occur due to multipath interference was evaluated. This experiment was critical because multipath interference is a feature that makes any prior threshold-sensing device exploiting bifurcations unusable^{18,19}. This was done through a wired experiment in which the two antennas 250, 275 were disconnected, and the Ising tag's 400 input and output ports 450, 475 were connected to a 50Ω signal generator and to a 50Ω oscilloscope, respectively. During this last experiment, the assembled prototype Ising tag 400 was kept at room temperature and the output port of each PO 401 was connected to different ports of an oscilloscope. Then, two fₚ/2 values (441 MHz and 440 MHz) were arbitrarily selected, resulting in different preferred coupling states (anti-ferromagnetic and ferromagnetic, respectively) at room temperature. Next, Pᵢₙ was swept from −5 dBm to 5 dBm. This 10 dB variation serves to emulate the effect of multipath perturbing the Ising tag's 400 input power when operating in uncontrolled electromagnetic environments [38]. While sweeping Pᵢₙ, the phase difference between the POs' output signal (i.e., Δφ) was monitored. As shown in FIG. 18E, Δφ was found to be independent from Pᵢₙ, which is a key feature that distinguishes SPIN from any prior nonlinear passive tag and makes it accurately usable for threshold sensing even when SPIN's interrogation signal is distorted by multipath.

Thus, the present technology introduces a new class of wireless sensing devices that can leverage synchronization dynamics typical of Ising systems to passively implement threshold sensing at RF with a wirelessly programmable threshold value. SPINs allow reader devices to reliably identify violations of a targeted PoI even in multipath-intense settings and when many SPIN prototypes are deployed in close vicinity. The present technology also enables wireless reconfigurability of the temperature threshold and allows a single Ising tag to detect events where the ambient temperature rises above or drops below a certain programmable threshold.

### Analysis of SPINs Having N>2 POS

### N Resonantly Coupled POs

In this section, to characterize the behavior of large-scale SPINs, a model is presented that consolidates the system of equations depicted in Eq. (S.4)-Eq. (S.6) into a set of coupled equations modelling the dynamics of N resonantly coupled POs. Start with the following generalized system:

$${\dot{x}}_{i} = - ( \frac{{κ}_{i}}{2} + i {Δ}_{i} + {r}_{1} \vert {x}_{i} {\vert}^{2} ) {x}_{i} - i {r}_{2} {x}_{i}^{*} - {\sum }_{j \neq i}^{N} i {g}_{i , j} {y}_{i , j} \qquad ( S . 13 )$$

$${\dot{y}}_{i , j} = - ( \frac{{Γ}_{i , j}}{2} + i {Δ}_{i , j} ) {y}_{i , j} - i {g}_{i , j} ( {x}_{i} + {x}_{j} ) \qquad ( S . 14 )$$

Here, xᵢ represents the amplitude of the intracavity field of the mode representing the i^{th} PO while κᵢ, and Δᵢ depict the total loss rate and the detuning of the same i^{th} PO. Similarly, y_{i,j} represents the mechanical mode of the resonant element coupling the i^{th} and j^{th} POs while Γ_{i,j} and Δ_{i,j} depict the mode's mechanical loss rate and detuning. The detuning of intracavity and mechanical modes takes the form:

$${Δ}_{i} = 2 π ( {f}_{i} - \frac{{f}_{p}}{2} ) and {Δ}_{i , j} = 2 π ( {f}_{i , j} - \frac{{f}_{p}}{2} ) ,$$

respectively. The nonlinear coupling rate between the i^{th} and j^{th} POs and their corresponding mechanical mode y_{i,j} is given as g_{i,j}≈4Γ_{i,j}. In the following analysis, it is assumed that the system behaves symmetrically, e.g., terms with the subscript i, j equal those with the subscript j, i.

By taking the steady state approximation, these equations can be rewritten into a single generalized equation as:

$$0 = - ( \frac{{κ}_{i}}{2} + i {Δ}_{i} + {r}_{1} {\vert {x}_{i} \vert}^{2} ) {x}_{i} - i {r}_{2} {x}_{i}^{*} - {\sum }_{j \neq i}^{N} \frac{{g}_{i , j}^{2} ( {x}_{i} + {x}_{j} )}{( \frac{{Γ}_{i , j}}{2} + i {Δ}_{i , j} )} \qquad ( S . 15 )$$

This expression can be further simplified by defining the effective loss rate of the i^{th} PO(κ̅ₗ) as Eq. (S.16), the effective detuning of the i^{th} PO(Δ̅ₗ) as Eq. (S.17), and the effective coupling between the i^{th} and j^{th} POs (G_{i,j}) as Eq. (S.18).

$${\overline{κ}}_{l} = {κ}_{i} + {\sum }_{j \neq i}^{N} \frac{{g}_{i , j}^{2} {Γ}_{i , j}}{{( \frac{{Γ}_{i , j}}{2} )}^{2} + {Δ}_{i , j}^{2}} , \qquad ( S . 16 )$$

$${\overline{Δ}}_{l} = {Δ}_{i} - {\sum }_{j \neq i}^{N} \frac{{g}_{i , j}^{2} {Δ}_{i , j}}{{( \frac{{Γ}_{i , j}}{2} )}^{2} + {Δ}_{i , j}^{2}} , \qquad ( S . 17 )$$

$${G}_{i , j} = \frac{{g}_{i , j}^{2}}{( \frac{{Γ}_{i , j}}{2} + i {Δ}_{i , j} )} . \qquad ( S . 17 )$$

After implementing these simplifications, the governing equation of motion for the i^{th} PO takes a familiar form in Eq. (S.18), mapping quite nicely to the Ising model [82], [83]:

$$0 = - ( \overline{\frac{{κ}_{l}}{2}} + i \overline{{Δ}_{l}} + {r}_{1} {\vert {x}_{i} \vert}^{2} ) {x}_{i} - i {r}_{2} {x}_{i}^{*} - {\sum }_{j \neq i}^{N} {G}_{i , j} {x}_{j} \qquad ( S . 18 )$$

### Multidimensional Threshold Sensing

In some instances, one or more different PoIs are interrelated and, therefore, sensed values of each different PoI can affect the appropriate threshold for one or more of the other PoIs and a combined multidimensional threshold is more appropriate than a linear binary threshold. For example, as shown in FIGS. 19A-19D, temperature, light, and humidity or water exposure PoIs may all be interrelated. In such applications, threshold sensors must be capable of sensing and detecting such multidimensional thresholds.

Threshold sensing PoIs, in some embodiments, can include one or more of a physical parameter, an electrical parameter, a chemical agent, a biological agent, any other detectable parameter, or combinations thereof. For example, such parameters can include one or more of mass, acceleration, pressure, transduced spin waves, vibration frequency, vibration intensity, temperature, humidity, radiation concentration, radiation energy, radiation intensity, radiation type, acoustic frequency, acoustic intensity, acoustic power, acoustic phase, photonic intensity, photonic frequency, photonic phase, photonic polarization, voltage of an electrical signal, current of an electrical signal, power of an electrical signal, frequency of an electrical signal, magnetic field, concentration of a chemical agent, presence or absence of a chemical agent, concentration of a biological agent, presence or absence of a biological agent, or combinations thereof. Chemical agents associated with presence, absence, or concentration PoIs can include, for example, a gas, a toxin, a volatile organic compound, an atmospheric or water-born pollutant, a vehicle emission, an emission of an animal or human, soil moisture, a pharmaceutical agent or formulation ingredient, a polymer, and combinations thereof. Biological agents associated with presence, absence, or concentration PoIs can include, for example, a bacterium, a virus, a viral vector, a cell, an exosome, an extracellular vesicle, a cellular organelle or cell fragment, an antibody, a protein, a glycoprotein, a nucleic acid, an antigen, a tumor antigen, a sugar, an oligosaccharide, a polysaccharide, a lipid, a glycolipid, a sphingolipid, a vaccine, and combinations thereof.

As described below, it has been discovered that the principles of SPIN Ising tag technology as described above can be expanded and modified to detect such multidimensional thresholds.

FIGS. 19A-19D illustrate and describe an exemplary Ising tag 1900 for multidimensional threshold sensing in accordance with various embodiments. As shown in FIG. 19A, the exemplary Ising tag 1900 includes an input antenna 1950, an output antenna 1975, and is formed by four POs 1901 (PO₁₋₄) coupled by three resonant sensors 1925, 1926, 1927 and a fixed resistor 1928, as well as a power combiner 1940. The four POs 1901 of the exemplary Ising tag 1900 are arranged according to an arbitrarily chosen graph (see FIG. 19B). As shown in FIGS. 19A and 19B, the Ising tag 1900 also includes the first resonant sensor 1925 coupling PO₁ and PO₂ (R₁₂), the second resonant sensor 1926 coupling PO₂ and PO₃ (R₂₃), the third resonant sensor 1927 coupling PO₃ and PO₄ (R₃₄), and the fixed resistor 1928 coupling PO₁ and PO₃ (R₁₃). As shown in FIG. 19A, each of the three resonant sensors 1925, 1926, 1927 can be designed to sense a distinct PoI (e.g., temperature for the first resonant sensor 1925, light for the second resonant sensor 1926, and humidity for the third resonant sensor 1927). This structure was numerically analyzed, and FIG. 19C illustrates a multidimensional sensing threshold of the Ising tag 1900, defined and shown as a locus of all combinations of values of the three parameters of interest (R₁₂, R₂₃, R₃₄) for which the output signals of the four POs 1901 constructively interfere to increase an output power of the combined output signal of the Ising tag 1900. Because the exemplary Ising tag 1900 is sensitive to three PoIs, the locus takes the form, shown in FIG. 19C, of a portion of a three dimensional space (the shaded portion of the plot) in which the multidimensional threshold would be violated.

However, although shown and described herein as having four POs, three sensor elements, a fixed resistor, and a three-dimensional threshold, such multidimensional Ising tags can, in some embodiments have any number of POs, coupled by any corresponding number of senor elements. In addition, in various embodiments all available PO connections can be coupled by a sensor element (e.g., sensors 1925, 1926, 1927 coupling POs 1-2, 2-3, and 3-4 respectively as shown), some available PO connections can instead be coupled by other circuit elements (e.g., fixed resistor 1928 connecting POs 1-3 as shown), and/or some available PO connections can be uncoupled (e.g., POs 1-4 and 2-4 as shown).

The resonant sensors have the same resonance frequency when not perturbed by the PoIs, and the detuning of their resonance frequency caused by the targeted PoIs is assumed to be small. This allows consideration of the impedance of each resonant sensor (Rᵢⱼ, where i and j refer to the indexes of the POs that each resonator couples) resistive and dependent on the corresponding targeted PoI. When summing the POs' output signals through a power combiner, the 4-PO Ising tag 1900 of FIG. 19A shows a strong output power only for certain R₁₂, R₂₃, and R₃₄ values. Thus, the Ising tag 1900 meets the multidimensional threshold only for certain combinations of the three corresponding PoIs. This is illustrated, as noted above and as an example, the shaded volume of FIG. 19C, which includes all the possible values of R₁₂, R₂₃, and R₃₄ that lead to a strong output power level in the numerically analyzed 4-PO Ising tag 1900 arbitrarily chosen as a case study. This 4-PO Ising tag 1900 relies on the same graph reported in FIG. 19B for the coupling of its POs. For all the R₁₂, R₂₃, and R₃₄ values laying within the shaded volume in FIG. 19C, the POs 1901 interfere with each other constructively, leading to the generation of a strong output power at half of their received signal's frequency. Conversely, the four POs 1901 destructively interfere with each other when R₁₂, R₂₃, and R₃₄ are chosen to be out of the shaded volume, making the output power of the analyzed 4-PO Ising tag negligible. In other words, the analyzed 4-PO Ising tag implements multi-dimensional threshold sensing, activating a strong output signal only when the targeted PoIs fall within certain ranges of values that depend on the graph used to interconnect the POs.

In this regard, such multidimensional Ising tags are the first passive sensor technology for providing data-fusion of multi-sensor parameters for enhancing decision-making.

The state of various multidimensional Ising tags 1900 that are spatially distributed in a sensor network and that independently monitor the same set of PoIs can also help a centralized wired monitoring system 790 address certain optimization goals with higher accuracy as exemplified in FIG. 19D.

Thus, such multidimensional Ising tags enhance existing wireless sensing infrastructure with smarter passive components that can facilitate decision-making well beyond what is possible with prior art passive tags.

### Solving Max-Cut Problems to Implement Higher Order Functions

### Higer Order Interactions

In this section, the topological complexity of SPINs is expanded to enable multi-parameter sensing through Ising-based logical operations embedded within the solution of Max-Cut problems [84], [85]. In particular, the following analysis demonstrates how introducing changes in the Ising Hamiltonians of SPINs by detuning strategically selected mechanical resonant modes with respect to fₚ/2 imbues SPINs with more complex passively embedded computational capabilities. First, the behavior of the 4-PO SPIN shown in FIGS. 19A-19D is expanded to demonstrate how these computational capabilities can be achieved purely by leveraging frustration in the Ising Model. Then, specific 4-PO and 6-PO SPINs are described, wherein the POs are coupled by different resonant elements with resonance frequencies defined based on their detuning with respect to fₚ/2 to implement a mixture of positive and negative interaction terms in the investigated SPINs' coupling topology.

When analyzing the SPIN depicted in FIG. 19A, it was observed that the SPINs began the same collective behaviors governing the dynamics of large-scale Ising systems. Specifically, the POs undergo frustrated coupling as a function of the graph topology. Frustration refers to the inability of SPINs to simultaneously satisfy each pair of POs' synchronization preferences [83], [86]. Thus, the 4-PO SPIN depicted in FIG. 19A utilizes PoI-driven changes to several coupling resistances Rᵢⱼ to alter the system's optimal spin configuration via transformations of the problem graph that induce spin frustrations. The PoI-sensitive Ising Hamiltonian of such a system can be described using the following equation [60], [87], where PoIᵢⱼ refers to sensed temperature, luminosity, or humidity, in accordance with FIG. 19A, and the interaction term J_{i,j}, which is proportional to

$$\frac{1}{{R}_{i , j}} ,$$

is dependent on a certain PoI_{i,j}:

$$H = - {\sum }_{j \neq i}^{N} {J}_{i , j} ( P o {I}_{i , j} ) {σ}_{i} {σ}_{j} \qquad ( S . 19 )$$

Therefore, when summing the waveforms of the POs in the 4-PO SPIN shown in FIG. 19A, the system produces a negligible output when two POs are out of phase from the other two and a strong output when 3 or 4 POs are in-phase with each other. These preferred phase configurations are determined by the relative values of R_{i,j}, as set by the detected PoI_{i,j}. It is noted that the PoI-induced detuning of R_{i,j} in this scheme does not result in a change in the sign of J_{i,j}, yet sufficiently large changes in R_{i,j} lead to changes in the ground state solution. In this regard, SPIN exploits frustration dynamics to implement multi-dimensional threshold sensing based on several sensed Pols. To help visualize such a topology's use as a multiparameter sensor, FIG. 19C is included to illustrate the range of R_{i,j} where the 4-node SPIN yields a high output amplitude due to the PoI-driven detuning of its coupling network.

Logic Gates from Higher Order SPINs

For SPINs with topologies embodying positive and negative coupling interactions via the strategic selection of the coupling resonant modes' frequencies with respect to the pump, the logical inputs A and B can be assigned to the respective sign of the selected resonant mode detuning Δ_{A} and Δ_{B} (where Δ_{A} and Δ_{B} represent the detuning of two different resonators with respective sensitivity to the inputs A and B). Also, a 4-PO SPIN's output can be mapped to the summation of the waveforms of its POs' individual output signals at fₚ/2. In this regard, positive Δ_{A} or Δ_{B} values (corresponding to fᵣₑₛ>fₚ/2) represent a logical input of “1” while negative values of Δ_{A} or Δ_{B} embed a logical input of “0”. Referring to FIGS. 10A-F, one can clearly see that a positive or negative detuning of the resonator yields ferromagnetic or anti-ferromagnetic coupling, respectively, in a system of two coupled POs. In other words, the detuning specified by the inputs A and B alters the nature of the Max-Cut problem being solved by modifying the signs [and not just the value, as was done previously for the SPIN system shown in FIGS. 19A-19D of the coupling terms J_{i,j} in the Ising Hamiltonian shown in Eq. (S.19) [87].

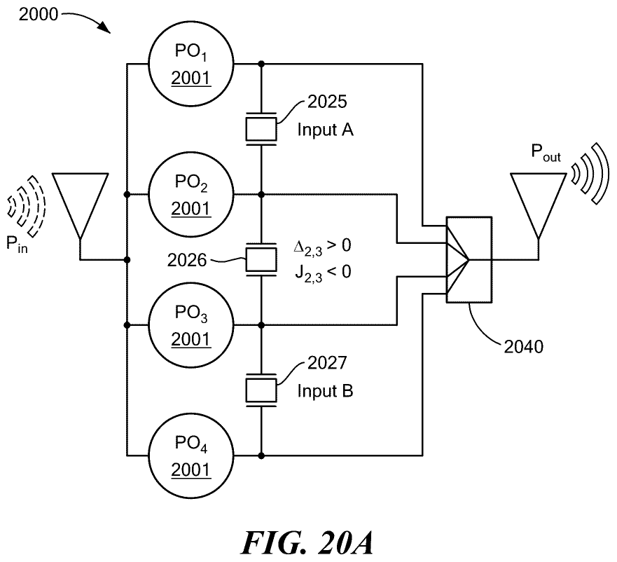

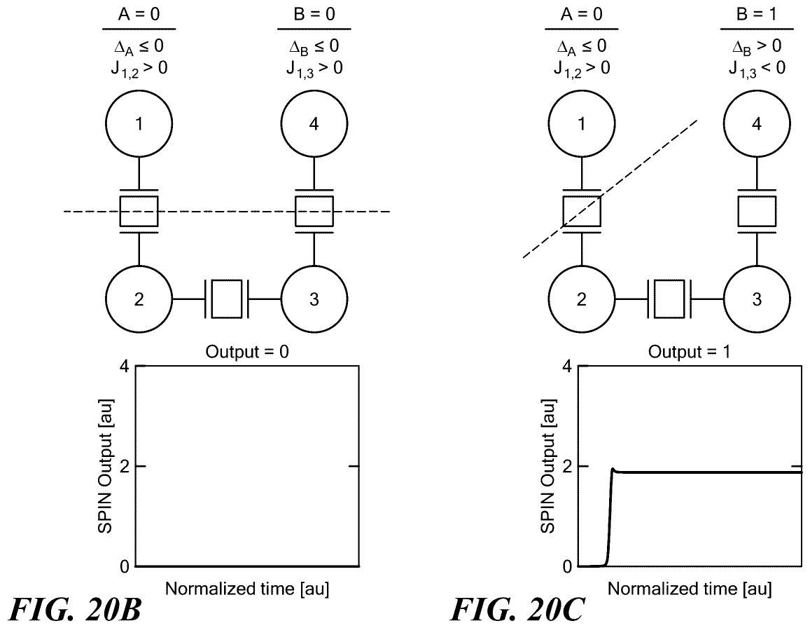

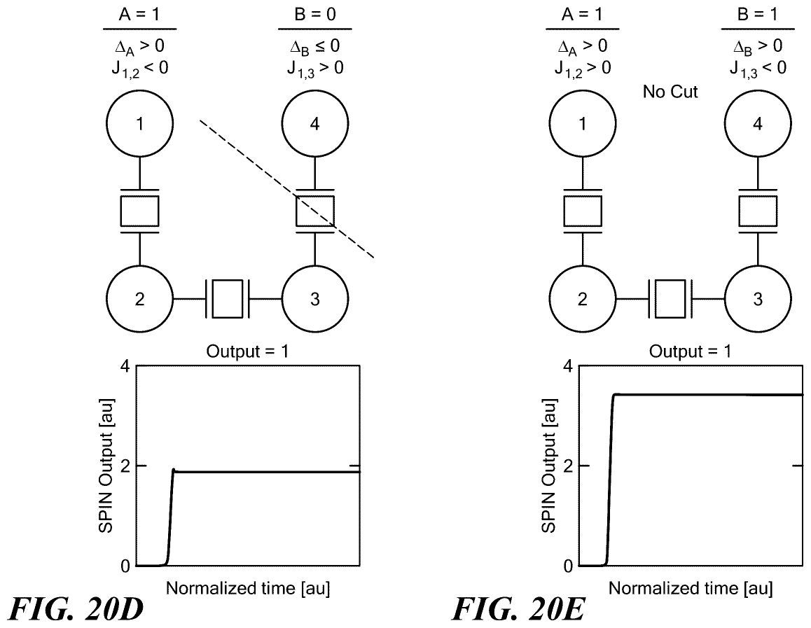

After the desired problem graph is configured by the inputs A and B through their Δ_{A} and Δ_{B}, the system is driven with a pump signal and the maximum-cut problem is solved. SPINs encode the solutions of the problems they solve into the bistable output phases of their POs. After synchronization, a problem graph yielding a non-zero sum of the POs' amplitudes produces a logical output of “1” while problems producing a negligible summed amplitude represent a logical output “0”. The most straightforward way to achieve a SPIN output of “0” is to somehow enforce the condition that an equal number of POs exist at both bistable phase values (0 and π). Alternatively, any imbalance in the number of POs at either possible phase state will inevitably produce a non-zero, or “1” output. This choice for mapping SPINs' outputs is most appropriate for devices with an even number of POs. Thus, by carefully selecting a SPIN's coupling topology and the respective Δ_{A} and Δ_{B}, more advanced computing and sensing functionalities can be passively embedded. To demonstrate this, three illustrative SPINs with 4 POs are presented in FIGS. 20A-E, 21A-E, and 22A-E, embodying the logical operation of OR, XOR, and AND gates respectively. In addition, two illustrative SPINs with 6 POs are presented in FIGS. 23A-E and 24A-E, embodying the logical operation of NOR and NAND gates, respectively.

Referring now to FIGS. 20A-E, the OR gate 2000 includes four POs 2001 having a coupling topology strategically selected such that the POs' 2001 output phase states are equally distributed between in-phase and out-of-phase only when A=B=0 (so Δ_{A} and Δ_{B} must be negative). When this condition for A and B is not satisfied, there must be an unequal distribution of POs across phase states (meaning that 3 or 4 POs must be synchronized in-phase). FIG. 20A illustrates a 4-PO SPIN topology 2000 for achieving this phenomenological behavior wherein the four POs 2001 are selectively coupled via three coupling elements 2025, 2026, 2027, with all four POs 2001 power combined via a power combiner 2040. As shown, PO₂ and PO₃ are ferromagnetically coupled by coupling element 2026. In general, for the OR gate 2000 or for any logic gate SPIN for which N>2, each coupled pair of POs and the coupling element by which they are coupled (e.g., PO₂ and PO₃ as coupled by coupling element 2026 encoding Input A) can be considered and referred to as “block” of the logic gate 2000.

To produce the OR gate, Δ_{2,3} is configured such that it produces J_{2,3}>0 regardless of any changes to Δ_{A} and Δ_{B}. This coupling network can yield solutions with even or uneven distributions of steady-state PO phases, when changing the signs of J_{i,j} (via Δ_{A} and Δ_{B}) in the corresponding Ising Hamiltonian. Thus, this topology provides the basis to access logical outputs of “0” and “1”. FIGS. 20B-E, show the output of the same SPIN 2000 of FIG. 20A for all 4 combinations of A and B. As shown, the SPIN 2000 shown in FIG. 20A has an output signal at fₚ/2 that is negligible only when both A and B are 0.

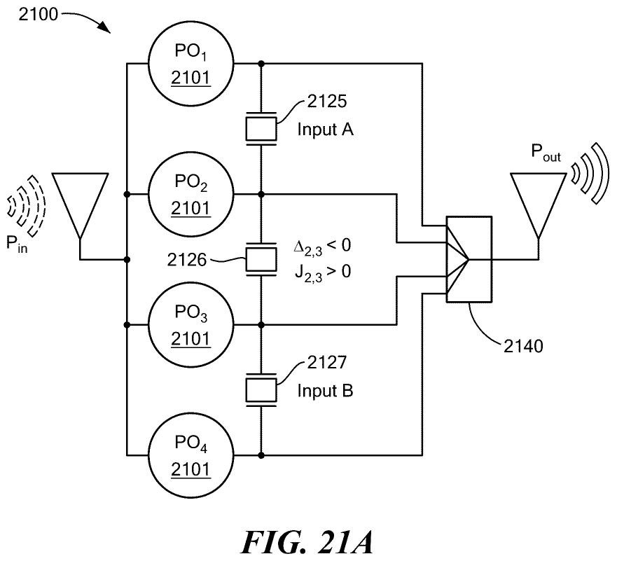

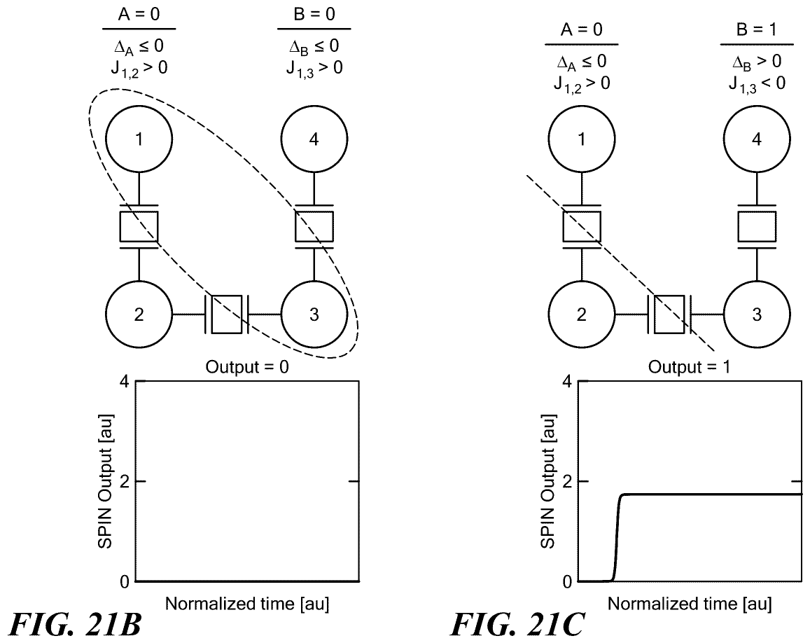

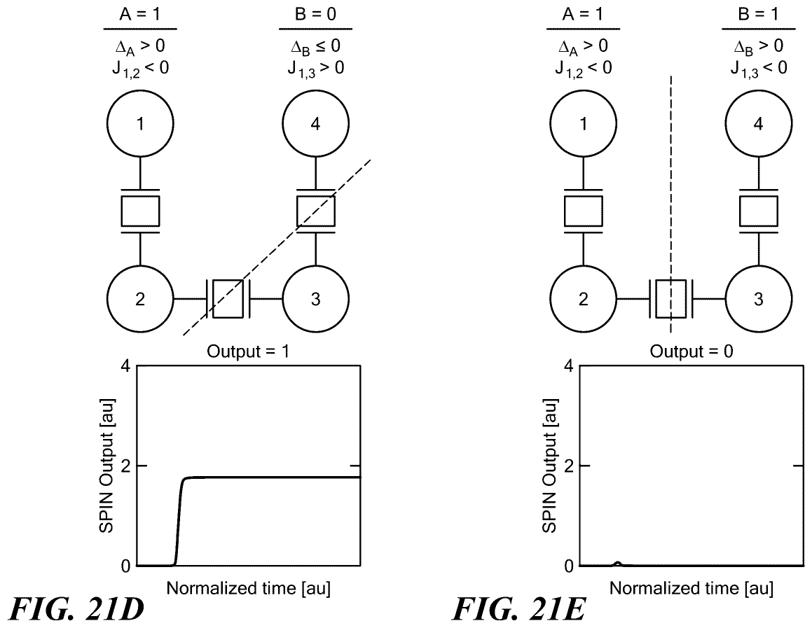

Referring now to FIGS. 21A-E, the XOR gate 2100 includes a similar four PO 2101 structure to the OR gate 2000, a similar procedure is applied, and a similar graph is selected. FIG. 21A illustrates a 4-PO SPIN topology of the XOR gate 2100 for achieving this phenomenological behavior wherein the four POs 2101 are selectively coupled via three coupling elements 2125, 2126, 2127, with all four POs 2101 power combined via a power combiner 2140. As shown, to produce the XOR gate PO₂ and PO₃ are anti-ferromagnetically coupled by coupling element 2126 such that Δ_{2,3} must be negative. Such a change in the coupling configuration of the topology between OR and XOR only affects SPIN's output when A=B=1. In this condition, the system will no longer be fully inphase, but will have “split” into two branches, each containing two in-phase POs, that are out-of-phase with the other branch. This results in the output of SPIN being negligible despite their existing ferromagnetic coupling between most of the POs. FIGS. 21B-E illustrate the maximum-cut solutions and numerically extracted outputs for all combinations of Δ_{A} and Δ_{B}. Note that such XOR logical sensing functionality would be applicable in situations where the sensed PoIs would generally be changing in the same direction, like temperature and pressure in a sealed gas system.

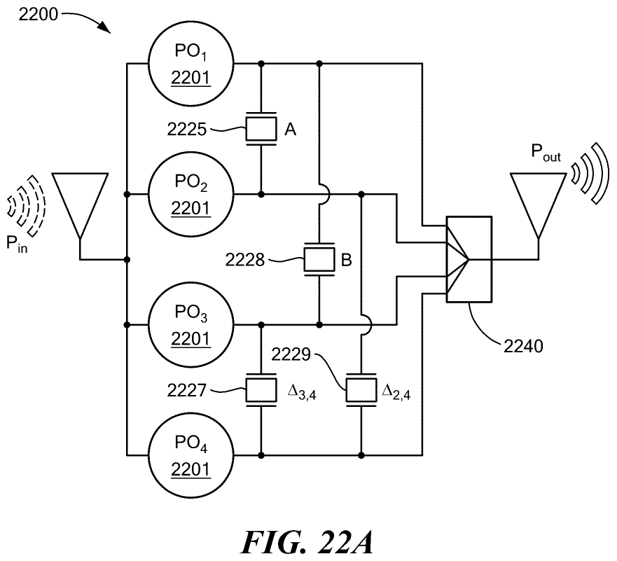

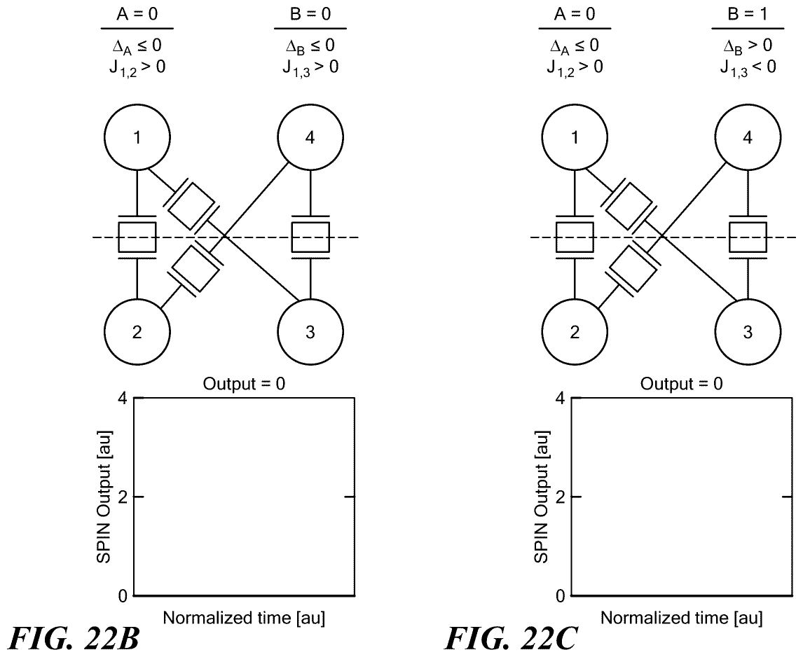

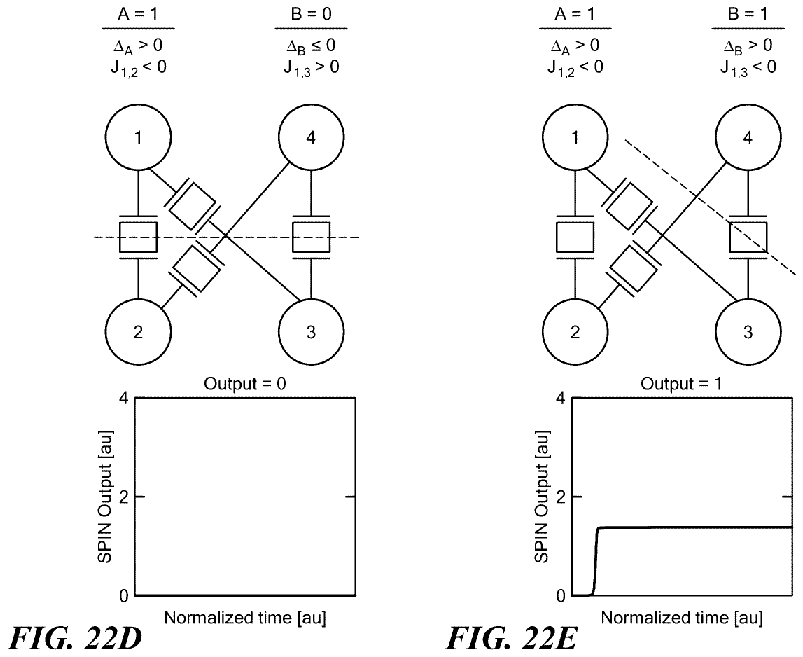

Referring now to FIGS. 22A-E, the AND gate 2200 uses a similar four PO 2201 structure but having different coupling topology. In particular, the detuning inputs are assigned to different mechanical modes than those used for the OR and XOR SPINs. This SPIN must exploit frustration in its problem solution to ensure that its output is “1” only when A and B are “1”. As shown in FIG. 22A, a 4-PO SPIN topology 2200 for achieving this phenomenological behavior is arranged according to a 4-node butterfly graph, wherein the four POs 2201 are selectively coupled via four coupling elements 2225, 2226, 2227, 2228 with all four POs 2201 power combined via a power combiner 2240. In particular, the inputs A and B are embedded in the detuning of the resonant modes y_{1,2} and y_{1,3}, respectively, while Δ_{2,4} and Δ_{3,4} are configured to produce anti-ferromagnetic coupling. FIGS. 22B-E show the maximum-cut graph solutions and numerically extracted output waveform for all combinations of A and B.

Referring now to FIGS. 23A-E, a NOR gate 2300 uses a six PO 2301 structure, having a coupling topology strategically selected to exploit frustration in its problem solution to ensure that its output is “1” only when A and B are both “0”. As shown in FIG. 23A, a 6-PO SPIN topology 2300 for achieving this phenomenological behavior is arranged according to a 6-node graph, wherein the 6 POs 2301 are selectively coupled via eight coupling elements 2325, 2326, 2327, 2329, 2330, 2331, 2332, 2333 with all 6 POs 2301 power combined via a power combiner 2340. In particular, the inputs A and B are embedded in the detuning of the resonant modes y_{1,2} and y_{4,5}, respectively, while Δ_{2,3} and Δ_{5,6} are configured to produce ferromagnetic coupling and Δ_{2,4}, Δ_{3,4}, Δ_{1,5}, and Δ_{1,6} are configured to produce anti-ferromagnetic coupling. FIGS. 23B-E show the maximum-cut graph solutions and numerically extracted output waveform for all combinations of A and B.

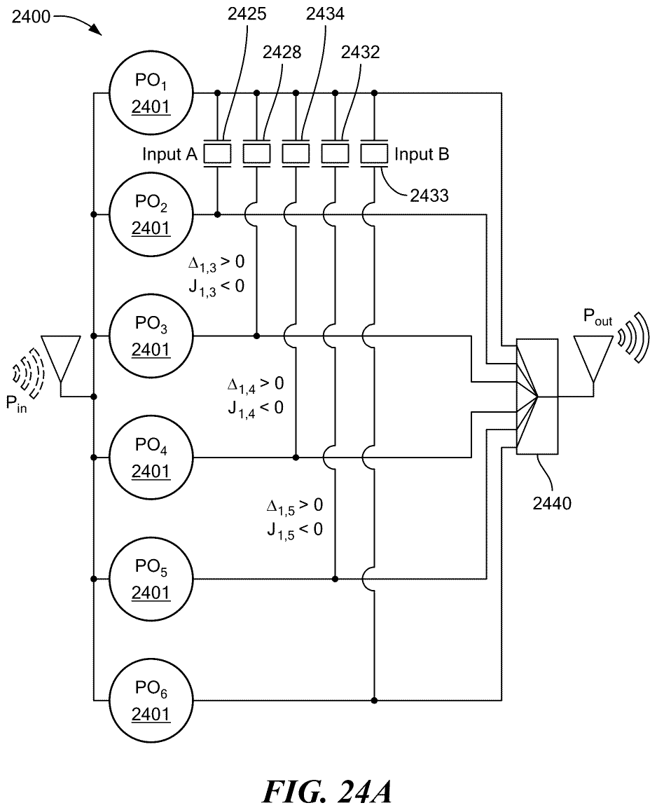

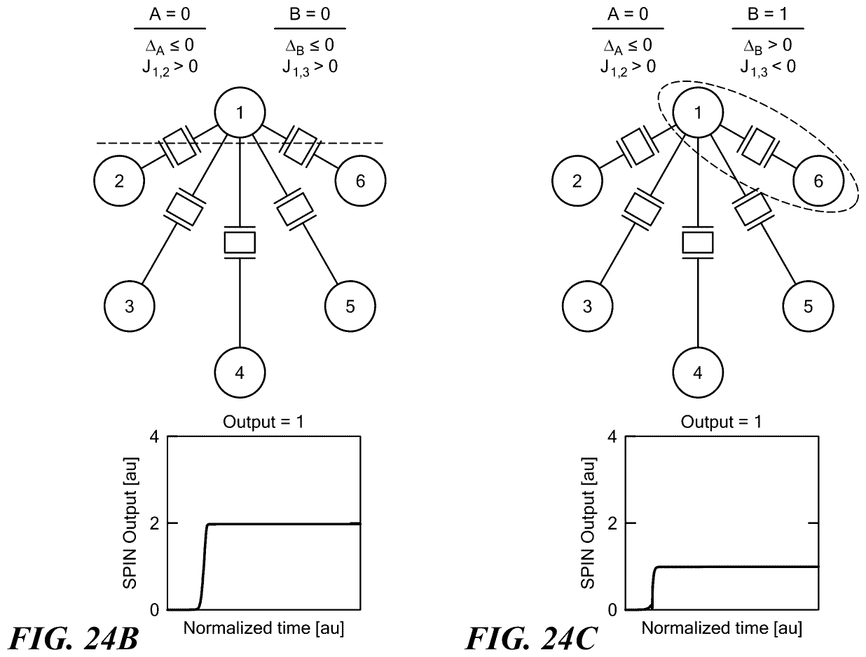

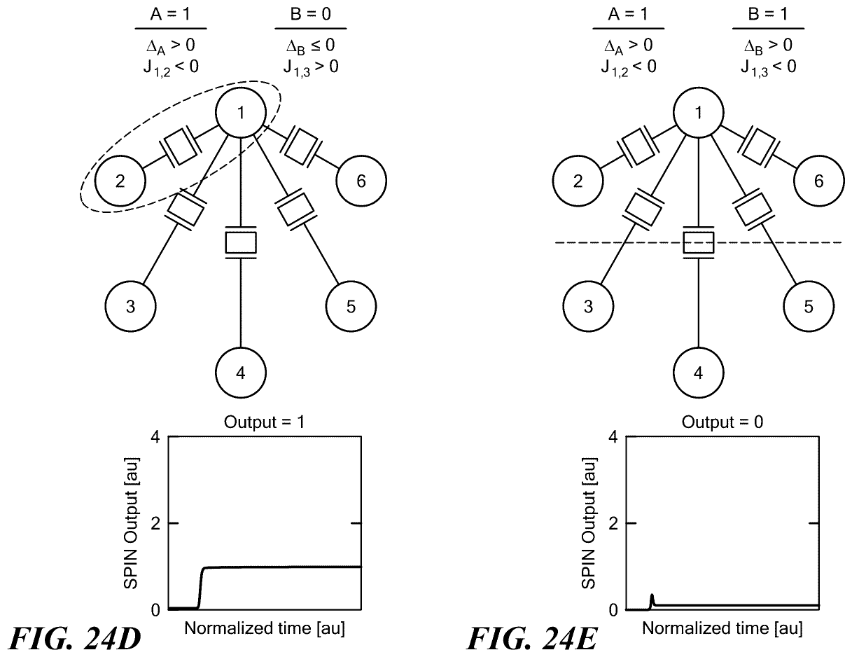

Referring now to FIGS. 24A-E, a NAND gate 2400 uses a six PO 2401 structure, having a coupling topology strategically selected to ensure that the POs' 2401 output phase states are equally distributed between in-phase and out-of-phase only when A=B=1. As shown in FIG. 24A, a 6-PO SPIN topology 2400 for achieving this phenomenological behavior is arranged according to a 6-node graph, wherein the 6 POs 2401 are selectively coupled via five coupling elements 2425, 2428, 2432, 2433, 2434 with all 6 POs 2301 power combined via a power combiner 2440. In particular, the inputs A and B are embedded in the detuning of the resonant modes y_{1,2} and y_{1,6}, respectively, while Δ_{1,3}, Δ_{1,4}, Δ_{1,5}, and Δ_{1,6} are configured to produce anti-ferromagnetic coupling. FIGS. 23B-E show the maximum-cut graph solutions and numerically extracted output waveform for all combinations of A and B.

### Analog Computing Engines

The provision of logic gates via the use of higher order SPINs, the present SPIN technology also makes possible the core unit of a new analog computing engine capable of reacting in real-time to changes in a group of parameters of interest. This reaction takes the form of a passively generated control signal. This control signal can be used by smart monitoring and automation systems to preserve optimal operating conditions under various scenarios, without running intense signal processing operations on wirelessly received sensing data. Moreover, because the envisioned SPIN-based computing engine autonomously produces the control signal based on its own sensed information, it does not need to transmit vast raw sensing data to a separate node with the requisite signal processing and computing capabilities. This reduces the congestion of the electromagnetic medium and the latency when multiple Ising tags are deployed for a finer-grained monitoring.

### Variations in SPINs' POs

### Variations for N=2

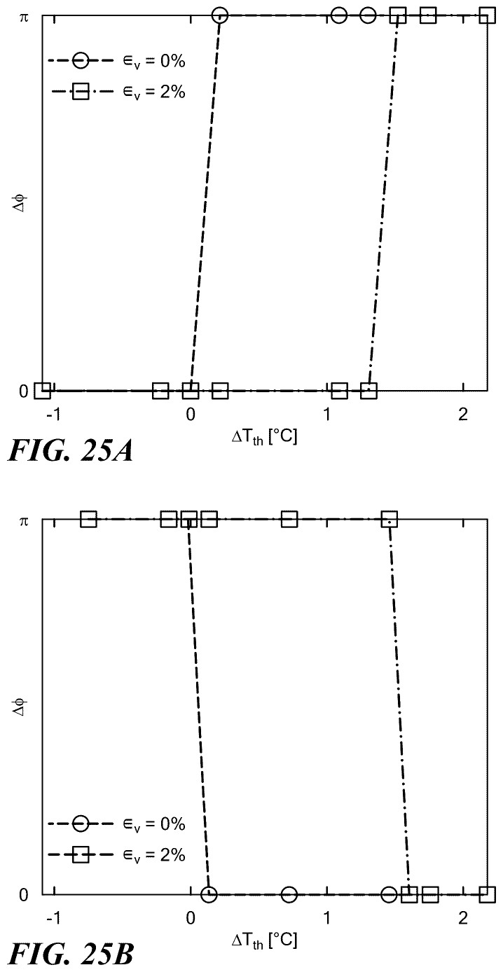

In order to study the impact of component tolerances, ϵ_{ν}, which can lead to asymmetries in the coupled POs of SPINs, the impact of variations in the POs' resonant frequency on the trends of Tₜₕ v. fₕ and Tₜₕ v. fₗ was studied. To conduct this investigation, the components of one of the POs in the simulated SPIN was intentionally detuned by 2% to model variations caused by the components' tolerances. Then, HB technique discussed above was applied for a fixed Tₐ of 25° C. while sweeping fₚ/2 around the fₗ and fₕ values calculated when neglecting the asymmetries. Next, the phase difference between the asymmetric SPIN's POs was monitored to precisely determine the new values of fₗ and fₕ that account for the asymmetries between the POs. Such new fₗ and fₕ values were found to have changed by ~0.1 MHz, which corresponds to a change of Tₜₕ (ΔTₜₕ) of ~1.5° C. compared to the perfectly symmetrical SPIN (where ϵ_{ν}=0), as seen in FIGS. 25A-B. Such ΔTₜₕ is below the temperature resolution required for the majority of cold chain temperature sensing applications [88]. It is worth mentioning that asymmetries in PO₁ and PO₂ can be compensated through calibration by extracting the Tₜₕ v. fₕ and Tₜₕ v. fₗ trends after completing the fabrication of SPINs.

### Variations for N>2

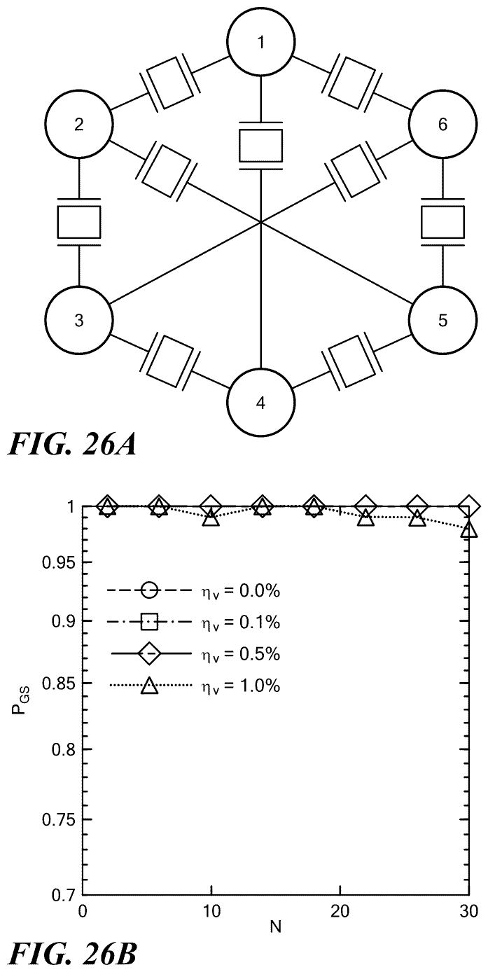

To understand the impact of device-to-device variations on the capabilities of higher-order SPINs to reliably settle to the Ising ground state, Eq. S. 18 was numerically solved when considering SPINs of increasing size (N). In this regard, all POs were arranged to be coupled in an antiferromagnetic fashion following a graph typically used for the characterization of Ising systems (the Mobius Ladder topology [60], [85], [89], see FIG. 26A). This specific topology is selected because its maximum-cut value can be calculated in closed-form, allowing us to compare the cut-size determined by the higher-order SPIN with the correct cut-size. Additionally, a parameter η_{ν} was introduced, arising from component and manufacturing tolerances, to model the inevitable variations in each PO's realized operational frequency,

$${f}_{i}^{v} ,$$

compared to the targeted design frequency of fₒₚₜ. In the analysis, all values of

$${f}_{i}^{v}$$

are considered as normally distributed around fₒₚₜ with a standard deviation of η_{ν}/3 so that 99% of the simulated POs have a variation within η_{ν}. There is also a relationship between the PO's variation η_{ν} and the component tolerances, ϵ_{ν}, which makes the selection of η_{ν} useful in subsequent numerical analysis. When synthesizing an LC resonant system, which can be used to model the PO's resonant branches [57], [60], its fₒₚₜ will be given as

$$\frac{1}{\sqrt{L C}} , while {f}_{i}^{v} = \frac{1}{\sqrt{L ( 1 + {ε}_{v} ) C}}$$

is synthesized for some variation of ϵ_{ν} in the inductor values. The ratio

$${f}_{o p t} / {f}_{i}^{v}$$

(which also maps to η_{ν}) can be described as \sqrt{(1+ϵ_{ν})}, which, for ϵ_{ν}→0, approximates to 1+ϵ_{ν}/2. Thus, the resultant variations in the POs, η_{ν}, can be treated as about half of the tolerated variations of the components, ϵ_{ν}. 100 simulations were run for each combination of N(2 to 30 in steps of 4) and η_{ν} (0%, 0.1%, 0.5%, and 1%). The probability of reaching the ground state (P_{GS}, used as the main parameter to evaluate the performance of higher-order SPINs) was computed as the ratio of the number of times the SPIN yielded the correct maximum-cut value to the total number of simulations. A random Wiener process was applied to inject noise into the system and a different randomized normal distribution of

$${f}_{i}^{v}$$

was generated for each simulation [90]. As can be seen in FIG. 26B, up to N=30 nodes, P_{GS} hardly degrades for the values of η_{ν} that are reasonably achievable within the constraints of current component and manufacturing tolerances.

### Advantages and Practical Applications

Ising Tags are described herein having coupled RF POs. Such Ising tags are useful in connection with a variety of applications, including, for example, parametrically reconfigurable and passive threshold sensing. Theoretical analysis and experimental validation of such devices reveals a distinct property: the energetic competition between the even and odd modes, and, consequently, the Pₒᵤₜ of Ising tags is independent to changes in the received power above the Ising tags' threshold. This distinctive property advantageously provides passive threshold sensing with an accuracy that is not degraded by multi-path or perturbations in the electromagnetic environment. In fact, by leveraging the collective dynamics of the coupled POs to encode the sensed parameter instead of active components or irreversible changes in a PT's radiation profile, Ising tags enable parametric reconfigurability while avoiding using batteries or energy harvesting circuits. In this regard, these experiments indicate that it is possible to measure violations of various temperature thresholds (or other PoI thresholds) using a singular Ising tag in an uncontrolled electromagnetic environment. The collective dynamics of the coupled POs in Ising tags also permits real-time simultaneous sensing of multiple and/or multi-dimensional PoIs and sensing-based passive computation for applications demanding sensitive reconfigurable threshold monitoring and accurate read-out capabilities without using battery-powered devices.

Uses of the present technology include wireless sensing, edge sensing, identification, RFIDs, analog computing, and neural networks.

PCT/US2024/019458 is hereby incorporated by reference in its entirety.

While example embodiments have been particularly shown and described, it will be understood by those skilled in the art that various changes in form and details may be made therein without departing from the scope of the embodiments encompassed or contemplated herein.

As used herein, “consisting essentially of” allows the inclusion of materials or steps that do not materially affect the basic and novel characteristics of the claim. Any recitation herein of the term “comprising”, particularly in a description of components of a composition or in a description of elements of a device, can be exchanged with “consisting essentially of” or “consisting of”.

### REFERENCES

[1] Kuglitsch, M. M., Pelivan, I., Ceola, S., Menon, M. & Xoplaki, E. Facilitating adoption of AI in natural disaster management through collaboration. Nat. Commun. 13, 1579 (2022).
[2] Madhvapathy, S. R. et al. Miniaturized implantable temperature sensors for the long-term monitoring of chronic intestinal inflammation. Nat. Biomed. Eng. (2024) doi: 10.1038/s41551-024-01183-w.
[3] Zhou, F. & Chai, Y. Near-sensor and in-sensor computing. Nat. Electron. 3, 664-671 (2020).
[4] Chiu, Y.-C. et al. A CMOS-integrated spintronic compute-in-memory macro for secure AI edge devices. Nat. Electron. 6, 534-543 (2023).
[5] Lenk, C. et al. Neuromorphic acoustic sensing using an adaptive microelectromechanical cochlea with integrated feedback. Nat. Electron. 6, 370-380 (2023).
[6] Paesani, S. & Brown, B. J. High-Threshold Quantum Computing by Fusing One-Dimensional Cluster States. Phys. Rev. Lett. 131, 120603 (2023).
[7] Landry, B. P., Palanki, R., Dyulgyarov, N., Hartsough, L. A. & Tabor, J. J. Phosphatase activity tunes two-component system sensor detection threshold. Nat. Commun. 9, 1433 (2018).
[8] Okawara, H. et al. Anaerobic threshold using sweat lactate sensor under hypoxia. Sci. Rep. 13, 22865 (2023).
[9] Xu, Z. et al. Reconfigurable nonlinear photonic activation function for photonic neural network based on non-volatile opto-resistive RAM switch. Light Sci. Appl. 11, 288 (2022).
[10] Gauthier, D. J., Bollt, E., Griffith, A. & Barbosa, W. A. S. Next generation reservoir computing. Nat. Commun. 12, 5564 (2021).
[11] Kuśmierz, Ł., Ogawa, S. & Toyoizumi, T. Edge of Chaos and Avalanches in Neural Networks with Heavy-Tailed Synaptic Weight Distribution. Phys. Rev. Lett. 125, 028101 (2020).
[12] Wright, L. G. et al. Deep physical neural networks trained with backpropagation. Nature 601, 549-555 (2022).
[13] Lin, R. et al. Wireless battery-free body sensor networks using near-field-enabled clothing. Nat. Commun. 11, 444 (2020).
[14] Kim, Y. et al. Remote control of muscle-driven miniature robots with battery-free wireless optoelectronics. Sci. Robot. 8, eadd1053 (2023).
[15] Hui, X. & Kan, E. C. Monitoring vital signs over multiplexed radio by near-field coherent sensing. Nat. Electron. 1, 74-78 (2017).
[16] Hui, X. & Kan, E. C. Radio ranging with ultrahigh resolution using a harmonic radio-frequency identification system. Nat. Electron. 2, 125-131 (2019).
[17] Niu, S. et al. A wireless body area sensor network based on stretchable passive tags. Nat. Electron. 2, 361-368 (2019).
[18] Hussein, H. M. E., Rinaldi, M., Onabajo, M. & Cassella, C. Capturing and recording cold chain temperature violations through parametric alarm-sensor tags. Appl. Phys. Lett. 119, 014101 (2021).
[19] Hussein, H. M. E., Rinaldi, M., Onabajo, M. & Cassella, C. A chip-less and battery-less subharmonic tag for wireless sensing with parametrically enhanced sensitivity and dynamic range. Sci. Rep. 11, 3782 (2021).
[20] Hussein, H. M. E., Kim, S., Rinaldi, M., Alù, A. & Cassella, C. Passive frequency comb generation at radiofrequency for ranging applications. Nat. Commun. 15, 2844 (2024).
[21] Biswas, K., Muthukkumarasamy, V., Bai, G. & Chowdhury, M. J. M. A reliable vaccine tracking and monitoring system for health clinics using blockchain. Sci. Rep. 13, 570 (2023).
[22] Zhang, J. et al. Real-time, selective, and low-cost detection of trace level SARS-CoV-2 spike-protein for cold-chain food quarantine. Npj Sci. Food 5, 12 (2021).
[23] Brush, S. G. History of the Lenz-Ising Model. Rev. Mod. Phys. 39, 883-893 (1967).
[24] Newell, G. F. & Montroll, E. W. On the Theory of the Ising Model of Ferromagnetism. Rev. Mod. Phys. 25, 353-389 (1953).
[25] Navarro-Moratalla, E. & Jarillo-Herrero, P. The Ising on the monolayer. Nat. Phys. 12, 112-113 (2016).
[26] Kalinin, K. P. & Berloff, N. G. Computational complexity continuum within Ising formulation of NP problems. Commun. Phys. 5, 20 (2022).
[27] English, L. Q., Zampetaki, A. V., Kalinin, K. P., Berloff, N. G. & Kevrekidis, P. G. An Ising machine based on networks of subharmonic electrical resonators. Commun. Phys. 5, 333 (2022).
[28] Heugel, T. L., Zilberberg, O., Marty, C., Chitra, R. & Eichler, A. Ising machines with strong bilinear coupling. Phys. Rev. Res. 4, 013149 (2022).
[29] Xiao, P. Optoelectronics for refrigeration and analog circuits for combinatorial optimization. (University of California, Berkeley, 2019).
[30] Calvanese Strinati, M., Bello, L., Pe'er, A. & Dalla Torre, E. G. Theory of coupled parametric oscillators beyond coupled Ising spins. Phys. Rev. A 100, 023835 (2019).
[31] Calvanese Strinati, M. et al. Coherent dynamics in frustrated coupled parametric oscillators. New J. Phys. 22, 085005 (2020).
[32] Calvanese Strinati, M. & Conti, C. Multidimensional hyperspin machine. Nat. Commun. 13, 7248 (2022).
[33] Casilli, N. et al. Parametric Frequency Divider Based Ising Machines. Phys. Rev. Lett. 132, 147301 (2024).
[34] Heugel, T. L. Parametrons: From Sensing to Optimization Machines. 190 p. (ETH Zurich, 2022). doi: 10.3929/ETHZ-B-000543175.
[35] Hong, H. & Strogatz, S. H. Conformists and contrarians in a Kuramoto model with identical natural frequencies. Phys. Rev. E 84, 046202 (2011).
[36] Strogatz, S. Nonlinear Dynamics and Chaos: with Applications to Physics, Biology, Chemistry, and Engineering. (Westview Press, Cambridge, Mass, 2007).
[37] Hussein, H. M. E. et al. Systematic Synthesis and Design of Ultralow Threshold 2:1 Parametric Frequency Dividers. IEEE Trans. Microw. Theory Tech. 68, 3497-3509 (2020).
[38] Pozar, D. M. Microwave Engineering. (Wiley, Hoboken, NJ, 2012).
[39] Roberg, M. & Campbell, C. A Novel Even & Odd-Mode Symmetric Circuit Decomposition Method. in 2013 IEEE Compound Semiconductor Integrated Circuit Symposium (CSICS) 1-4 (IEEE, Monterey, CA, USA, 2013). doi: 10.1109/CSICS.2013.6659204.
[40] Mallick, A. et al. CMOS-compatible ising machines built using bistable latches coupled through ferroelectric transistor arrays. Sci. Rep. 13, 1515 (2023).
[41] Colombo, L., Kochhar, A., Vidal-Alvarez, G. & Piazza, G. X-Cut Lithium Niobate Laterally Vibrating MEMS Resonator With Figure of Merit of 1560. J. Microelectromechanical Syst. 27, 602-604 (2018).
[42] Colombo, L., Kochhar, A., Vidal-Alvarez, G. & Piazza, G. High-Figure-of-Merit X-Cut Lithium Niobate MEMS Resonators Operating Around 50 MHz for Large Passive Voltage Amplification in Radio Frequency Applications. IEEE Trans. Ultrason. Ferroelectr. Freq. Control 67, 1392-1402 (2020).
[43] Cassella, C. & Piazza, G. Low phase-noise autonomous parametric oscillator based on a 226.7 MHz AlN contour-mode resonator. IEEE Trans. Ultrason. Ferroelectr. Freq. Control 62, 617-624 (2015).
[44] Suárez, A. Analysis and Design of Autonomous Microwave Circuits. (Wiley, IEEE Xplore, Hoboken, New Jersey, [Piscataway, New Jersey], 2015).

### Additional Refs

[45] H. El Matbouly, S. Tedjini, K. Zannas, and Y. Duroc, “Compact Multi Bit Slotted CScatterer for Threshold Sensitive Chipless Wireless Temperature Sensor,” Technologies, vol. 6, no. 3, p. 59, June 2018, doi: 10.3390/technologies6030059.
[46] G. Shi, X. Shen, L. Gu, S. Weng, and Y. He, “Multipath Interference Analysis for LowPower RFID-Sensor Under Metal Medium Environment,” IEEE Sens. J., vol. 23, no. 18, pp. 20561-20569, September 2023, doi: 10.1109/JSEN.2023.3253571.
[47] M. Škiljo, P. Šolić, Z. Blažević, and T. Perković, “Analysis of Passive RFID Applicability in a Retail Store: What Can We Expect?,” Sensors, vol. 20, no. 7, p. 238 April 2020, doi: 10.3390/s20072038.
[48] G. Wang et al., “A Generalized Method to Combat Multipaths for RFID Sensing,” IEEEACM Trans. Netw., vol. 31, no. 1, pp. 336-351, February 2023, doi: 10.1109/TNET.2022.3190862.
[49] S. Sauer and W.-J. Fischer, “An Irreversible Single-Use Humidity-Threshold Monitoring Sensor Principle for Wireless Passive Sensor Solutions,” IEEE Sens. J., vol. 16, no. 18, pp. 6920-6930 September 2016, doi: 10.1109/JSEN.2016.2590837.
[50] A. A. Babar, S. Manzari, L. Sydanheimo, A. Z. Elsherbeni, and L. Ukkonen, “Passive UHF RFID Tag for Heat Sensing Applications,” IEEE Trans. Antennas Propag., vol. 60, no. 9, pp. 4056-464 September 2012, doi: 10.1109/TAP.2012.2207045.
[51] R. Bhattacharyya, C. Di Leo, C. Floerkemeier, S. Sarma, and L. Anand, “RFID tag antenna based temperature sensing using shape memory polymer actuation,” in 2010 IEEE Sensors, Kona, HI: IEEE, November 2010, pp. 2363-2368. doi: 10.1109/ICSENS.2010.5690951.
[52] T. Athauda, R. Bhattacharyya, N. Karmakar, and S. Sarma, “Electromagnetic characterization of a food safe, organic smart material for customizable temperature threshold sensing in cold chain applications,” in 2019 IEEE International Conference on RFID (RFID), Phoenix, AZ, USA: IEEE, April 2019, pp. 1-6. doi: 10.1109/RFID.2019.8719251.
[53] Y. Shafiq, J. S. Gibson, H. Kim, C. P. Ambulo, T. H. Ware, and S. V. Georgakopoulos, “A Reusable Battery-Free RFID Temperature Sensor,” IEEE Trans. Antennas Propag., vol. 67, no. 10, pp. 6612-6626 October 2019, doi: 10.1109/TAP.2019.2921150.
[54] W. Wang, W. Zeng, A. Sadeqi, and S. Sonkusale, “Wireless Temperature Monitoring With Shape Memory Alloy-Based Antenna,” IEEE Antennas Wirel. Propag. Lett., vol. 20, no. 3, pp. 313-316, March 2021, doi: 10.1109/LAWP.2020.3048884.
[55] H. M. E. Hussein, M. Rinaldi, M. Onabajo, and C. Cassella, “Capturing and recording cold chain temperature violations through parametric alarm-sensor tags,” Appl. Phys. Lett., vol. 119, no. 1, p. 014101, July 2021, doi: 10.1063/5.0054022.
[56] H. M. E. Hussein, M. Rinaldi, M. Onabajo, and C. Cassella, “A chip-less and battery-less subharmonic tag for wireless sensing with parametrically enhanced sensitivity and dynamic range,” Sci. Rep., vol. 11, no. 1, p. 3782 December 2021, doi: 10.1038/s41598-021-82894-x.
[57] H. M. E. Hussein, M. A. A. Ibrahim, G. Michetti, M. Rinaldi, M. Onabajo, and C. Cassella, “Systematic Synthesis and Design of Ultralow Threshold 2:1 Parametric Frequency Dividers,” IEEE Trans. Microw. Theory Tech., vol. 68, no. 8, pp. 3497-359 August 2020, doi: 10.1109/TMTT.2020.2999790.
[58] A. Suarez, Analysis and Design of Autonomous Microwave Circuits. John Wiley & Sons, 2009.
[59] C. Cassella and G. Piazza, “Low phase-noise autonomous parametric oscillator based on a 226.7 MHz AlN contour-mode resonator,” IEEE Trans. Ultrason. Ferroelectr. Freq. Control, vol. 62, no. 4, pp. 617-624, April 2015, doi: 10.1109/TUFFC.2014.006753.
[60] N. Casilli, T. Kaisar, L. Colombo, S. Ghosh, P. X.-L. Feng, and C. Cassella, “Parametric Frequency Divider Based Ising Machines,” Phys. Rev. Lett., vol. 132, no. 14, p. 147301, April 2024, doi: 10.1103/PhysRevLett.132.147301.
[61] H. Hussein and C. Cassella, “Frequency Domain Acoustic-Based Subharmonic Tags for Far-Field Identification,” preprint, August 2022. doi: 10.36227/techrxiv.20505711.v1.
[62] H. M. E. Hussein, S. Kim, M. Rinaldi, A. Alù, and C. Cassella, “Passive frequency comb generation at radiofrequency for ranging applications,” Nat. Commun., vol. 15, no. 1, p. 2844 April 2024, doi: 10.1038/s41467-024-46940-2.
[63] S. Strogatz, Nonlinear dynamics and chaos: with applications to physics, biology, chemistry, and engineering, Repr. in Studies in nonlinearity. Cambridge, Mass: Westview Press, 2007.
[64] J. Woo and R. Landauer, “Fluctuations in a parametrically excited subharmonic oscillator,” IEEE J. Quantum Electron., vol. 7, no. 9, pp. 435-440, September 1971, doi: 10.1109/JQE.1971.1076831.
[65] S. Kim, S. H. Park, and C. S. Ryu, “Noise-Enhanced Multistability in Coupled Oscillator Systems,” Phys. Rev. Lett., vol. 78, no. 9, pp. 1616-1619 March 1997, doi: 10.1103/PhysRevLett.78.1616.
[66] M. Roberg and C. Campbell, “A Novel Even & Odd-Mode Symmetric Circuit Decomposition Method,” in 2013 IEEE Compound Semiconductor Integrated Circuit Symposium (CSICS), Monterey, CA, USA: IEEE, October 2013, pp. 1-4. doi: 10.1109/CSICS.2013.6659204.
[67] D. M. Pozar, Microwave engineering, 4th ed. Hoboken, NJ: Wiley, 2012.
[68] T. L. Heugel, O. Zilberberg, C. Marty, R. Chitra, and A. Eichler, “Ising machines with strong bilinear coupling,” Phys. Rev. Res., vol. 4, no. 1, p. 013149, February 2022, doi: 10.1103/PhysRevResearch.4.013149.
[69] L. Colombo, A. Kochhar, G. Vidal-Alvarez, P. Simeoni, U. Soysal, and G. Piazza, “SubGHz X-Cut Lithium Niobate So Mode MEMS Resonators,” J. Microelectromechanical Syst., vol. 31, no. 6, pp. 888-900, December 2022, doi: 10.1109/JMEMS.2022.3204449.
[70] L. Colombo, A. Kochhar, G. Vidal-Alvarez, and G. Piazza, “High-Figure-of-Merit X-Cut Lithium Niobate MEMS Resonators Operating Around 50 MHz for Large Passive Voltage Amplification in Radio Frequency Applications,” IEEE Trans. Ultrason. Ferroelectr. Freq. Control, vol. 67, no. 7, pp. 1392-142 July 2020, doi: 10.1109/TUFFC.2020.2972293.
[71] L. Gao, Y. Yang, and S. Gong, “Investigating Substrate Loss in MEMS Acoustic Resonators and On-Chip Inductors,” IEEE Trans. Ultrason. Ferroelectr. Freq. Control, vol. 69, no. 6, pp. 2178-2189 June 2022, doi: 10.1109/TUFFC.2022.3168539.
[72] S. Gong and G. Piazza, “Design and Analysis of Lithium-Niobate-Based High Electromechanical Coupling RF-MEMS Resonators for Wideband Filtering,” IEEE Trans. Microw. Theory Tech., vol. 61, no. 1, pp. 403-414, January 2013, doi: 10.1109/TMTT.2012.2228671.
[73] L. Colombo, A. Kochhar, G. Vidal-Alvarez, Z. Schaffer, P. Simeoni, and G. Piazza, “Comparison between different MEMS Laterally Vibrating Resonator Technologies for Passive Voltage Amplification in an RF Front-End System,” in 2018 IEEE MTT-S International Microwave Workshop Series on Advanced Materials and Processes for RF and THz Applications (IMWS-AMP), Ann Arbor, MI: IEEE, July 2018, pp. 1-3. doi: 10.1109/IMWS-AMP.2018.8457149.
[74] L. Colombo, A. Kochhar, G. Vidal-Alvarez, and G. Piazza, “X-Cut Lithium Niobate Laterally Vibrating MEMS Resonator With Figure of Merit of 1560,” J. Microelectromechanical Syst., vol. 27, no. 4, pp. 602-604, August 2018, doi: 10.1109/JMEMS.2018.2847310.
[75] Y. Yang, R. Lu, T. Manzaneque, and S. Gong, “1.7 GHZ Y-Cut Lithium Niobate MEMS Resonators with FoM of336 andfQ of 9.15×10¹²,” in 2018 IEEE/MTT-S International Microwave Symposium—IMS, Philadelphia, PA: IEEE, June 2018, pp. 563-566. doi: 10.1109/MWSYM.2018.8439516.
[76] S. Pan, M. M. Memon, J. Wan, T. Wang, and W. Zhang, “The Influence of Pressure on the TCF of AlN-Based SAW Pressure Sensor,” IEEE Sens. J., vol. 22, no. 4, pp. 3097-3104, February 2022, doi 10.1109/JSEN.2022.3140412.
[77] Z. Luo et al., “A10.7Sc0.3N butterfly-shaped laterally vibrating resonator with a figure-ofmerit (kt2·Qm) over 146,” Appl. Phys. Lett., vol. 120, no. 17, p. 173508, April 2022, doi: 10.1063/5.0090226.
[78] A. Ding et al., “Investigation of Temperature Characteristics and Substrate Influence on AlScN-Based SAW Resonators,” in 2018 IEEE International Ultrasonics Symposium (IUS), Kobe, Japan: IEEE, October 2018, pp. 1-9. doi: 10.1109/ULTSYM.2018.8579751.
[79] L. Colombo, A. Kochhar, C. Xu, G. Piazza, S. Mishin, and Y. Oshmyansky, “Investigation of 20% scandium-doped aluminum nitride films for MEMS laterally vibrating resonators,” in 2017 IEEE International Ultrasonics Symposium (IUS), Washington, DC: IEEE, September 2017, pp. 1-4. doi: 10.1109/ULTSYM.2017.8092076.
[80] Y. Chen et al., “Heterogeneous integration of lithium tantalate thin film on quartz for high performance surface acoustic wave resonator,” Jpn. J. Appl. Phys., vol. 62, no. 1, p. 015503, January 2023, doi: 10.35848/1347-4065/aca5d7.
[81] N. Casilli, L. Colombo, and C. Cassella, “A UHF 1.3 cm² Passive Subharmonic Tag With a 13 m Read-Range,” IEEE Microw. Wirel. Technol. Lett., vol. 33, no. 6, pp. 939-942, June 2023, doi: 10.1109/LMWT.2023.3268542.
[82] J. Roychowdhury, “A global Lyapunov function for the coherent Ising machine,” Nonlinear Theory Its Appl. IEICE, vol. 13, no. 2, pp. 227-232, 2022, doi: 10.1587/nolta. 13.227.
[83] M. Calvanese Strinati and C. Conti, “Multidimensional hyperspin machine,” Nat. Commun., vol. 13, no. 1, p. 7248 November 2022, doi: 10.1038/s41467-022-34847-9.
[84] S. Tsukiyama, K. Nakano, X. Li, Y. Ito, T. Kato, and Y. Kawamata, “Designing Unit Ising Models for Logic Gate Simulation through Integer Linear Programming,” 2024, arXiv. doi: 10.48550/ARXIV.2406.18130.
[85] K. P. Kalinin and N. G. Berloff, “Computational complexity continuum within Ising formulation of NP problems,” Commun. Phys., vol. 5, no. 1, p. 20, January 2022, doi: 10.1038/s42005-021-00792-0.
[86] Z.-Y. Zhou, C. Gneiting, J. Q. You, and F. Nori, “Frustration elimination for effective optical spins in coherent Ising machines,” Feb. 22, 2024, arXiv: arXiv: 2402.15090. Accessed: Oct. 4, 2024. [Online]. Available: http://arxiv.org/abs/2402.15090
[87] A. Mallick et al., “CMOS-compatible ising machines built using bistable latches coupled through ferroelectric transistor arrays,” Sci. Rep., vol. 13, no. 1, p. 1515 January 2023, doi: 10.1038/s41598-023-28217-8.
[88] S. Mercier, S. Villeneuve, M. Mondor, and I. Uysal, “Time-Temperature Management Along the Food Cold Chain: A Review of Recent Developments,” Compr. Rev. Food Sci. Food Saf., vol. 16, no. 4, pp. 647-667, July 2017, doi: 10.1111/1541-4337.12269.
[89] A. Lucas, “Ising formulations of many NP problems,” Front. Phys., vol. 2, 2014, doi: 10.3389/fphy.2014.00005.
[90] H. A. Haus, Electromagnetic Noise and Quantum Optical Measurements, in Advanced Texts in Physics. Berlin, Heidelberg: Springer Berlin Heidelberg, 2000. doi: 10.1007/978-3-662-04190-1.

1. An Ising logic-gate comprising:
at least four parametric oscillators (POs), each coupled to and power-combined with at least one other of the at least four POs, each of the at least four POs configured to passively activate, responsive to a pump signal exceeding a threshold power of the PO, a parametric oscillation having an oscillation frequency equal to half an angular input frequency of the pump signal, wherein an output signal of the PO can be switched between an in-phase state and an out-of-phase state;
a first coupling element for coupling first and second POs of the at least four POs to provide a first block having a first mode corresponding to a first logical input, wherein the first mode is passively activatable via passive activation of the first and/or second POs a first block output;
a second coupling element for coupling third and fourth POs of the at least four POs to provide a second block having a second mode corresponding to a second logical input, wherein the second mode is passively activatable via passive activation of the third and/or fourth POs to produce a second block output;
a third coupling element for coupling two of the at least four POs to provide a third block having a third mode, the third mode passively activatable to produce a third block output tuned to selectively either frustrate the first block output and/or the second block output to produce a combined output signal having a negligible amplitude or constructively interfere with the first block output and/or the second block output to produce the combined output signal having a detectable amplitude; and
a power combiner for power-combining the block outputs produced by the first, second, and third blocks and to produce the combined output signal indicating an in-phase or out-of-phase state of the Ising logic-gate.

2. The Ising logic-gate of claim 1, wherein the Ising logic-gate is an OR gate and the third block is tuned to produce the combined output signal having the negligible amplitude only when the first mode and the second mode are both inactive.

3. (canceled)

4. The Ising logic-gate of claim 1, wherein the Ising logic-gate is an XOR gate and the third block is tuned to produce the combined output signal having the negligible amplitude when the first mode and the second mode are either both inactive or both active.

5. (canceled)

6. The Ising logic-gate of claim 1, further comprising:
a fourth coupling element for coupling two of the at least four POs not coupled by the third coupling element to provide a fourth block having a fourth mode, the fourth mode passively activatable to produce a fourth block output tuned to selectively either frustrate the first, second, and/or third block output to produce the combined output signal having the negligible amplitude or constructively interfere with the first, second, and/or third block output to produce the combined output signal having the detectable amplitude;
wherein the Ising logic-gate is an AND gate and the third and fourth blocks are tuned produce the combined output signal having the detectable amplitude only when the first mode and the second mode are both active.

7. (canceled)

8. (canceled)

9. The Ising logic-gate of claim 1, wherein:
the first coupling element is a first sensor element for sensing a first parameter of interest, wherein the first sensor element is configured to set the threshold power of the first and second POs to be exceeded by a power of the pump signal responsive to a value of the first parameter of interest exceeding a first parameter of interest threshold; and
the second coupling element is a second sensor element for sensing a second parameter of interest, wherein the second sensor element is configured to set the threshold power of the third and fourth POs to be exceeded by a power of the pump signal responsive to a value of the second parameter of interest exceeding a second parameter of interest threshold.

10. The Ising logic-gate of claim 9, wherein:
a multidimensional sensing threshold of the Ising logic-gate is defined as a locus of all combinations of values of the first and second parameters of interest for which the block outputs constructively interfere to produce the combined output signal having the detectable amplitude.

11. (canceled)

12. (canceled)

13. (canceled)

14. (canceled)

15. (canceled)

16. (canceled)

17. (canceled)

18. The Ising logic-gate of claim 9, wherein one or more of the sensor elements includes piezoelectric resonator, a MEMS resonator, a NEMS resonator, or a combination thereof.

19. The Ising logic-gate of claim 1, wherein the power combiner is a Wilkinson power combiner.

20. The Ising logic-gate of claim 1, wherein each PO further comprises:
a resonant input mesh driven by the pump signal;
a resonant output mesh coupled to the input mesh through a nonlinear component to form a parametric frequency divider; and
the nonlinear component configured to passively activate, responsive to the pump signal exceeding the threshold power of the PO, the parametric oscillation between the input and output meshes, the parametric oscillation having the oscillation frequency equal to half the angular input frequency of the pump signal,
wherein the output signal of the PO can be switched between the in-phase state and the out-of-phase state.

21. The Ising logic-gate of claim 20, wherein a characteristic of the nonlinear component is modulated at the angular input frequency of the pump signal.

22. The Ising logic-gate of claim 20, wherein the nonlinear component has a nonlinear reactance.

23. The Ising logic-gate of claim 22, wherein the nonlinear component includes one or more of a diode, a varactor, or a combination thereof.

24. The Ising logic-gate of claim 23, wherein the nonlinear component includes a varactor and an inductor, wherein the input mesh and the output mesh are coupled through the varactor and the inductor.

25. The Ising logic-gate of claim 20, wherein:
the input mesh includes an input filter to constrain the pump signal within the input mesh to the angular input frequency of the pump signal; and
the output mesh includes an output filter to constrain the output signal within the output mesh to half of the angular input frequency of the pump signal.

26. The Ising logic-gate of claim 20, wherein the output mesh is configured to series-resonate at half the angular input frequency of the pump signal.

27. The Ising logic-gate of claim 20, wherein each of the input mesh and the output mesh includes a resonator.

28. The Ising logic-gate of claim 27, wherein each resonator includes one or more of an electrical resonator, a piezoelectric resonator, a MEMS resonator, a NEMS resonator, an optical resonator, a non-Hermitian resonator, an electromagnetic resonator, or a combination thereof.

29. A Ising logic system having logic gates based on Ising dynamics comprising:
an Ising logic-gate including:
an input antenna;
an output antenna;
at least four parametric oscillators (POs), each coupled to and power-combined with at least one other of the at least four POs, each of the at least four POs configured to passively activate, responsive to a pump signal exceeding a threshold power of the PO, a parametric oscillation having an oscillation frequency equal to half an angular input frequency of the pump signal, wherein an output signal of the PO can be switched between an in-phase state and an out-of-phase state;
a first coupling element for coupling first and second POs of the at least four POs to provide a first block having a first mode corresponding to a first logical input, wherein the first mode is passively activatable via passive activation of the first and/or second POs a first block output;
a second coupling element for coupling third and fourth POs of the at least four POs to provide a second block having a second mode corresponding to a second logical input, wherein the second mode is passively activatable via passive activation of the third and/or fourth POs to produce a second block output;
a third coupling element for coupling two of the at least four POs to provide a third block having a third mode, the third mode passively activatable to produce a third block output tuned to selectively either frustrate the first block output and/or the second block output to produce a combined output signal having a negligible amplitude or constructively interfere with the first block output and/or the second block output to produce the combined output signal having a detectable amplitude; and
a power combiner for power-combining the block outputs produced by the first, second, and third blocks and to produce the combined output signal indicating an in-phase or out-of-phase state of the Ising logic-gate; and
a reader configured to produce the pump signal and to read the combined output signal, wherein the reader is configured to detect an in-phase or out-of-phase state of the Ising logic-gate.

30. (canceled)

31. An Ising logic-gate comprising:
at least four parametric oscillators (POs), each coupled to and power-combined with at least one other of the at least four POs, each of the at least four POs configured to passively activate, responsive to a pump signal exceeding a threshold power of the PO, a parametric oscillation having an oscillation frequency equal to half an angular input frequency of the pump signal, wherein an output signal of the PO can be switched between an in-phase state and an out-of-phase state;
a plurality of coupling elements for coupling the at least four POs to form a plurality of blocks, each block comprising a coupled two of the at least four POs and having a mode corresponding to or interactive with a logical input, wherein the mode is passively activatable via passive activation of at least one of the coupled two of the at least four POs to produce a corresponding block output, the plurality of blocks producing a corresponding plurality of block outputs;
wherein the plurality of block outputs are tuned to selectively either frustrate at least one other of the plurality of block outputs to produce a combined output signal having a negligible amplitude or constructively interfere with the at least one other of the plurality of block outputs to produce the combined output signal having a detectable amplitude; and
a power combiner for power-combining the plurality of block outputs and for producing the combined output signal indicating an in-phase or out-of-phase state of the Ising logic-gate.

32. (canceled)

33. (canceled)

34. (canceled)

35. (canceled)

36. (canceled)

37. (canceled)
